(19) United States
(12) Patent Application Publication
(10) Pub. No.: US 2014/0291634 A1
(43) Pub. Date: Oct. 2, 2014

(54) INDOLE-BASED COMPOUND AND ORGANIC LIGHT-EMITTING DIODE COMPRISING THE SAME

(71) Applicant: SAMSUNG DISPLAY CO., LTD., Yongin-City (KR)

(72) Inventors: Dong-Woo Shin, Yongin-City (KR); Seul-Ong Kim, Yongin-City (KR); O-Hyun Kwon, Yongin-City (KR); Kyul Han, Yongin-City (KR)

(21) Appl. No.: 14/084,404

(22) Filed: Nov. 19, 2013

(30) Foreign Application Priority Data
Mar. 26, 2013 (KR) 10-2013-0032365

(51) Int. Cl. H01L 51/00; H01L 51/50

(52) U.S. Cl. CPC H01L 51/0072; H01L 51/50
USPC 257/40; 548/455; 548/490

(57) ABSTRACT

An indole-based compound represented by Formula 1 below, and an organic light-emitting diode including the indole-based compound are provided.

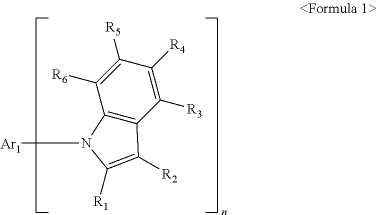

In Formula 1, Ar₁, R₁ to R₈, and n are the same as defined in the specification. The organic light-emitting diode with an organic layer including the indole-based compound of Formula 1 may have a low driving voltage, a high-emission efficiency, and long lifespan characteristics.

### CLAIM OF PRIORITY

This application makes reference to, incorporates the same herein, and claims all benefits accruing under 35 U.S.C. §119 from an application for INDOLE-BASED COMPOUND AND ORGANIC LIGHT-EMITTING DIODE COMPRISING THE SAME, earlier filed in the Korean Intellectual Property Office on Mar. 26, 2013 and there duly assigned Serial No. 10-2013-0032365.

### BACKGROUND OF THE INVENTION

1. Field of the Invention

One or more embodiments of the present invention relate to an indole-based compound and an organic light-emitting diode including the indole-based compound.

2. Description of the Related Art

Organic light-emitting diodes (OLEDs), which are self-emitting devices, have advantages such as wide viewing angles, excellent contrast, quick response, high brightness, excellent driving voltage characteristics, and can provide multicolored images.

A typical OLED has a structure including a substrate, and an anode, a hole transport layer (HTL), an emission layer (EML), an electron transport layer (ETL), and a cathode which are sequentially stacked on the substrate. In this regard, the HTL, the EML, and the ETL are organic thin films formed of organic compounds.

An operating principle of an OLED having the above-described structure is as follows. When a voltage is applied between the anode and the cathode, holes injected from the anode move to the EML via the HTL, and electrons injected from the cathode move to the EML via the ETL. The holes and electrons recombine in the EML to generate excitons. When the excitons drop from an excited state to a ground state, light is emitted.

Therefore, there is a demand for the development of novel materials for organic light-emitting diodes with high luminance, high efficiency, and long lifetime.

### SUMMARY OF THE INVENTION

One or more embodiments of the present invention include an indole-based compound for an organic light-emitting diode with low voltage, high luminance, high efficiency, high color purity, and long lifetime, and an organic light-emitting diode having an organic layer including the indole-based compound.

Additional aspects will be set forth in part in the description which follows and, in part, will be apparent from the description, or may be learned by practice of the presented embodiments.

According to one or more embodiments of the present invention, there is provided an indole-based compound represented by Formula 1 below:

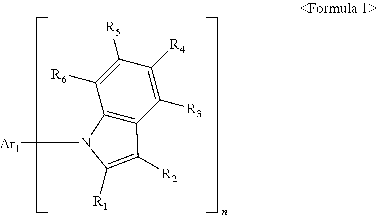

wherein, in Formula 1,

Ar₁ is one of a substituted or unsubstituted pyrene, a substituted or unsubstituted chrysene, a substituted or unsubstituted fluoranthene, a substituted or unsubstituted benzo[k]fluoranthene, and a substituted or unsubstituted anthracene;

n is 1 or 2, wherein, when n is 2, the two Ar₁s are identical to or differ from each other; and

R₁ to R₆ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, —Si(Q₁)(Q₂)(Q₃), or —N(Q₄)(Q₅) (where Q₁ to Q₅ are each independently a substituted or unsubstituted C₁-C₆₀ alkyl group, a substituted or unsubstituted C₆-C₆₀ aryl group, or a substituted or unsubstituted C₂-C₆₀ heteroaryl group).

According to one or more embodiments of the present invention, an organic light-emitting diode includes: a substrate; a first electrode disposed on the substrate; a second electrode disposed opposite to the first electrode; and an organic layer disposed between the first electrode and the second electrode, the organic layer including at least one of the indole-based compounds of Formula 1 above.

### BRIEF DESCRIPTION OF THE DRAWING

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic view of a structure of an organic light-emitting diode according to an embodiment of the present invention.

### DETAILED DESCRIPTION OF THE INVENTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

According to an embodiment of the present invention, there is provided an indole-based compound represented by Formula 1 below:

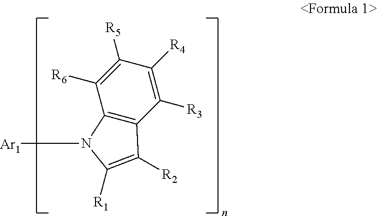

In Formula 1,

Ar₁ is one of a substituted or unsubstituted pyrene, a substituted or unsubstituted chrysene, a substituted or unsubstituted fluoranthene, a substituted or unsubstituted benzo[k]fluoranthene, and a substituted or unsubstituted anthracene;

n is 1 or 2, wherein, when n is 2, the two Ar₁s are identical to or differ from each other; and

R₁ to R₆ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, —Si(Q₁)(Q₂)(Q₃), or —N(Q₄)(Q₅) (where Q₁ to Q₅ are each independently a substituted or unsubstituted C₁-C₆₀ alkyl group, a substituted or unsubstituted C₆-C₆₀ aryl group, or a substituted or unsubstituted C₂-C₆₀ heteroaryl group).

In some embodiments, Ar₁ in Formula 1 may be a group represented by one of Formulae 2A to 2P below:

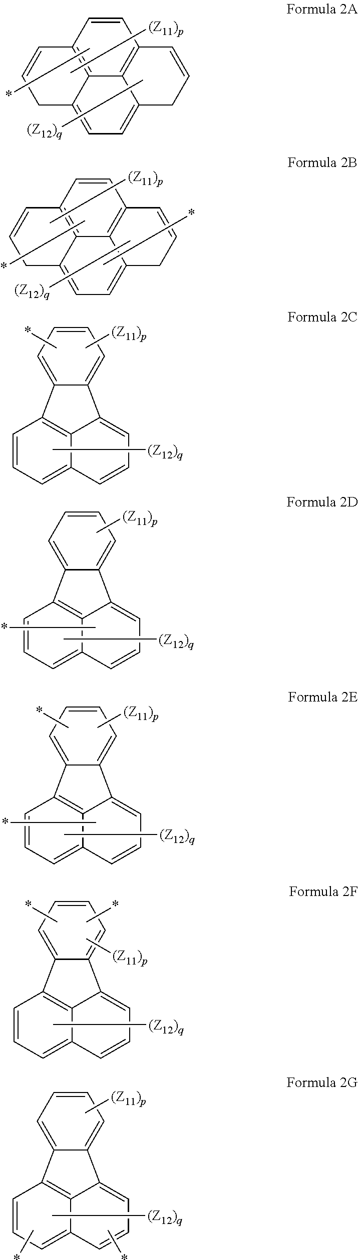

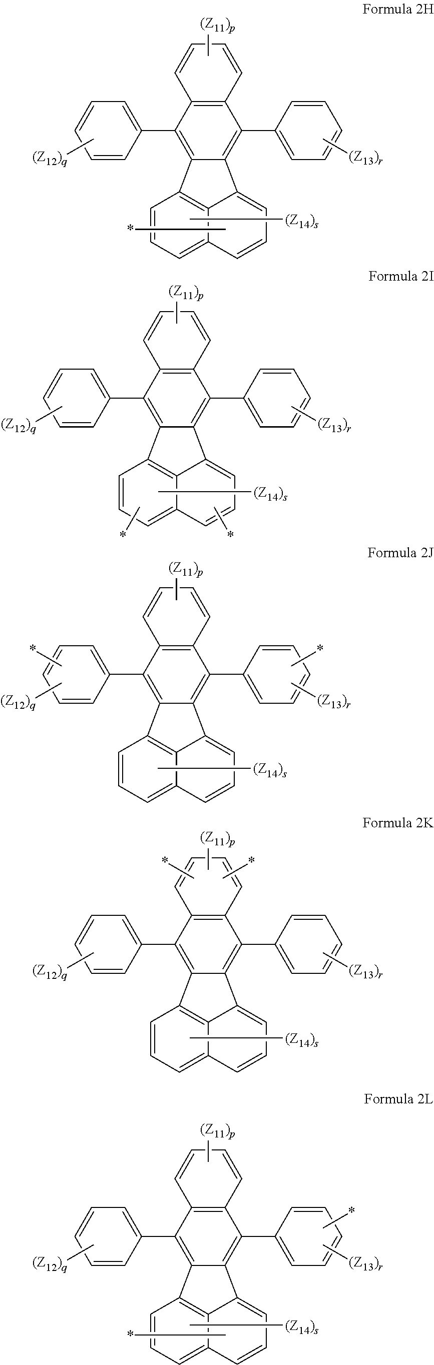

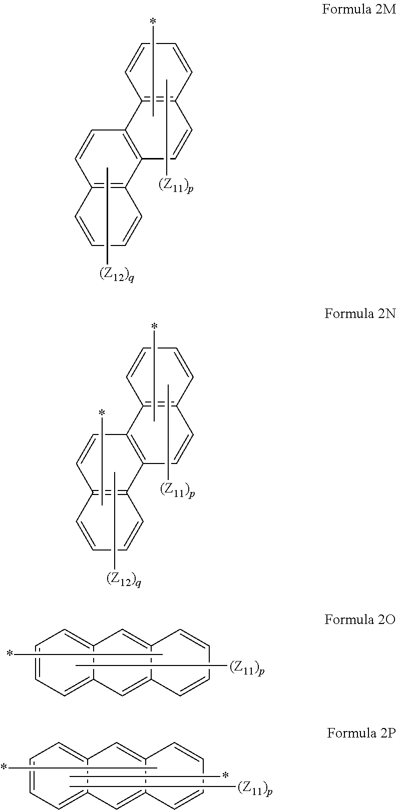

In Formulae 2A to 2P, Z₁₁ to Z₁₄ may be substituents, each independently being one selected from

a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, and a C₂-C₂₀ heteroaryl group,

a C₁-C₂₀ alkyl group and a C₁-C₂₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, and

a C₆-C₂₀ aryl group and a C₂-C₂₀ heteroaryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, and a C₂-C₂₀ heteroaryl group, wherein, when the number of Z₁₁s to Z₁₄s are each plural, the Z₁₁s, the Z₁₂s, the Z₁₃s, and the Z₁₄s are identical to or differ from each other;

p may be an integer of 0 to 9; q and s may be each independently an integer of 0 to 6; r may be an integer of 0 to 5; and * may be a binding site.

For example, Z₁₁ to Z₁₄ Formulae 2A to 2P may be each independently one selected from

a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a propyl group, a methoxy group, an ethoxy group, a propoxy group, a phenyl group, a naphthyl group, a pyrrole group, a pyridyl group, and a pyrimidyl group,

a methyl group, an ethyl group, a propyl group, a methoxy group, an ethoxy group, a propoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, and

a phenyl group, a naphthyl group, a pyrrole group, a pyridyl group, and a pyrimidyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, C₁-C₂₀ alkyl group, a C₁-C₂₀ alkoxy group, a C₆-C₂₀ aryl group, and a C₂-C₂₀ heteroaryl group; and

the Z₁₁s, the Z₁₂s, the Z₁₃s, and the Z₁₄s are identical to or differ from each other.

In some embodiments, Ar₁ in Formula 1 may be a group represented by one of Formulae 3A to 3H:

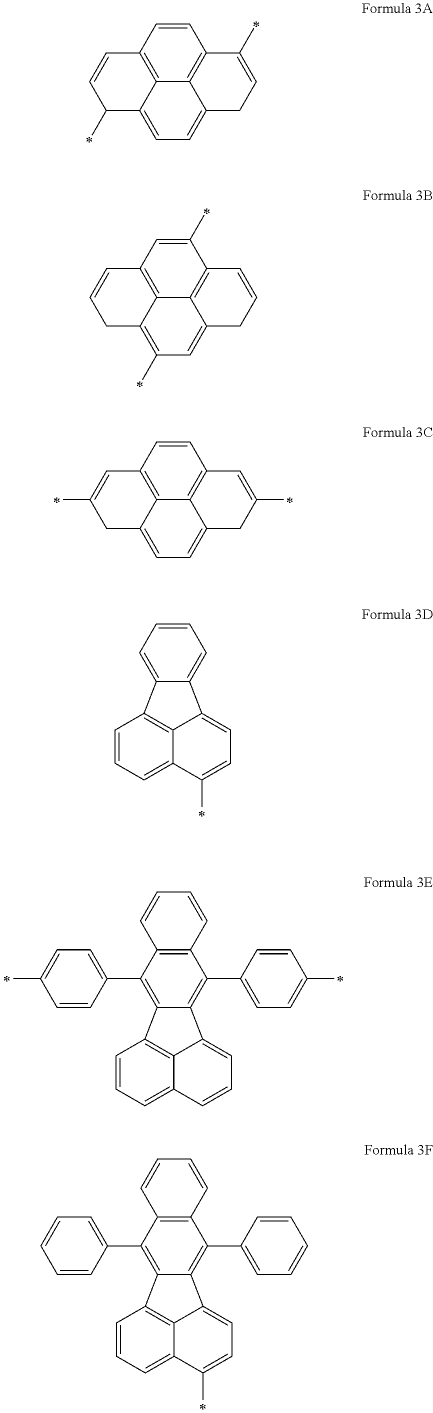

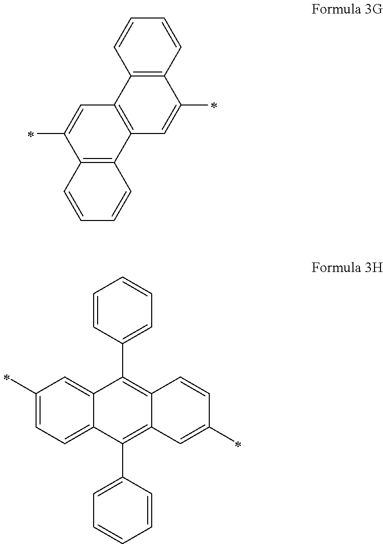

In Formulae 3A to 3H, * indicates a binding site.

In some embodiments, R₁ to R₆ in Formula 1 may be each independently one selected from

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, a C₁-C₁₀ alkoxy group, a phenyl group, a naphthyl group, a phenanthrenyl group, an anthryl group, a pentalenyl group, and an indenyl group, and

a C₁-C₁₀ alkyl group, a C₁-C₁₀ alkoxy group, a phenyl group, a naphthyl group, a phenanthrenyl group, an anthryl group, a pentalenyl group, and an indenyl group, each substituted with at least one of a deuterium atom, a halogen atom, a hydroxyl group, a cyano group, a nitro group, an amino group, an amidino group, a hydrazine, a hydrazone, a silyl group, a carboxyl group or a salt thereof, a sulfonic acid group or a salt thereof, and a phosphoric acid group or a salt thereof.

In some other embodiments, R₁ to R₆ in Formula 1 above may be each independently one selected from a phenyl group, a naphthyl group, a phenanthrenyl group, an anthryl group, a pentalenyl group, and an indenyl group, each substituted with a hydrogen atom, a deuterium atom, a halogen atom, a cyano group, a methyl group, an ethyl group, a propyl group, a phenyl group, or a silyl group.

In some other embodiments, R₁ and R₂ in Formula 1 may be each independently a hydrogen atom or a group represented by one of Formulae 4A and 4B; and R₃ to R₆ may be hydrogen atoms:

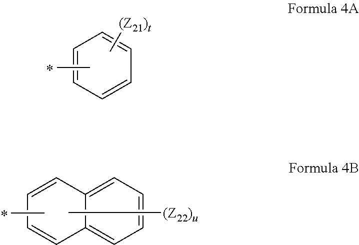

In Formula 4A and 4B, Z₂₁ and Z₂₂ may be substituents, being each independently one selected from among

a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, and a C₂-C₂₀ heteroaryl group,

a C₁-C₂₀ alkyl group and a C₁-C₂₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, and

a C₆-C₂₀ aryl group and a C₂-C₂₀ heteroaryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, C₁-C₂₀ alkyl group, a C₁-C₂₀ alkoxy group, a C₆-C₂₀ aryl group, and C₂-C₂₀ heteroaryl group;

t may be an integer of 0 to 5, and u may be an integer of 0 to 7, wherein, when the number of Z₂₁ s and Z₂₂s are each plural, the Z₂₁ s and the Z₂₂s are identical to or differ from each other; and

* indicates a binding site.

In some other embodiments, R₁ and R₂ in Formula 1 may be each independently a hydrogen atom or a group represented by one of Formulae 5A to 5M below; and R₃ to R₆ may be each independently hydrogen atoms:

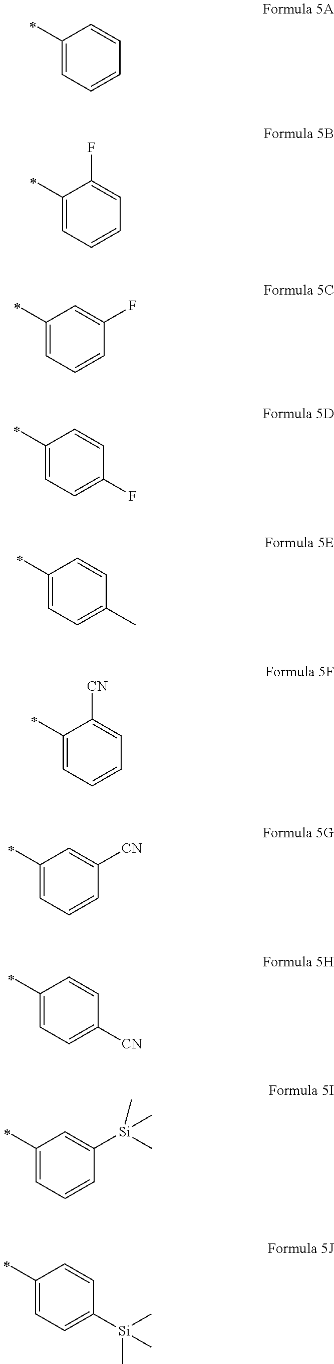

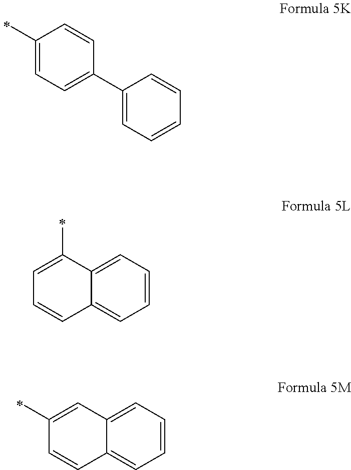

In Formulae 5A to 5M, * indicates a binding site.

In some embodiments, the indole-based compound of Formula 1 above may be one of Compounds 1 to 60 below, but is not limited thereto:

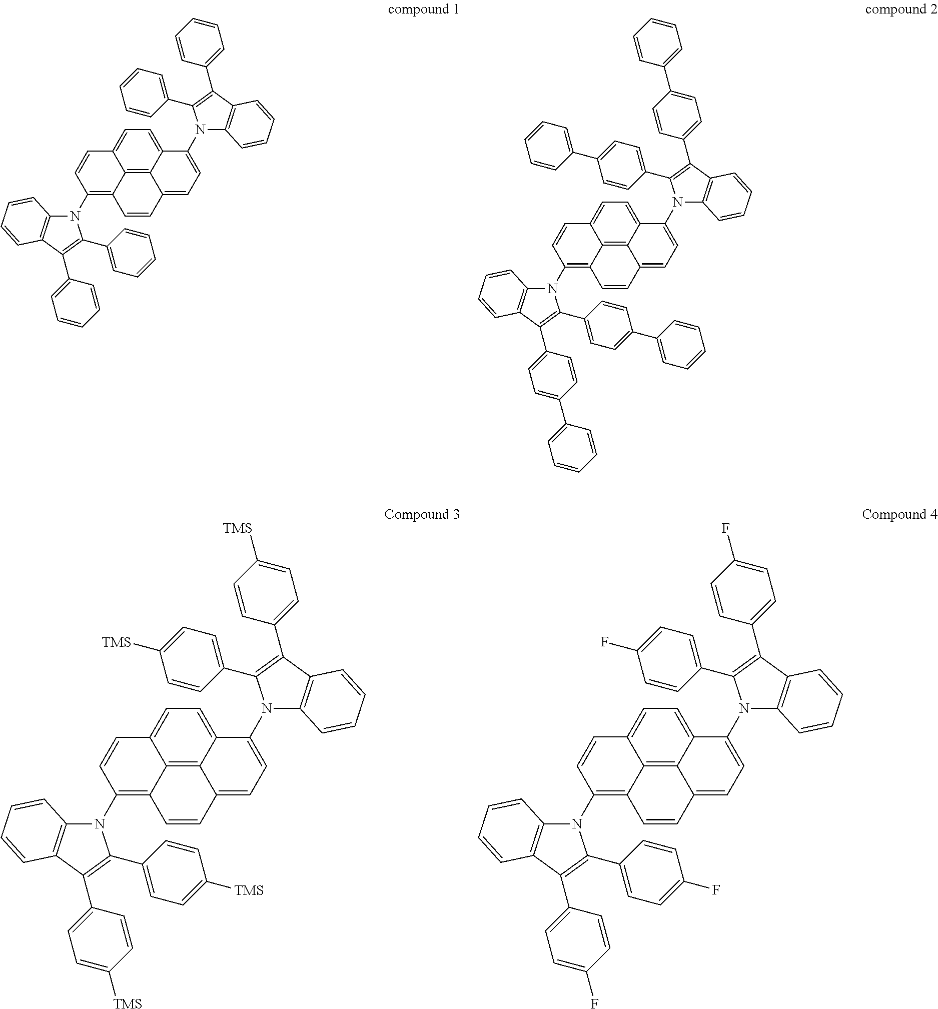

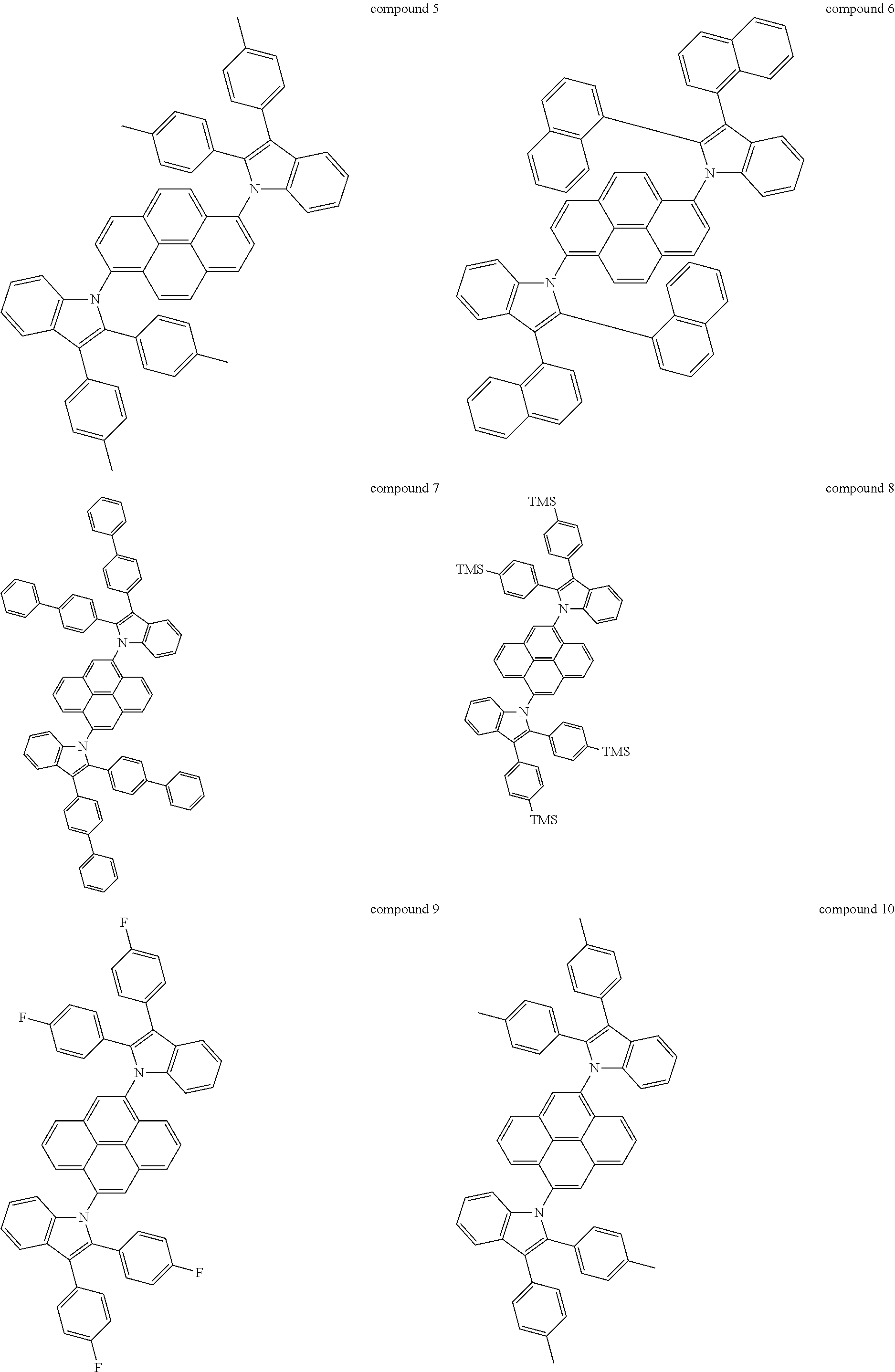

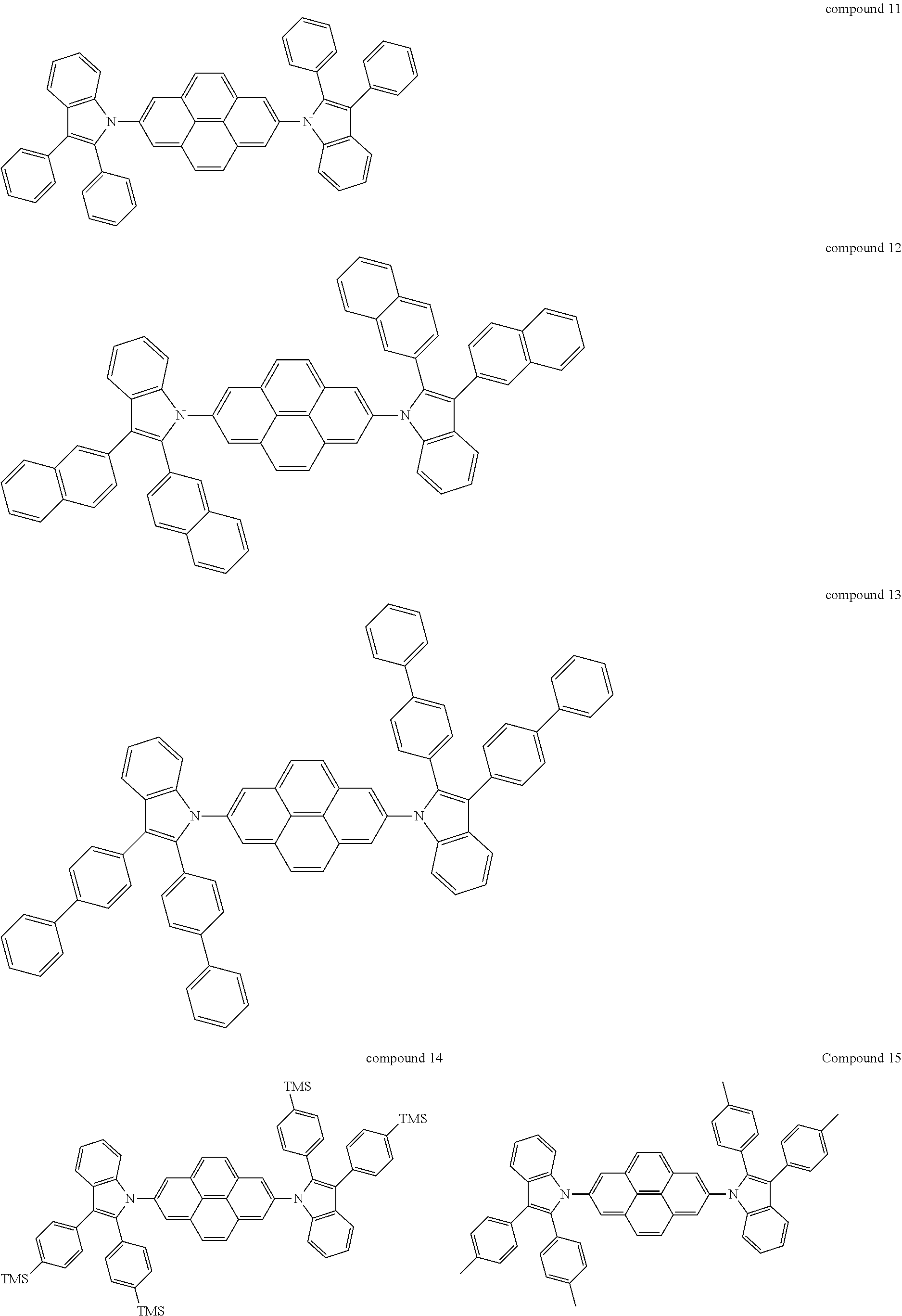

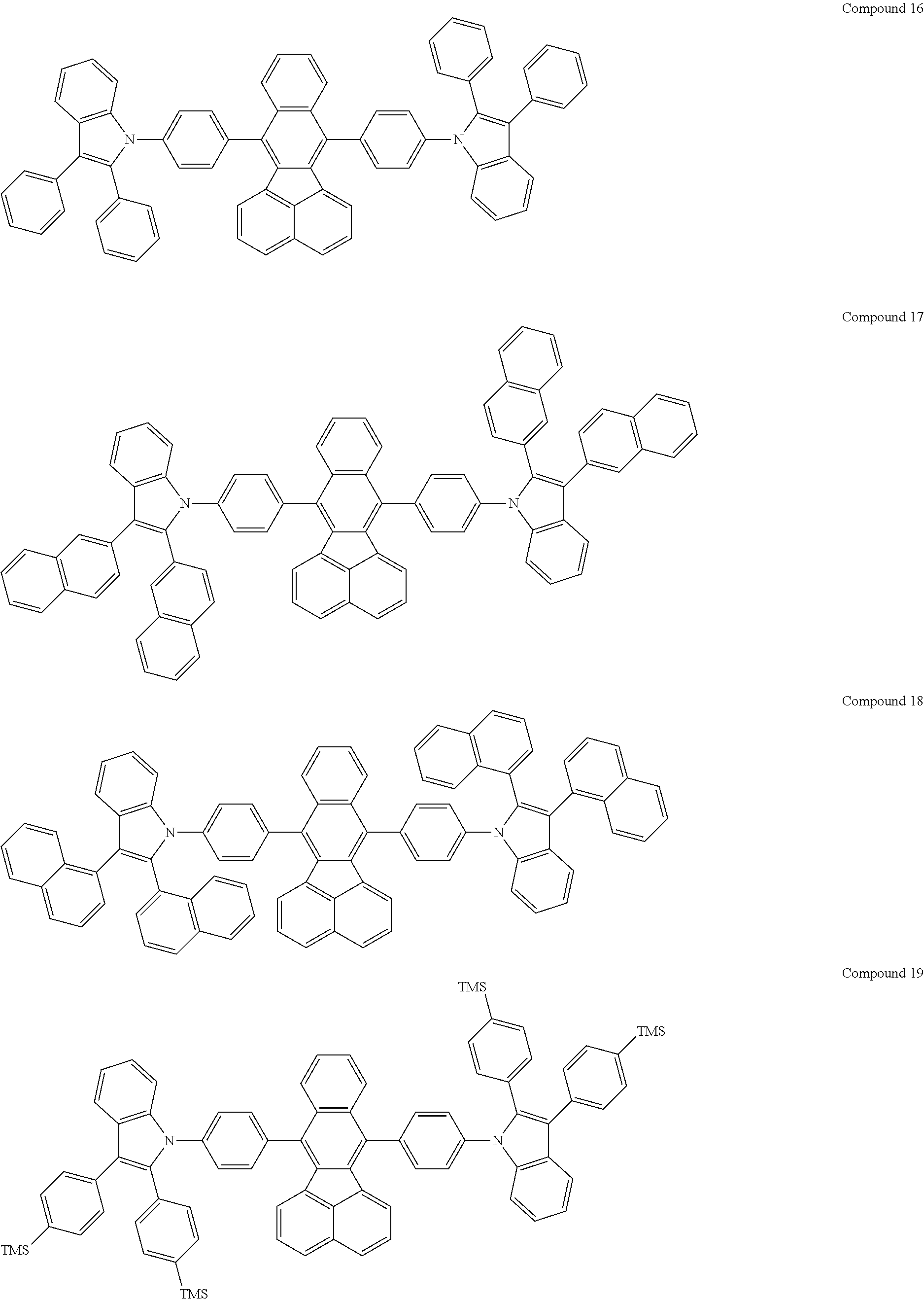

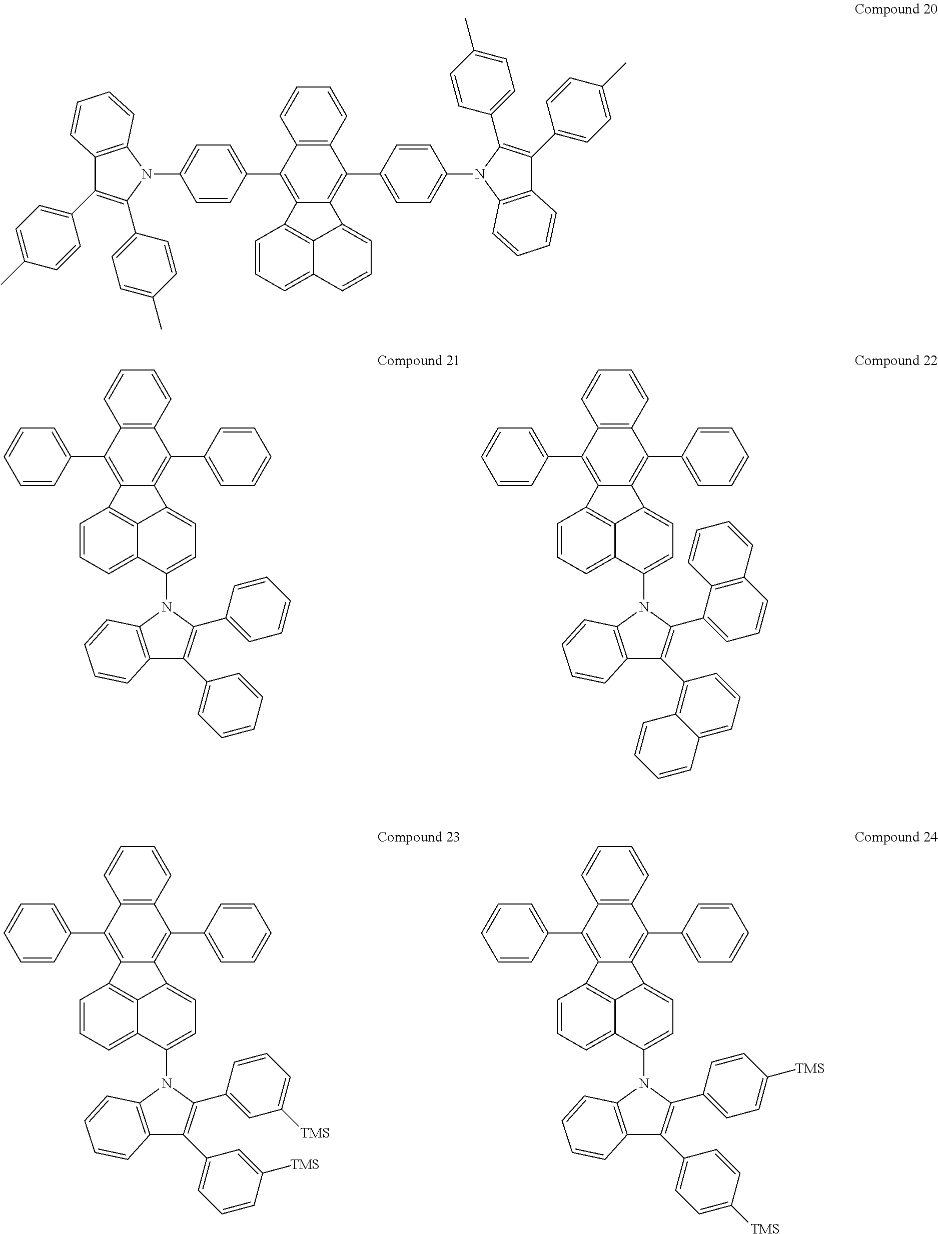

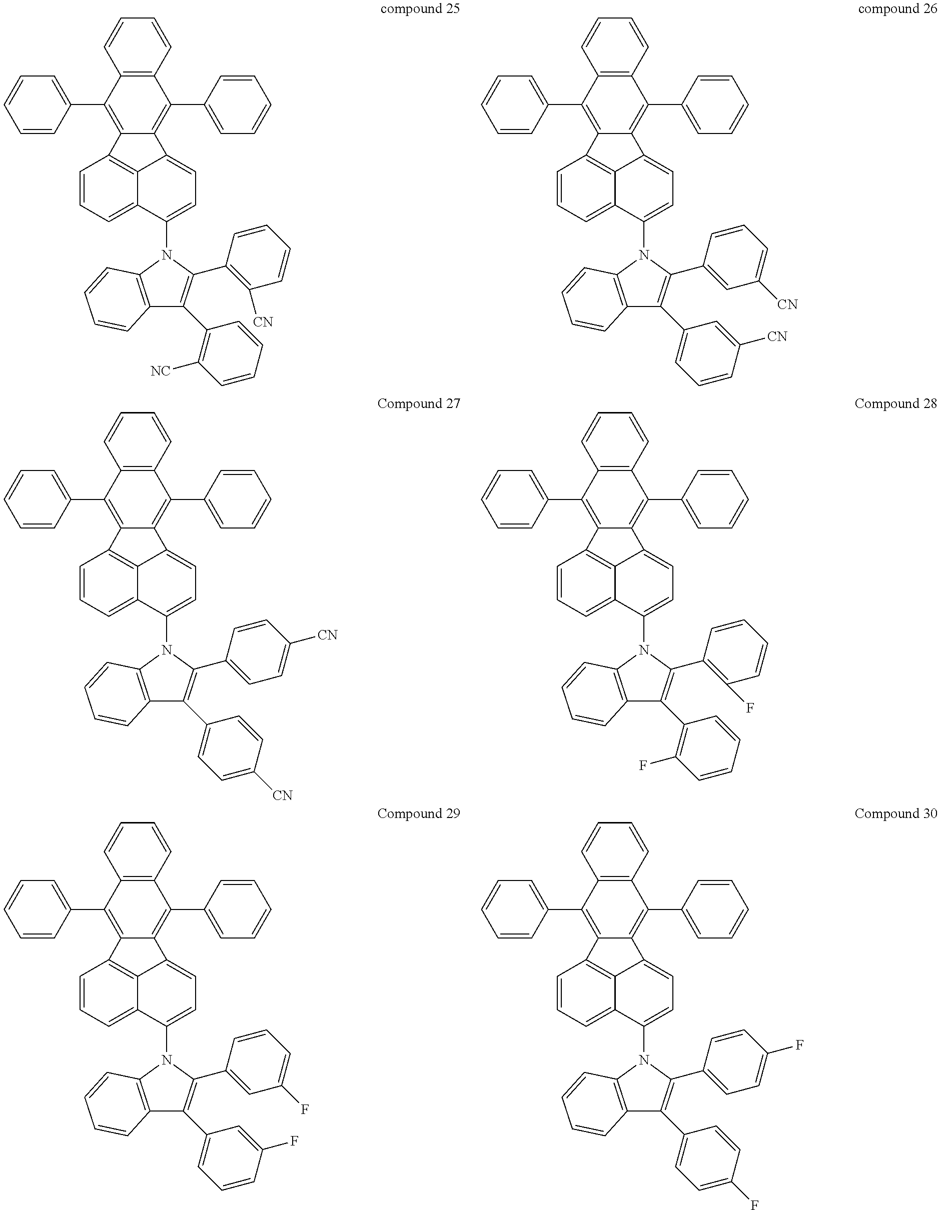

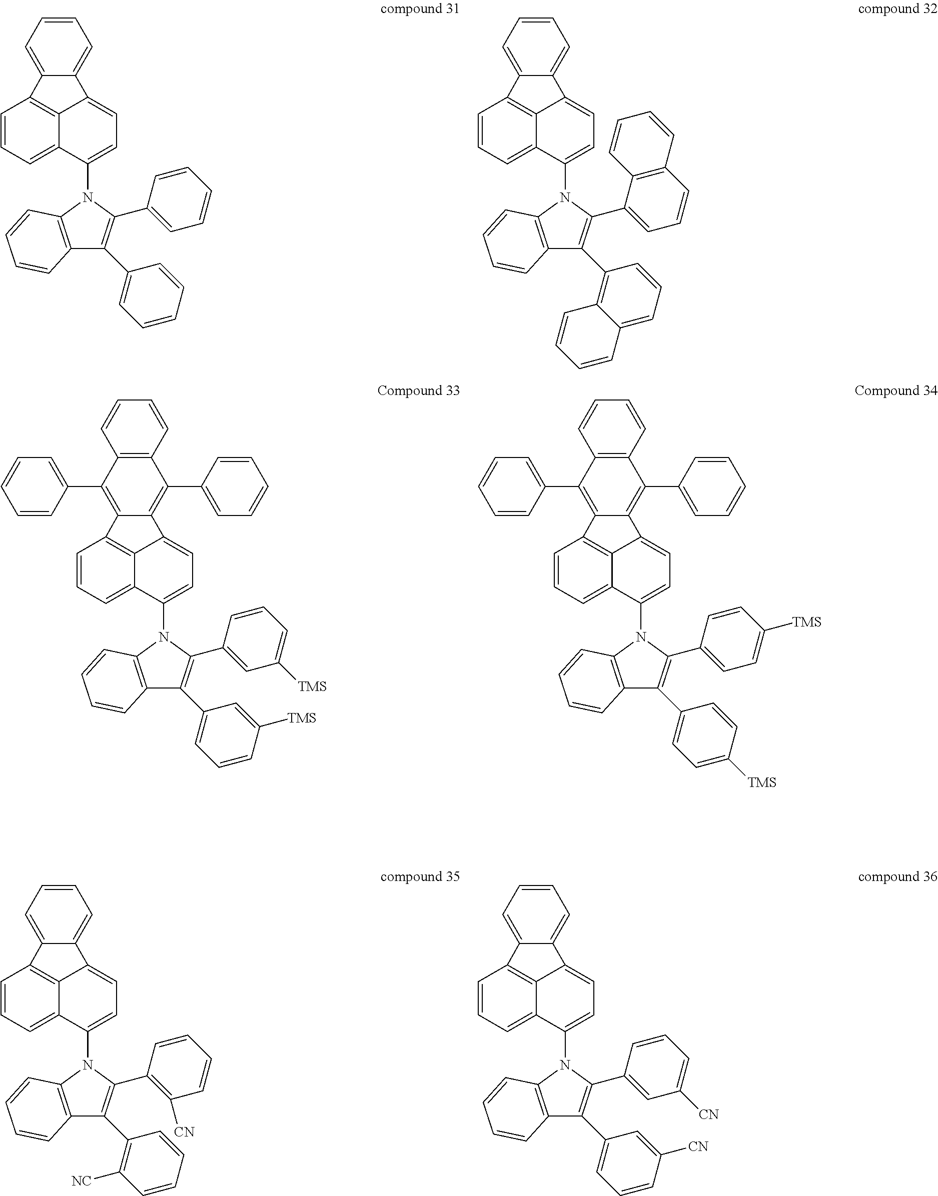

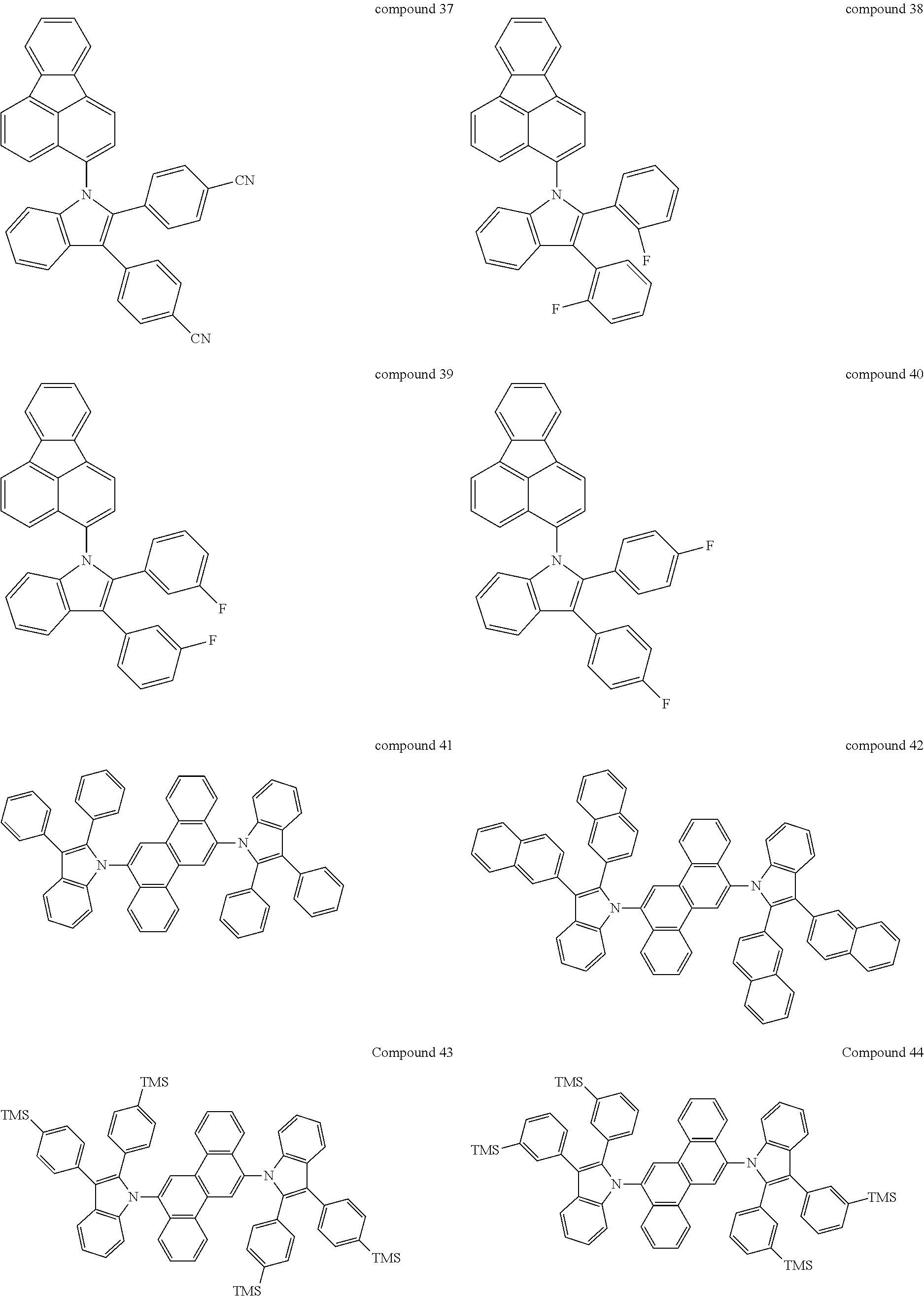

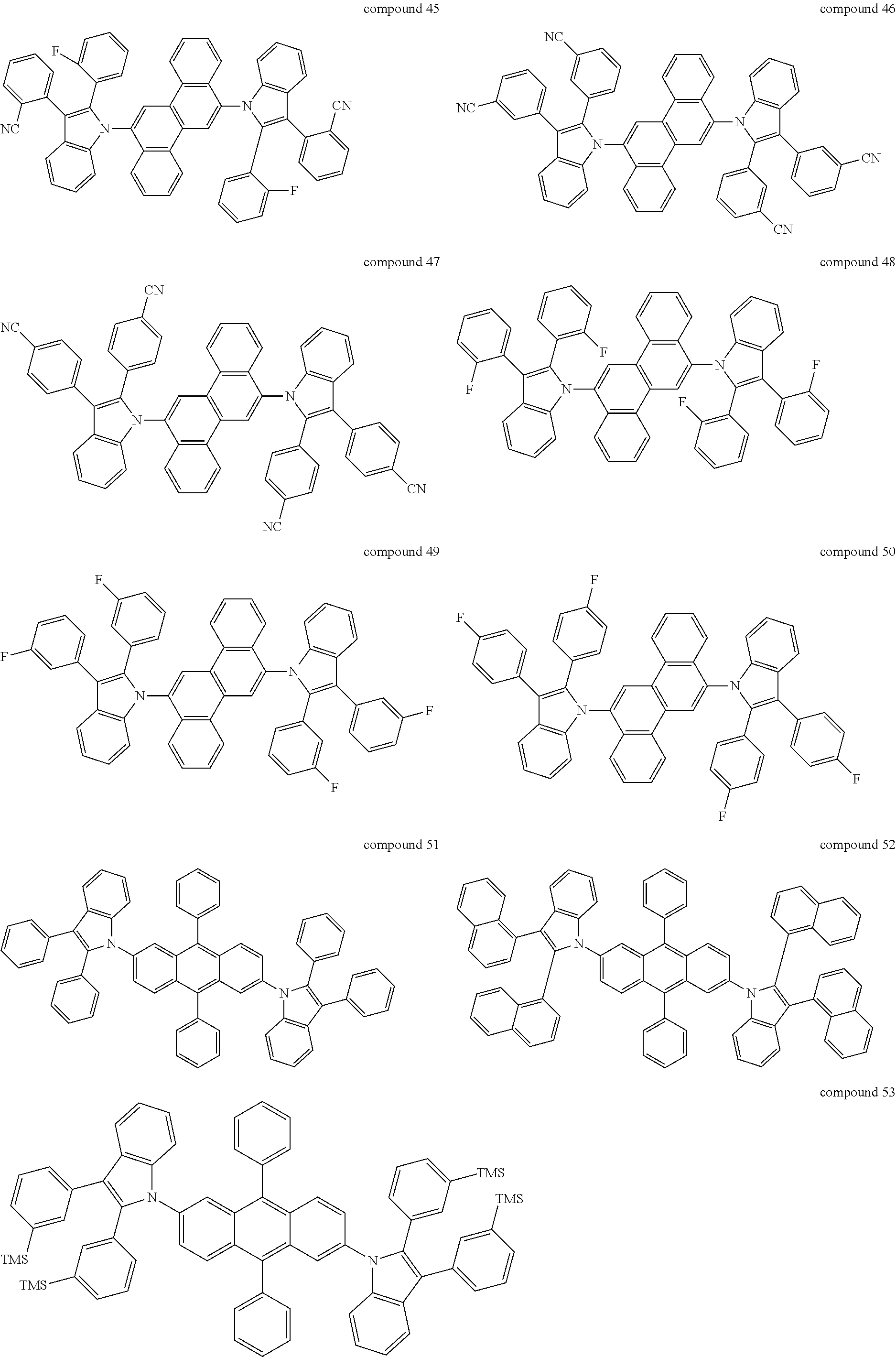

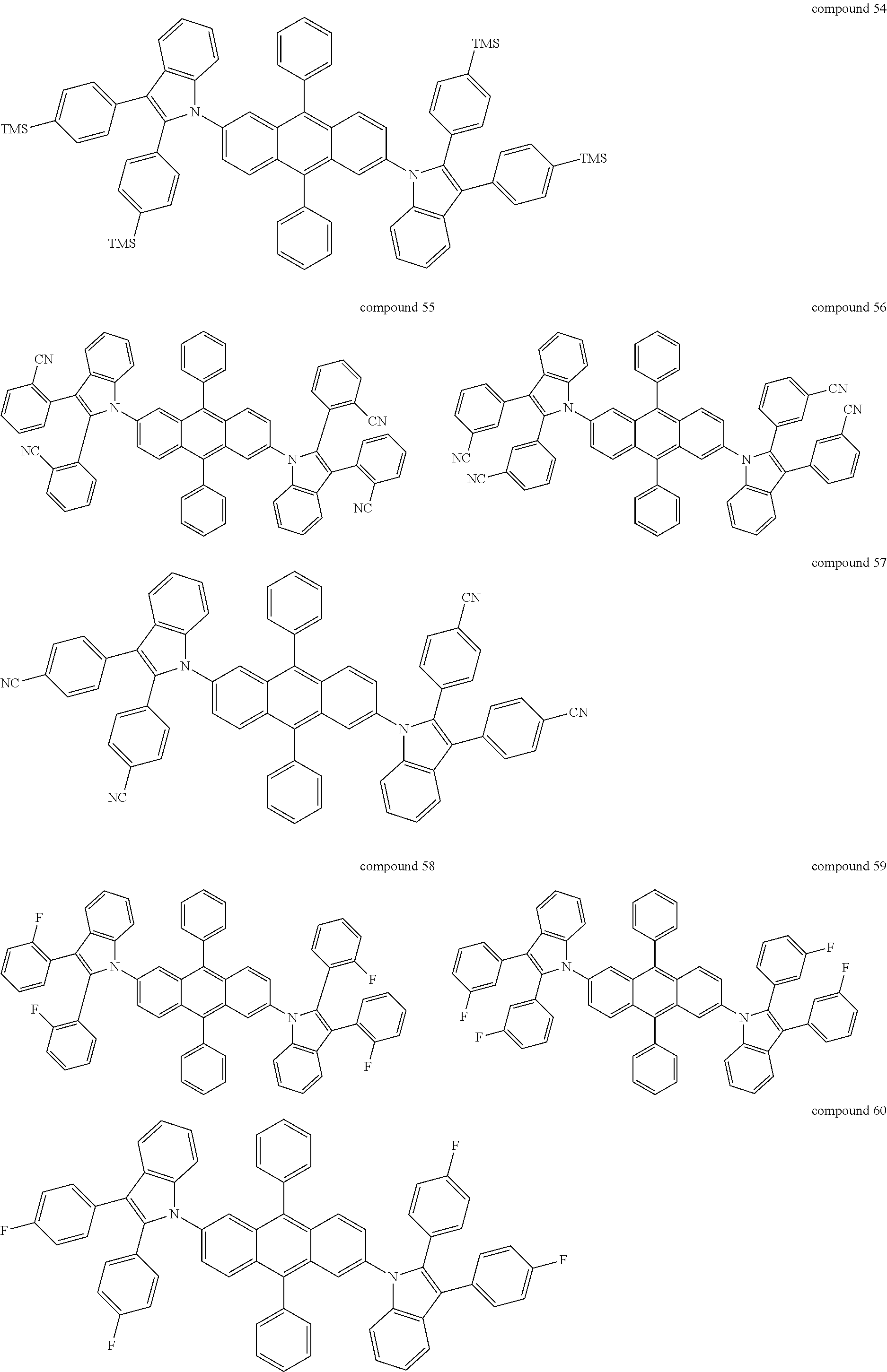

The indole-based compound of Formula 1 above may be used as an emitting material for organic light-emitting diodes. The indole-based compound(s) of Formula 1 has a high glass transition temperature (Tg) or a high melting point due to the inclusion of a condensed ring in its molecular structure. Thus, the indole-based compound may have high heat resistance against Joule's heat generated in an organic layer, between organic layers, or between an organic layer and a metal electrode when light emission occurs, and may have high durability in high-temperature environments. An organic light-emitting diode manufactured using the indole-based compound of Formula 1 may have improved durability when stored or operated. The indole-based compound of Formula 1 may have improved blue color purity and improved electrical performance. Accordingly, an organic light-emitting diode including the indole-based compound of Formula 1 may have improved optical and electrical characteristics.

Hereinafter, substituents described with reference to the formulae will now be described in detail. In this regard, the numbers of carbons in substituents are presented only for illustrative purposes and do not limit the characteristics of the substituents. The substituents not defined herein are construed as the same meanings understood by one of ordinary skill in the art.

Examples of the unsubstituted C₁-C₆₀ alkyl group (or a C₁-C₆₀ alkyl group) used herein are linear of branched C1-C60 alky groups, such as a methyl group, an ethyl group, a propyl group, an isobutyl group, a sec-butyl group, a pentyl group, an iso-amyl group, or a hexyl group. In a substituted C₁-C₆₀ alkyl group, at least one hydrogen atom in the unsubstituted C₁-C₆₀ alkyl group may be substituted with one selected from

a deuterium atom, a halogen atom, a cyano group, a hydroxyl group, a nitro group, an amino group, an amidino group, a silyl group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₆₀ cycloalkyl group, a C₆-C₆₀ aryl group, a C₂-C₆₀ heteroaryl group, a C₆-C₆₀ aralkyl group, and a C₆-C₆₀ aryloxy group;

a C₁-C₆₀ alkyl group, a C₂-C₆₀ alkenyl group, a C₂-C₆₀ alkynyl group, and a C₁-C₆₀ alkoxy group, each substituted with at least one of a deuterium atom, a halogen atom, a cyano group, a hydroxyl group, a nitro group, an amino group, an amidino group, a silyl group, a hydrazine group, a hydrazone group, a carboxyl group or a salt thereof, a sulfonic acid group or a salt thereof, and a phosphoric acid group or a salt thereof; and

a C₃-C₆₀ cycloalkyl group, a C₆-C₆₀ aryl group, a C₂-C₆₀ heteroaryl group, a C₆-C₆₀ aralkyl group, and a C₆-C₆₀ aryloxy group, each substituted with at least one of a deuterium atom, a halogen atom, a cyano group, a hydroxyl group, a nitro group, an amino group, an amidino group, a silyl group, a hydrazine group, a hydrazone group, a carboxyl group or a salt thereof, a sulfonic acid group or a salt thereof, a phosphoric acid group or a salt thereof, C₁-C₆₀ alkyl group, a C₂-C₆₀ alkenyl group, a C₂-C₆₀ alkynyl group, a C₁-C₆₀ alkoxy group, a C₆-C₆₀ aryl group, and a C₂-C₆₀ heteroaryl group (Any substituted group used therein may have the same substituents as those described in conduction with the substituted alkyl group).

The unsubstituted C₂-C₆₀ alkenyl group (or a C₂-C₆₀ alkenyl group) is a C₂-C₆₀ alkyl group having at least one carbon-carbon double bond in the center or at a terminal thereof. Non-limiting examples of the unsubstituted C₂-C₃₀ alkenyl group are ethenyl, propenyl, and butenyl groups. In a substituted C₂-C₆₀ alkenyl group, at least one hydrogen atom in the unsubstituted C₂-C₆₀ alkenyl group may be substituted with those substituents described above in conjunction with the substituted C₂-C₆₀ alkyl group.

The unsubstituted C₂-C₆₀ alkynyl group (or a C₂-C₆₀ alkynyl group) is a C₂-C₆₀ alkyl group having at least one carbon-carbon triple bond in the center or at a terminal thereof. Non-limiting examples of the unsubstituted C₂-C₂₀ alkynyl group are acetylene, propylene, phenylacetylene, naphthylacetylene, isopropylacetylene, t-butylacetylene, and diphenylacetylene. In a substituted C₂-C₆₀ alkynyl group, at least one hydrogen atom in the unsubstituted C₂-C₆₀ alkynyl group may be substituted with those substituents described in conjunction with the substituted C₂-C₆₀ alkyl group.

The unsubstituted C₃-C₆₀ cycloalkyl group used herein refers to a C3-C60 cyclic alkyl group. In a substituted C₃-C₆₀ cycloalkyl group, at least one hydrogen atom in the unsubstituted C₃-C₆₀ cycloalkyl group may be substituted with those substituents described in conjunction with the substituted C₁-C₆₀ alkyl group.

The unsubstituted C₁-C₆₀ alkoxy group (or a C₁-C₆₀ alkoxy group) may be a group represented by —OA (where A is an unsubstituted C₁-C₆₀ alkyl group described above). Non-limiting example of the unsubstituted C₁-C₆₀ alkoxy group are a methoxy group, an ethoxy group, an isopropyloxy group, a butoxy group, and a pentoxy group. in a substituted C₁-C₆₀ alkoxy group, at least one hydrogen atom in the unsubstituted C₁-C₆₀ alkoxy group may be substituted with those substituents described above in conjunction with the substituted C₁-C₆₀ alkyl group.

The unsubstituted C₆-C₆₀ aryl group is a monovalent group having a carbocyclic aromatic system having 5 to 60 carbon atoms including at least one aromatic ring. The unsubstituted C₆-C₆₀ arylene group is a divalent group having a carbocyclic aromatic system having 5 to 60 carbon atoms including at least one aromatic ring. When the aryl group or the arylene group has at least two rings, they may be fused to each other via a single bond. In a substituted C₆-C₆₀ aryl group, at least one hydrogen atom in the unsubstituted C₆-C₆₀ aryl group may be substituted with those substituents described above in conjunction with the substituted C₁-C₆₀ alkyl group. In a substituted C₆-C₆₀ arylene group, at least one hydrogen atom in the unsubstituted C₆-C₆₀ arylene group may be substituted with those substituents described above in conjunction with the substituted C₁-C₆₀ alkyl group.

Examples of the substituted or unsubstituted C₆-C₆₀ aryl group are a phenyl group, a C₁-C₁₀ alkylphenyl group (e.g., an ethylphenyl group), a C₁-C₁₀ alkylbiphenyl group (e.g., an ethylbiphenyl group), a halophenyl group (e.g., an o-, m- or p-fluorophenyl group and a dichlorophenyl group), a dicyanophenyl group, a trifluoromethoxyphenyl group, an o-, m- or p-tolyl group, an o-, m- or p-cumenyl group, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (e.g., a fluoronaphthyl group), a C₁-C₁₀ alkylnaphthyl group (e.g., a methylnaphthyl group), a C₁-C₁₀ alkoxynaphthyl group (e.g., a methoxynaphthyl group), an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylenyl group, a pyrenyl group, a chrysenyl group, an ethyl-chrysenyl group, a picenyl group, a perylenyl group, a chloroperylenyl group, a pentaphenyl group, a pentacenyl group, a tetraphenylenyl group, a hexaphenyl group, hexacenyl group, a rubicenyl group, a coronenyl group, a trinaphthylenyl group, a heptaphenyl group, a heptacenyl group, a phenanthrenyl group, and an ovalenyl group. Examples of the substituted C₅-C₆₀ aryl group may be inferred based on those of the unsubstituted C₅-C₆₀ aryl group and the substituted C₁-C₃₀ alkyl group described above. Examples of the substituted or unsubstituted C₆-C₆₀ arylene group may be inferred based on those examples of the substituted or unsubstituted C₆-C₆₀ aryl group described above.

The unsubstituted C₂-C₆₀ heteroaryl group is a monovalent group having a system consisting of at least one aromatic ring which comprises at least one of the heteroatoms selected from the group consisting of N, O, P, and S. The unsubstituted C₂-C₆₀ heteroarylene group is a divalent group having a system consisting of at least one aromatic ring which comprises at least one of the heteroatoms selected from the group consisting of N, O, P, and S. In this regard, when the heteroaryl group and the heteroarylene group have at least two rings, they may be fused to each other via a single bond. In a substituted C₂-C₆₀ heteroaryl group, at least one hydrogen atom in the unsubstituted C₂-C₆₀ heteroaryl group may be substituted with those substituents described above in conjunction with the substituted C₁-C₆₀ alkyl group. In a substituted C₂-C₆₀ heteroarylene group, at least one hydrogen atom in the unsubstituted C₂-C₆₀ heteroarylene group may be substituted with those substituents described above in conjunction with the substituted C₁-C₆₀ alkyl group.

Non-limiting examples of the unsubstituted C₂-C₆₀ heteroaryl group are a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzoimidazolyl group, an imidazopyridinyl group and an imidazopyrimidinyl group. Examples of the substituted C₂-C₆₀ heteroaryl group may be inferred based on those of the unsubstituted C₂-C₆₀ heteroaryl group and the substituted C₁-C₆₀ alkyl group described above. Examples of the substituted or unsubstituted C₂-C₆₀ heteroarylene group may be inferred based on those examples of the substituted or unsubstituted C₂-C₆₀ heteroaryl group described above.

The unsubstituted C₆-C₆₀ aryloxy group indicates —OA₂ (where A₂ is a substituted or unsubstituted C₆-C₆₀ aryl group described above). An example of the aryloxy group is a phenoxy group. Examples of the substituted C₆-C₆₀ aryloxy group may be inferred based on those of the unsubstituted C₆-C₆₀ aryloxy group and the substituted C₁-C₆₀ alkyl group described above.

The unsubstituted C₆-C₆₀ arylthio group indicates —SA₃ (where A₃ is a substituted or unsubstituted C₆-C₆₀ aryl group described above). Non-limiting examples of the arylthio group are a benzenethio group and a naphthylthio group. Examples of the substituted C₆-C₆₀ arylthio group may be inferred based on those of the unsubstituted C₆-C₆₀ arylthio group and the substituted C₁-C₆₀ alkyl group described above.

The indole-based compound of Formula 1 above may be synthesized using organic synthesis. A synthesis method of the indole-based compound of Formula 1 may be understood by those of ordinary skill in the art based on the examples that will be described below.

The indole-based compound of Formula 1 may be used between a pair of electrodes of an organic light-emitting diode. For example, at least one of the indole-based compounds of Formula 1 may be used in an emission layer.

According to another embodiment of the present invention, an organic light-emitting diode includes a first electrode, a second electrode disposed opposite to the first electrode, and an organic layer disposed between the first electrode and the second electrode, the organic layer including at least one of the indole-based compounds of Formula 1 described above.

As used herein, the term “organic layer” refers to a layer containing an organic compound and consisting of at least one layer. For example, the organic layer may include at least one layer selected from among a hole injection layer, a hole transport layer, a functional layer (hereinafter, “hole injection and transport layer”) having both hole injection and hole transport capabilities, an electron blocking layer, an emission layer, a hole blocking layer, an electron injection layer, an electron transport layer, and a functional layer (hereinafter, “electron injection and transport layer”) having both electron injection and electron transport capabilities.

The organic layer may not include solely an organic compound. The organic layer may include an inorganic compound or an inorganic material. In one embodiment, the organic layer may include both an organic compound and an inorganic compound or an inorganic material in one layer. For example, the organic layer may include an organometallic complex in one layer. In another embodiment, the organic layer may include a layer containing an organic compound and a layer containing an inorganic compound or an inorganic material.

The organic layer may include at least one of the indole-based compounds listed above in one layer, and in some other embodiments, may include at least one of the heterocyclic compounds listed above in layers. For example, the indole-based compound in the emission layer may include Compound 3 above, or Compound 3 and Compound 21. For example, the organic layer may include one of the indole-based compounds of Formula 1 above in an emission layer, and a different indole-based compound of Formula 1 as an electron transport material in an electron transport layer.

The organic layer may include an emission layer, which may include a host and a dopant. The dopant may include an indole-based compound of Formula 1 above. The indole-based compound of Formula 1 may serve as a fluorescent dopant. The emission layer including the indole-based compound may emit blue light. In this regard, the host may include an anthracene-based compound.

The organic layer may include at least one of the hole injection layer, the hole transport layer, and the hole injection and transport layer, and at least one of these layers may further include a charge generating material. The charge generating material may be, for example, a p-dopant. The p-dopant may be, for example, a quinine derivative, a metal oxide, or a cyano group-containing compound.

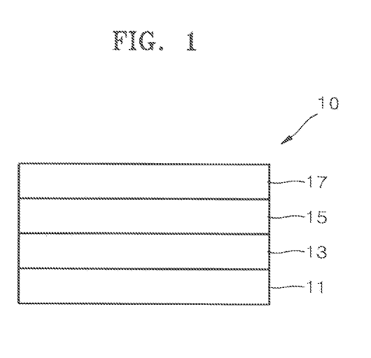

FIG. 1 is a schematic sectional view of an organic light-emitting diode 10 according to an embodiment of the present invention. Hereinafter, a structure of an organic light-emitting diode according to an embodiment of the present invention and a method of manufacturing the same will now be described with reference to FIG. 1.

Referring to FIG. 1, the organic light-emitting diode 10 includes a substrate 11, a first electrode 13, an organic layer 15, and a second electrode 17, which are sequentially stacked in this order.

The substrate 11 may be any substrate that is used in existing organic light-emitting diodes. In some embodiments the substrate 11 may be a glass substrate or a transparent plastic substrate with strong mechanical strength, thermal stability, transparency, surface smoothness, ease of handling, and water resistance.

The first electrode 13 may be formed by depositing or sputtering a first electrode-forming material on the substrate 11. When the first electrode 13 is an anode, a material having a high work function may be used as the first electrode-forming material to facilitate hole injection. The first electrode 13 may be a reflective electrode or a transmission electrode. The first electrode-forming material may be for example indium tin oxide (ITO), indium zinc oxide (IZO), tin oxide (SnO2), or zinc oxide (ZnO). In some embodiments, the first electrode 13 may be formed as a reflective electrode from magnesium (Mg), aluminum (Al), aluminum-lithium (Al—Li), calcium (Ca), magnesium-indium (Mg—In), magnesium-silver (Mg—Ag), or the like. The first electrode 13 may have a single-layer structure or a multi-layer structure including at least two layers. For example, the first electrode 13 may have a three-layered structure of ITO/Ag/ITO, but is not limited thereto.

The organic layer 15 may be disposed on the first electrode 13.

The organic layer 15 may include a hole injection layer (HIL), a hole transport layer (HTL), a buffer layer (not shown), an emission layer (EML), an electron transport layer (ETL), and an electron injection layer (EIL).

The HIL may be formed on the first electrode 13 by any of a variety of methods, including vacuum deposition, spin coating, casting, Langmuir-Blodgett (LB) deposition, and the like.

When the HIL is formed using vacuum deposition, vacuum deposition conditions may vary depending on the compound that is used to form the HIL, and the desired structure and thermal properties of the HIL to be formed. For example, vacuum deposition may be performed at a temperature of about 100° C. to about 500° C., a pressure of about 10⁻⁸ torr to about 10⁻³ torr, and a deposition rate of about 0.01 to about 100 Å/sec. However, the deposition conditions are not limited thereto.

When the HIL is formed using spin coating, the coating conditions may vary depending on the compound that is used to form the HIL, and the desired structure and thermal properties of the HIL to be formed. For example, the coating rate may be in the range of about 2,000 rpm to about 5,000 rpm, and a temperature at which heat treatment is performed to remove a solvent after coating may be in the range of about 80° C. to about 200° C. However, the coating conditions are not limited thereto.

The HIL may be formed of any known materials for forming HILs. Non-limiting examples of known hole injection materials include N,N′-diphenyl-N,N′-bis-[4-(phenyl-m-tolyl-amino)-phenyl]-biphenyl-4,4′-diamine, (DNTPD), a phthalocyanine compound such as copperphthalocyanine, 4,4′,4″-tris(3-methylphenylphenylamino)triphenylamine (m-MTDATA), 4,4′,4″-tris(N,N-diphenylamino)triphenylamine (TDATA), 4,4′,4″-tris{N,-(2-naphthyl)-N-phenylamino}-triphenylamine (2T-NATA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonicacid (PANI/CSA), and polyaniline)/poly(4-styrenesulfonate (PANI/PSS).

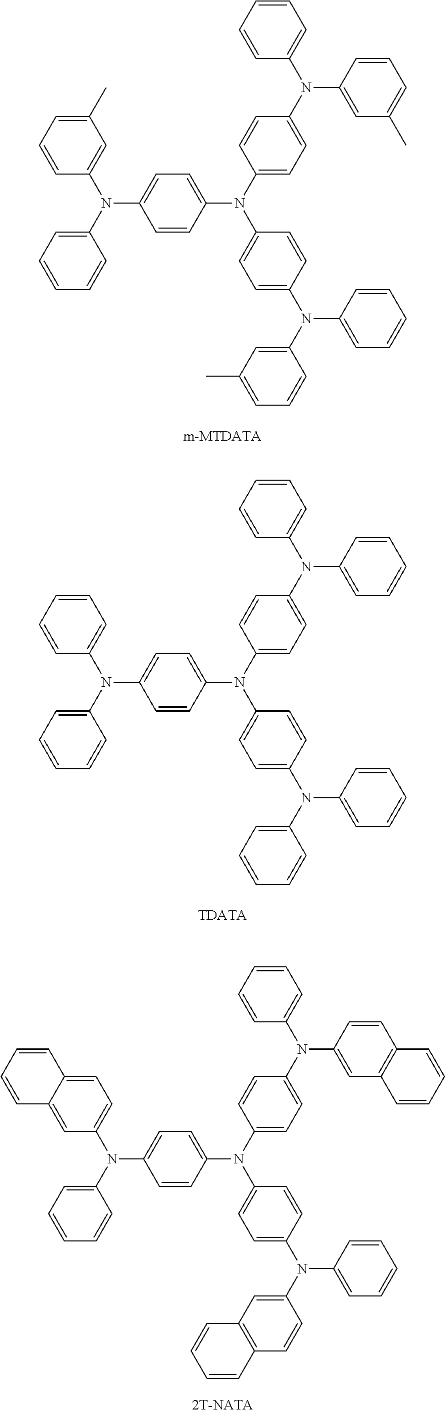

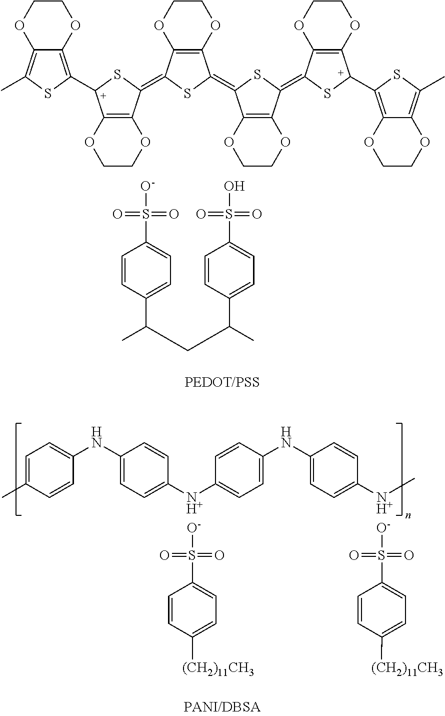

The thickness of the HIL may be from about 100 Å to about 10,000 Å, and in some embodiments, from about 100 Å to about 10,000 Å. When the thickness of the HIL is within these ranges, the HIL may have good hole injecting ability without a substantial increase in driving voltage.

Then, a HTL may be formed on the HIL by using vacuum deposition, spin coating, casting, Langmuir-Blodgett (LB) deposition, or the like. When the HTL is formed using vacuum deposition or spin coating, the conditions for deposition and coating may be similar to those for the formation of the HIL, though the conditions for the deposition and coating may vary depending on the material that is used to form the HTL.

The HTL may be formed of any known hole-transporting materials. Non-limiting examples of known hole transporting materials are carbazole derivatives, including N-phenylcarbazole and polyvinylcarbazole, TPD (N,N′-bis(3-methylphenyl)-N,N′-diphenyl-[1,1-biphenyl]-4,4′-diamine), NPB (N,N′-di(1-naphthyl)-N,N-diphenylbenzidine), α-NPD (N,N′-bis(naphthalen-1-yl)-N,N′-bis(phenyl)-2,2′-dimethylbenzidine, and TCTA (4,4′,4″-tris(N-carbazolyl)triphenylamine).

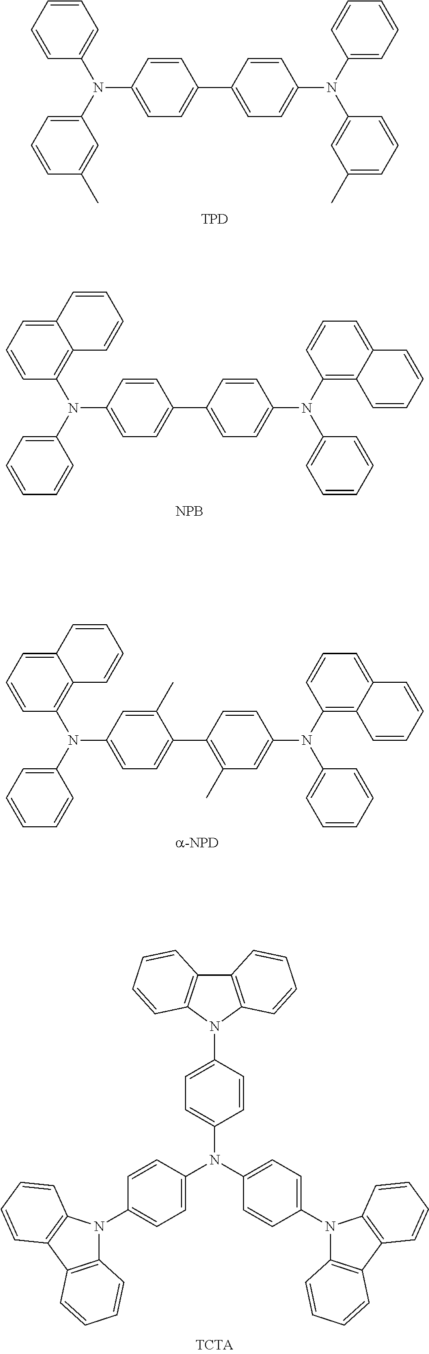

The thickness of the HTL may be from about 50 Å to about 1,000 Å, and in some embodiments, from about 100 Å to about 800 Å. When the thickness of the HTL 14 is within these ranges, the HTL 140 may have satisfactory hole transporting ability without a substantial increase in driving voltage.

In some embodiments, instead of the HIL and the HTL, a hole injection and transport layer may be formed. The hole injection and transport layer may include at least one of the hole injection layer materials and hole transport layer materials described above. A thickness of the hole injection and transport layer may be from about 500 Å to about 10,000 Å, and in some embodiments, may be from about 100 Å to about 1,000 Å. When the thickness of the hole injection and transport layer is within these ranges, the hole injection and transport layer may have good hole injection and transport capabilities without a substantial increase in driving voltage.

In some embodiments, at least one of the HIL, HTL, and hole injection and transport layer may include at least one of a compound of Formula 100 below and a compound of Formula 101 below:

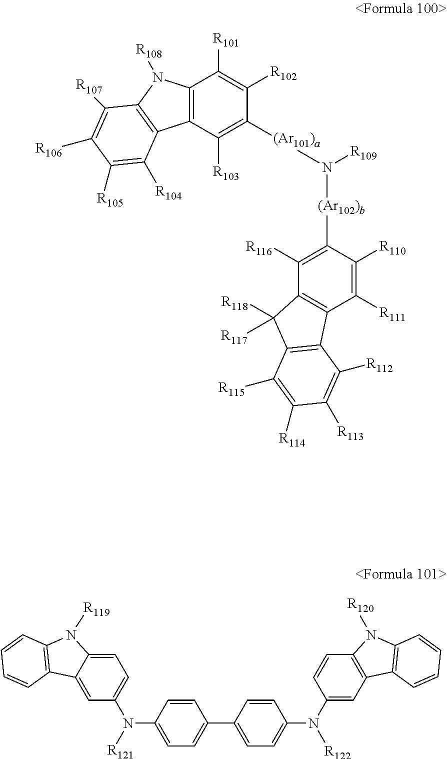

In Formula 100, Ar₁₀₁ and Ar₁₀₂ may be each independently a substituted or unsubstituted C₆-C₆₀ arylene group. In some embodiments, Ar101 and Ar102 may be each independently one of a phenylene group, a pentalenylene group, an indenylene group, a naphthylene group, an azulenylene group, a heptalenylene group, a substituted or unsubstituted an acenaphthylene group, a fluorenylene group, a phenalenylene group, a phenanthrenylene group, an anthracenylene group, a fluoranthenylene group, a triphenylenylene group, a pyrenylenylene group, a chrysenylene group, a naphthacenylene group, a picenylene group, a perylenylene group, and a pentacenylene group; and a phenylene group, a pentalenylene group, an indenylene group, a naphthylene group, an azulenylene group, a heptalenylene group, a substituted or unsubstituted an acenaphthylene group, a fluorenylene group, a phenalenylene group, a phenanthrenylene group, an anthracenylene group, a fluoranthenylene group, a triphenylenylene group, a pyrenylenylene group, a chrysenylene group, a naphthacenylene group, a picenylene group, a perylenylene group, and a pentacenylene group, each substituted with at least one of a deuterium atom, a halogen atom, a hydroxyl group, a nitro group, a cyano group, an amino group, an amidino group, hydrazine, hydrazone, a carboxyl group or salt thereof, a sulfuric acid group or salt thereof, a phosphoric acid group or salt thereof, a C₁-C₆₀ alkyl group, a C₂-C₆₀ alkenyl group, a C₂-C₆₀ alkynyl group, a C₁-C₆₀ alkoxy group, a C₃-C₆₀cycloalkyl group, a C₃-C₆₀ cycloalkenyl group, a C₃-C₆₀ heterocycloalkyl group, a C₃-C₆₀ heterocycloalkenyl group, a C₆-C₆₀ aryl group, a C₆-C₆₀ aryloxy group, a C₆-C₆₀ arylthio group, and a C₂-C₆₀ heteroaryl group.

In Formula 100, a and b may be each independently an integer from 0 to 5, and in some embodiments, may be each independently 0, 1, or 2. For example, a may be 1, and b may be 0, but are not limited thereto.

In Formulae 100 and 101 above, R₁₀₁ to R₁₂₂ may be each independently a hydrogen atom, a deuterium atom, a halogen atom, a hydroxyl group, a cyano group, a nitro group, an amino group, an amidino group, a hydrazine group, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀alkynyl group, a substituted or unsubstituted C₁-C₆₀ alkoxy group, a substituted or unsubstituted C₃-C₆₀ cycloalkyl group, a substituted or unsubstituted C₆-C₆₀ aryl group, a substituted or unsubstituted C₆-C₆₀ aryloxy group, or a substituted or unsubstituted C₆-C₆₀ arylthio group.

In some embodiments, R₁₀₁ to R₁₀₈, and R₁₁₀ to R₁₂₂ may be each independently one of a hydrogen atom; a deuterium atom; a halogen atom; a hydroxyl group; a cyano group; a nitro group; an amino group; an amidino group; a hydrazine; a hydrazone; a carboxyl group or a salt thereof; a sulfonic acid group or a salt thereof; a phosphoric acid group or a salt thereof; a C₁-C₁₀ alkyl group (for example, a methyl group, an ethyl group, a propyl group, a butyl group, a pentyl group, a hexyl group, or the like); a C₁-C₁₀ alkoxy group (for example, a methoxy group, an ethoxy group, a propoxy group, a butoxy group, a pentoxy group, or the like), a phenyl group, a naphthyl group, an anthryl group, a fluorenyl group, and a pyrenyl group; and a C₁-C₁₀ alkyl group and a C₁-C₁₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, but are not limited thereto.

In Formula 100, R₁₀₉ may be one of a phenyl group, a naphthyl group, an anthryl group, a biphenyl group, a pyridyl group; and a phenyl group, a naphthyl group, an anthryl group, a biphenyl group, and a pyridyl group that are substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

In an embodiment, the compound of Formula 100 may be a compound represented by Formula 100A below, but is not limited thereto:

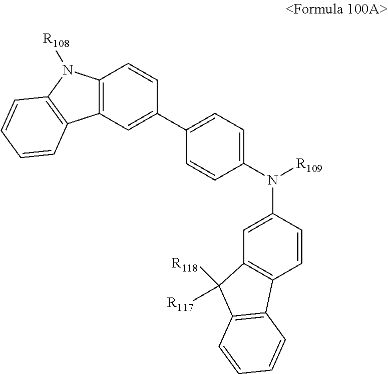

In Formula 100A, R₁₀₈, R₁₀₉, R₁₁₇, and R₁₁₈ may be as defined above.

In some embodiments, at least one of the HIL, HTL, and hole injection and transport layer may include at least one of compounds represented by Formulae 102 to 121 below, but is not limited thereto:

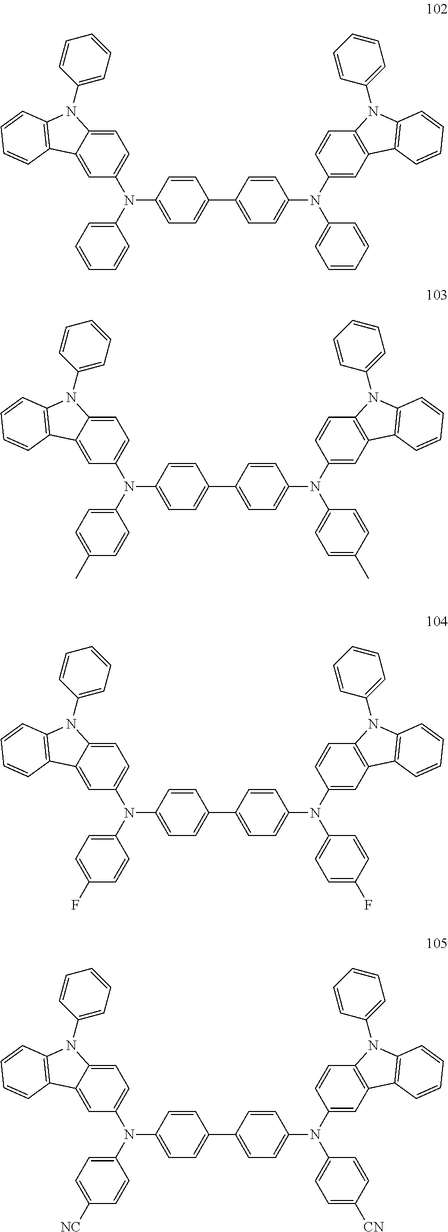 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

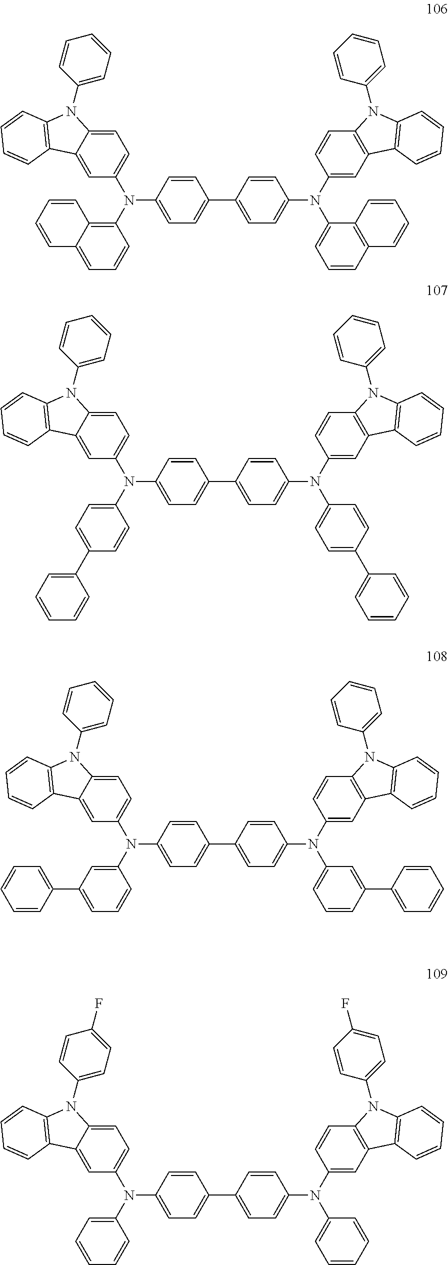 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

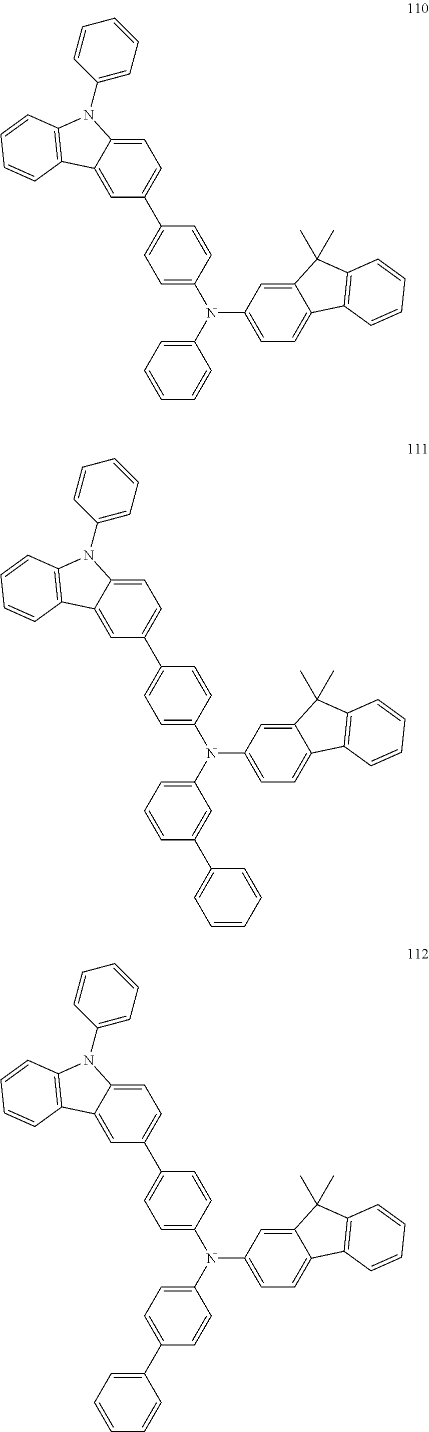 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

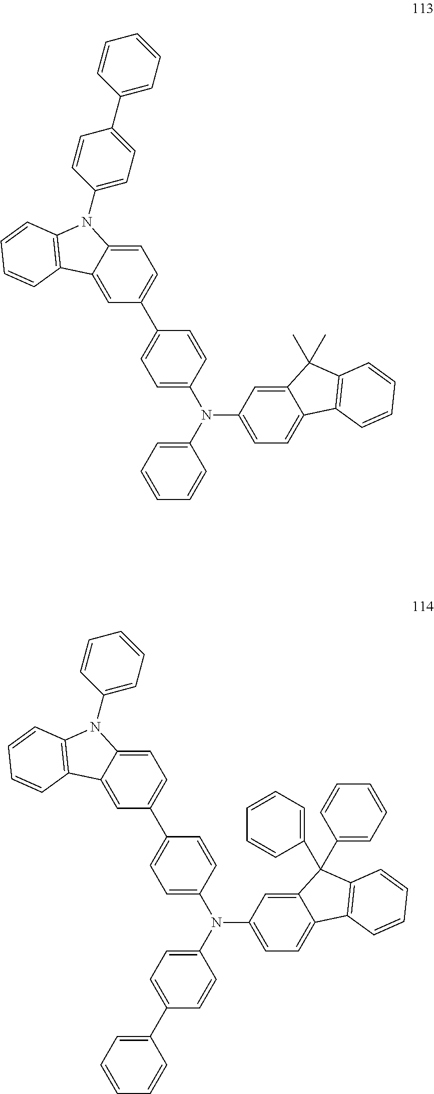 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

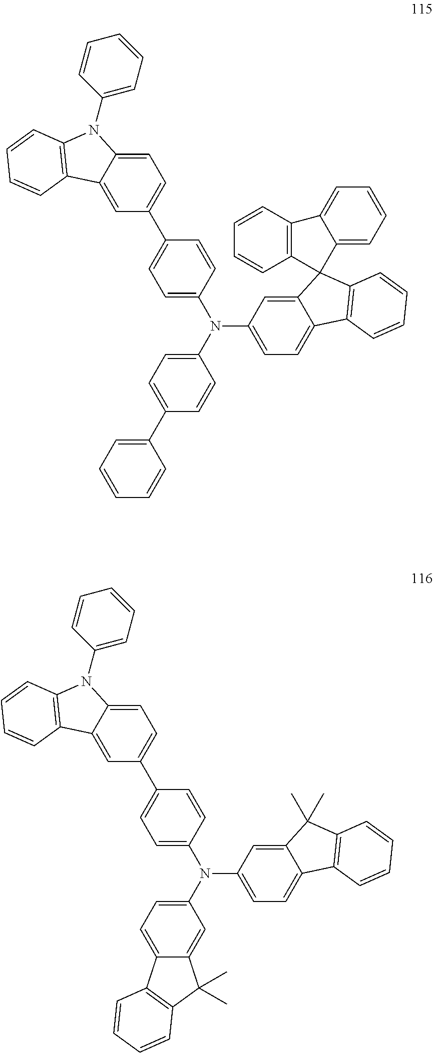 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

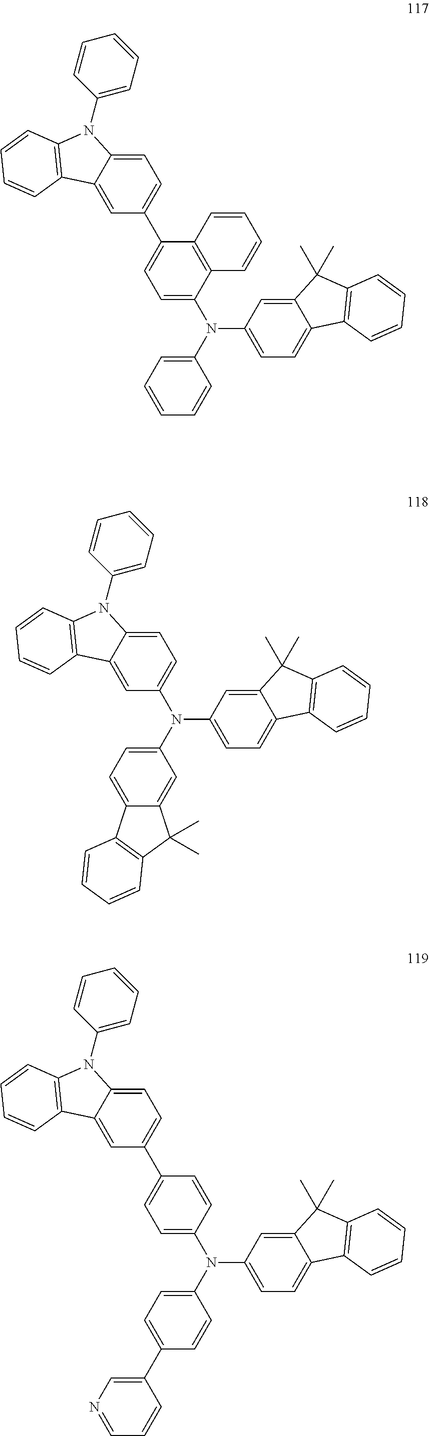 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

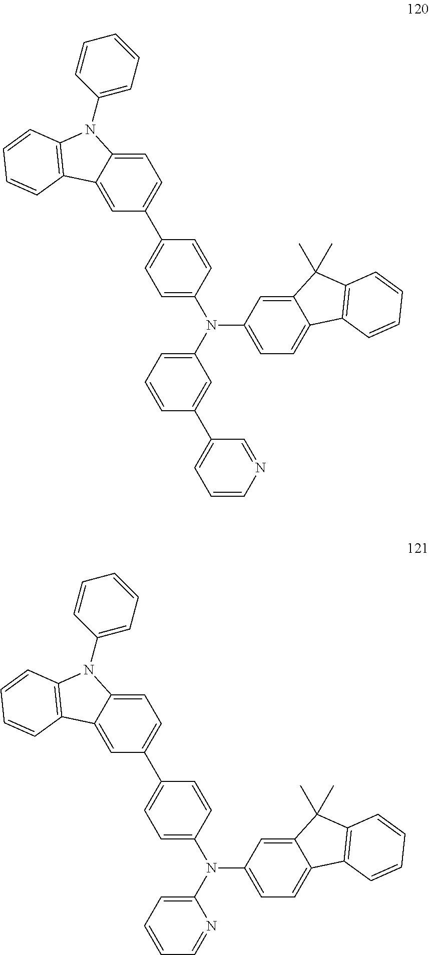 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

At least one of the HIL, HTL, and hole injection and transport layer may further include a charge-generating material for improved layer conductivity, in addition to a known hole injecting material, hole transport material, and/or material having both hole injection and hole transport capabilities as described above.

The charge-generating material may be, for example, a p-dopant. Non-limiting examples of the p-dopant are quinone derivatives, such as tetracyanoquinonedimethane (TCNQ) and, 2,3,5,6-tetrafluoro-tetracyano-1,4-benzoquinonedimethane (F4TCNQ); metal oxides, such as tungsten oxide and molybdenum oxide; and cyano-containing compounds such as HAT-CN (1,4,5,8,9,12-hexaazatriphenylene-hexacarbo-nitrilenitrie).

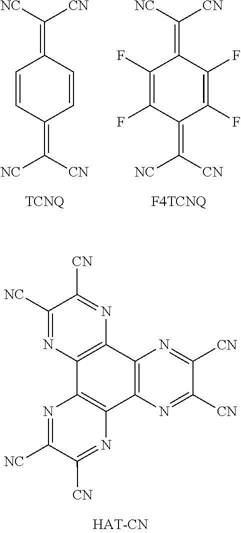 [SMILES: N#CC(C#N)=c1ccc(=C(C#N)C#N)cc1 ; N#CC(C#N)=c1c(F)c(F)c(=C(C#N)C#N)c(F)c1F ; N#Cc1nc2c3nc(C#N)c(C#N)nc3c3nc(C#N)c(C#N)nc3c2nc1C#N]

When the hole injection layer, the hole transport layer, or the hole injection and transport layer further includes a charge generating material, the charge generating material may be, but not limited to, homogeneously dispersed or inhomogeneously distributed in the layer.

A buffer layer may be disposed between at least one of the HIL, HTL and hole injection and transport layer, and the EML. The buffer layer may compensate for an optical resonance distance of light according to a wavelength of the light emitted from the EML, and thus may increase efficiency. The butter layer may include any hole injecting material or hole transporting material that are widely known. In some other embodiments, the buffer layer may include the same material as one of the materials included in the HIL, HTL, and hole injection and transport layer.

Then, an EML may be formed on the HTL, hole injection and transport layer, or buffer layer by vacuum deposition, spin coating, casting, Langmuir-Blodget (LB) deposition, or the like. When the EML is formed using vacuum deposition or spin coating, the deposition and coating conditions may be similar to those for the formation of the HIL, though the conditions for deposition and coating may vary depending on the material that is used to form the EML.

The EML may include at least one of the indole-based compounds of Formula 1. The EML may include a dopant and a host. The indole-based compound of Formula 1 may serve as a fluorescent dopant. For example, the indole-based compound may serve as a blue fluorescent dopant.

Non-limiting examples of the host are, for example, Alq₃ (tris (8-quinolinolate)aluminum, CBP (4,4′-bis(carbazol-9-yl)biphenyl), dmCBP (4,4′-bis(carbazol-9-yl)-2,2′-dimethylbiphenyl), 4,4′-bis(carbazol-9-yl)-2,2′-dimethylbiphenyl), ADN (9,10-di(naphthalene-2-yl)anthracene), 9,10-di(naphthalene-2-yl)anthracene), TCTA, TPBI (1,3,5-tris(N-phenylbenzimidazole-2-yl)benzene), TBADN (2-tert-butyl-9,10-di(naphth-2-yl)anthracene), 3-tert-butyl-9,10-di(naphth-2-yl)anthracene, PVK (poly(n-vinylcabazole), poly(n-vinylcarbazol)), DSA (distyrylarylene), 4,4′-(9,10-anthracenediyldi-2,1-ethenediyl)bis (N,N-diphenyl-benzenamine), E3 (9,9-diethyl-2-(9,9-diethyl-2-(9,9-diethyl-9H-fluoren-2-yl)-9H-fluoren-7-yl)-9H-fluorene), or Compounds 501 to 509 below.

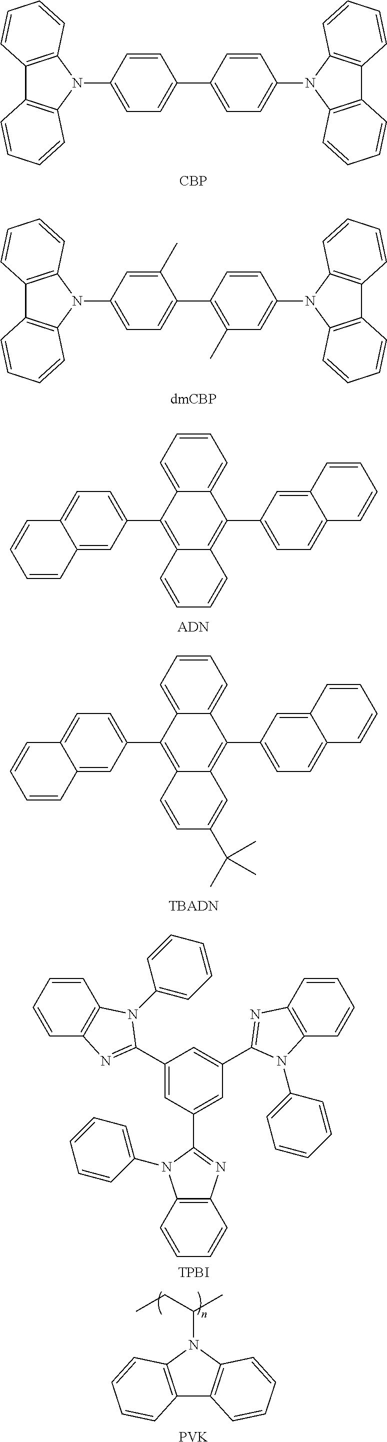

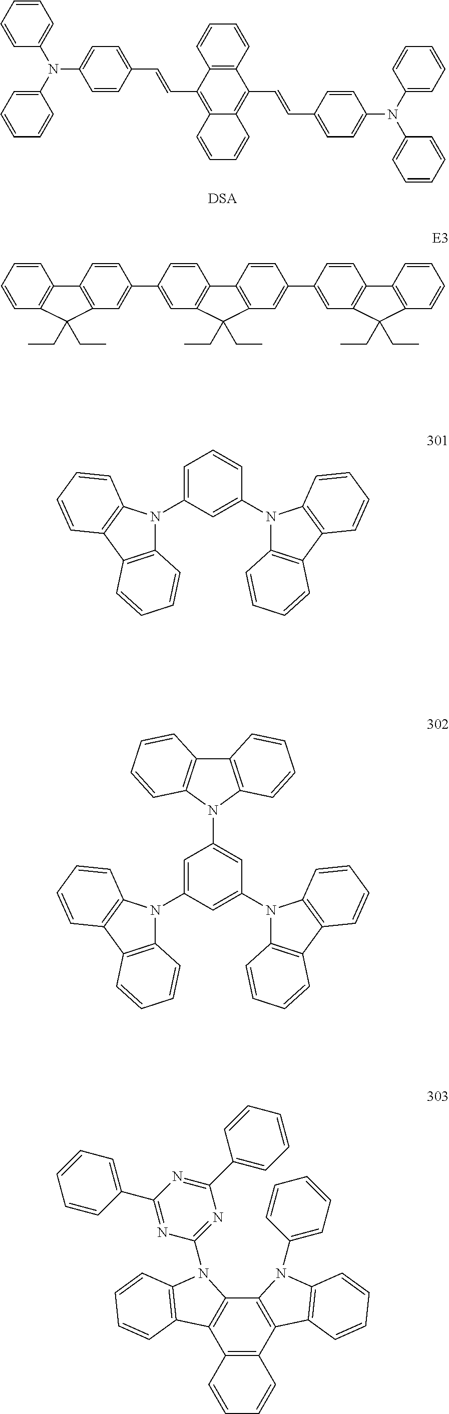

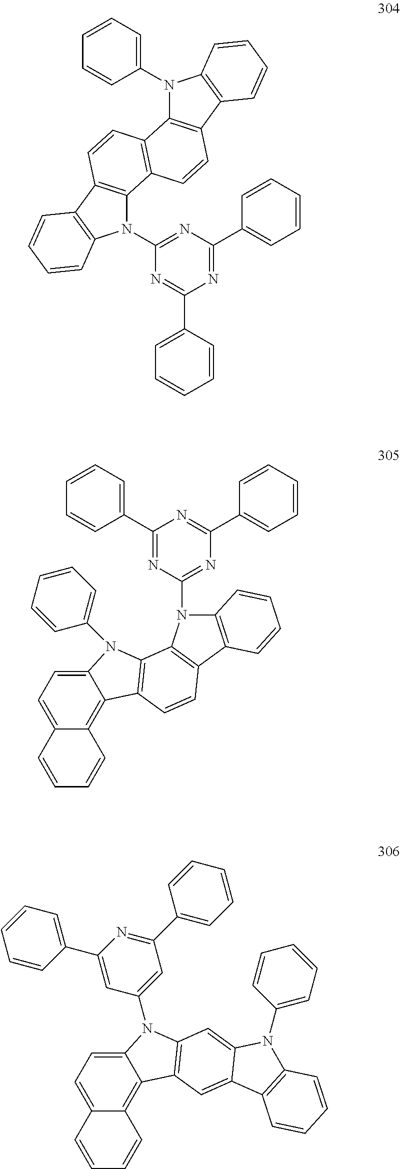 [SMILES: c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1 ; c1ccc(-c2cc(-n3c4cc5c(cc4c4c6ccccc6ccc43)c3ccccc3n5-c3ccccc3)cc(-c3ccccc3)n2)cc1]

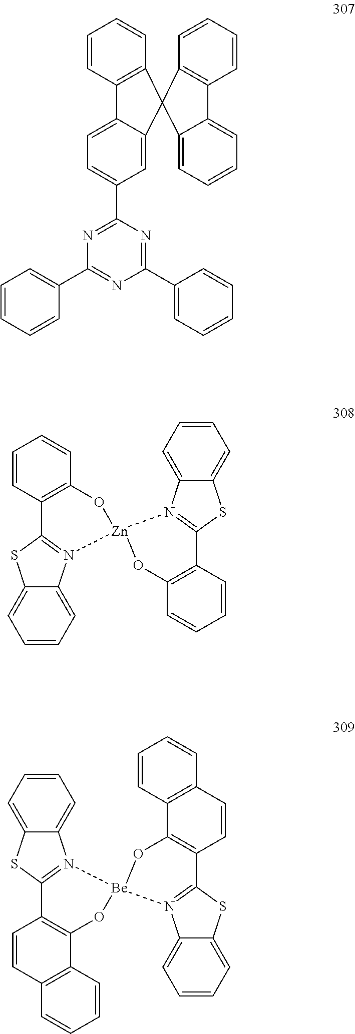

In some embodiments, an anthracene-based compound represented by Formula 400 below may be used as the host.

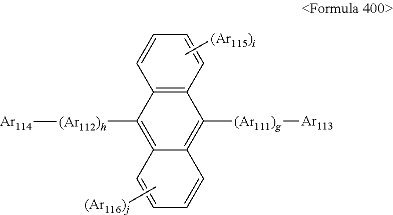

In Formula 400, Ar₁₁₁ and Ar₁₁₂ are each independently a substituted or unsubstituted C₆-C₆₀ arylene group; Ar₁₁₃ to Ar₁₁₆ are each independently a substituted or unsubstituted C₁-C₁₀ alkyl group, or a substituted or unsubstituted C₆-C₆₀ aryl group; and g, h, I, and j are each independently an integer from 0 to 4.

In some embodiments, Ar₁₁₁ and Ar₁₁₂ in Formula 400 may be each independently a phenylene group, a naphthylene group, a phenanthrenylene group, or a pyrenylene group; or a phenylene group, a naphthylene group, a phenanthrenylene group, a fluorenyl group, or a pyrenylene group that are substituted with at least one of a phenyl group, a naphthyl group, and an anthryl group.

In Formula 400 above, g, h, I, and j may be each independently 0, 1, or 2.

In some embodiments, Ar₁₁₃ to Ar₁₁₆ in Formula 400 may be each independently one of a C₁-C₁₀ alkyl group substituted with at least one of a phenyl group, a naphthyl group, and an anthryl group; a phenyl group; a naphthyl group; an anthryl group; a pyrenyl group; a phenanthrenyl group; a fluorenyl group; a phenyl group, a naphthyl group, an anthryl group, a pyrenyl group, a phenanthrenyl group, and a fluorenyl group that are substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a pyrenyl group, a phenanthrenyl group, and a fluorenyl group, but are not limited thereto.

For example, the anthracene-based compound of Formula 400 above may be one of the compounds represented by the following formulae, but is not limited thereto:

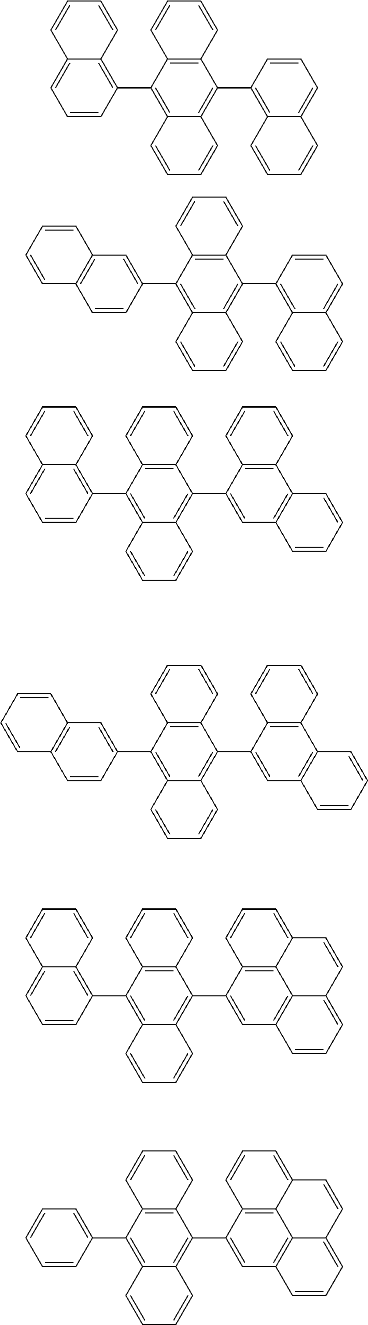

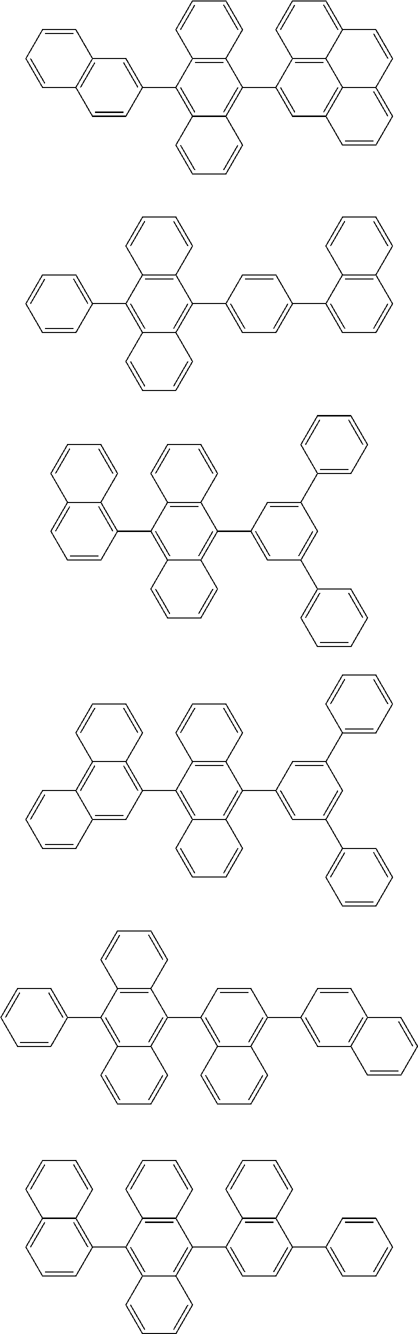

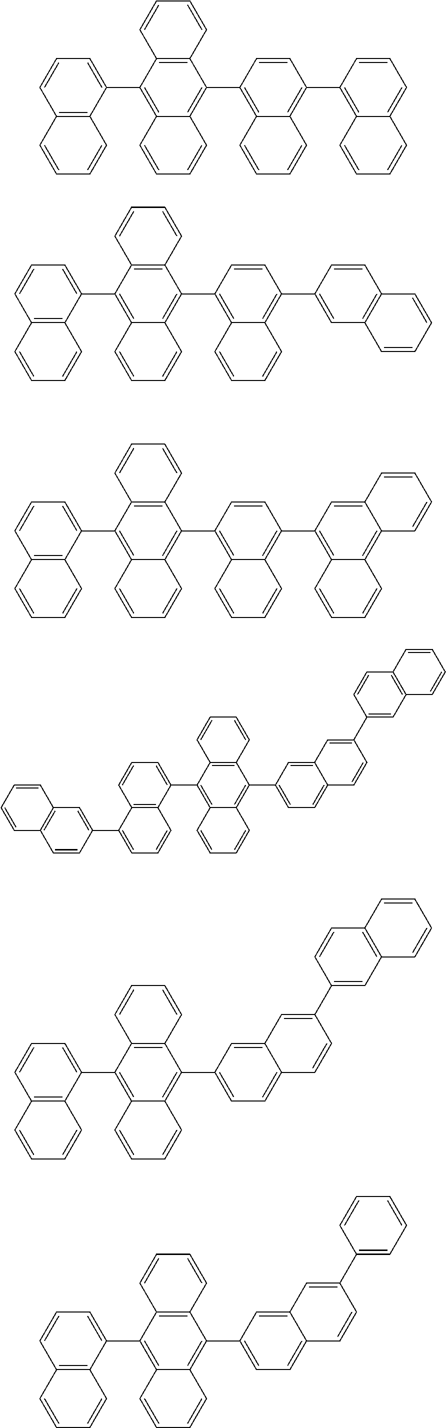

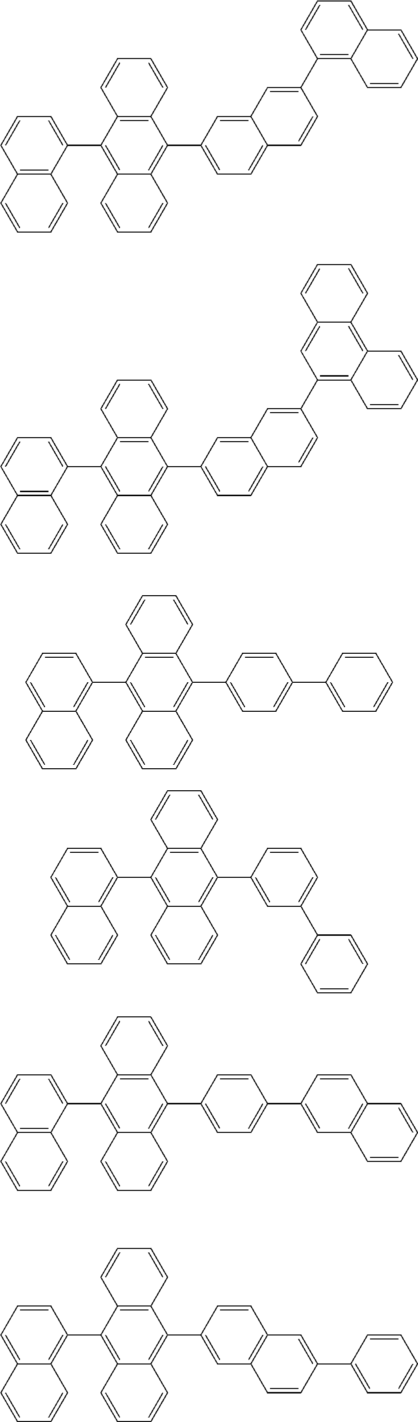

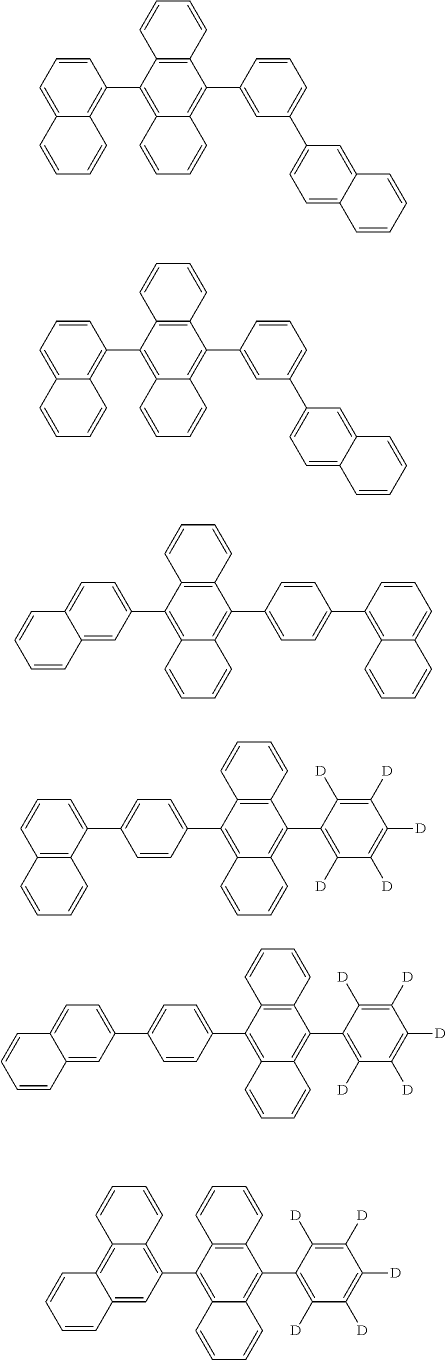

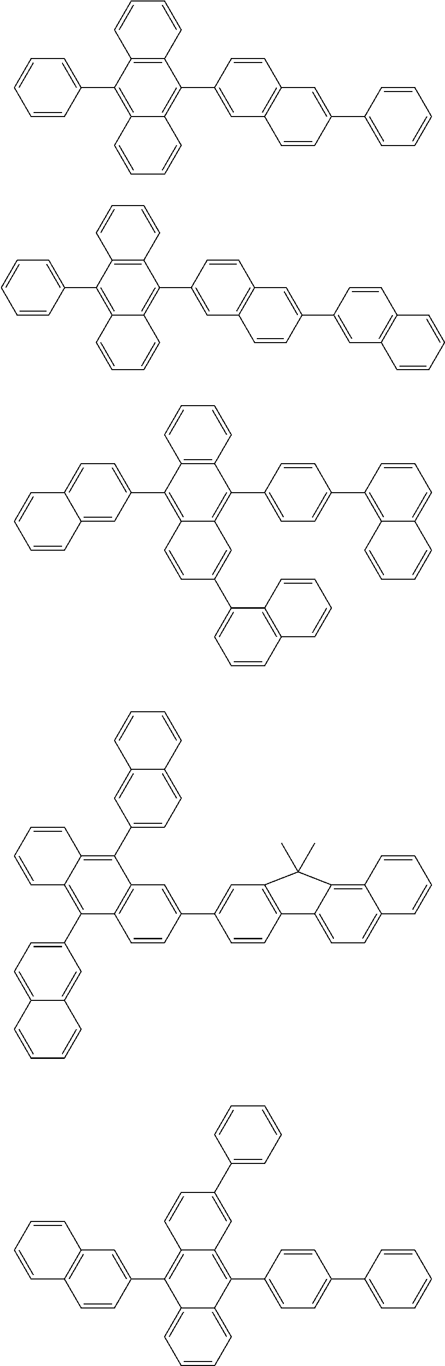

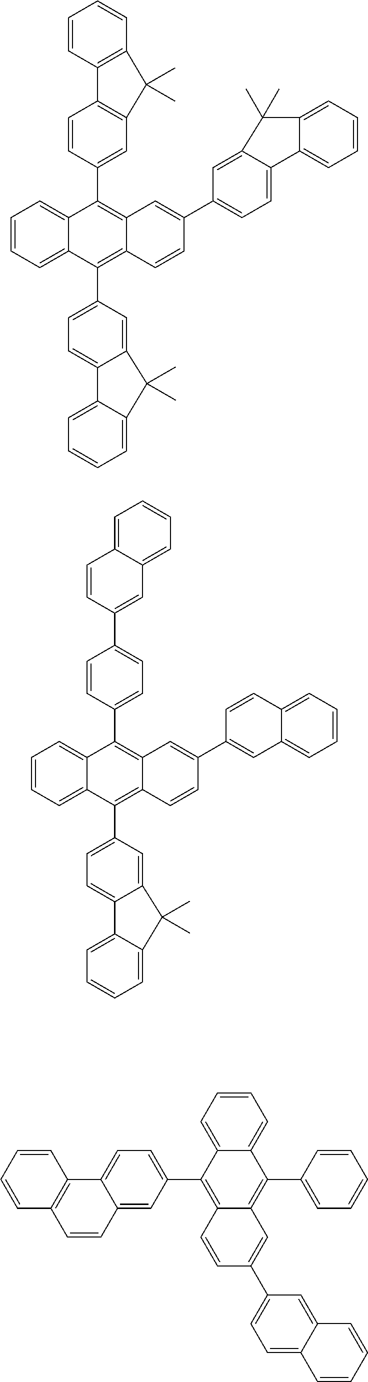

In some embodiments, an anthracene-based compound represented by Formula 401 below may be used as the host.

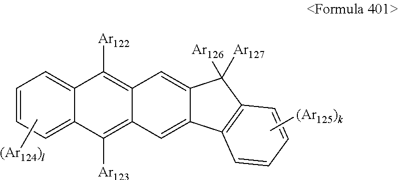

Detailed descriptions of Ar₁₂₂ to Ar₁₂₅ in Formula 401 above may be the same as those described above in conjunction with Ar₁₁₃ of Formula 400.

Ar₁₂₆ and Ar₁₂₇ in Formula 401 above may be each independently a C₁-C₁₀ alkyl group, for example, a methyl group, an ethyl group, or a propyl group.

In Formula 401, k and l may be each independently an integer from 0 to 4, for example, 0, 1, or 2.

For example, the anthracene compound of Formula 401 above may be one of the compounds represented by the following formulae, but is not limited thereto:

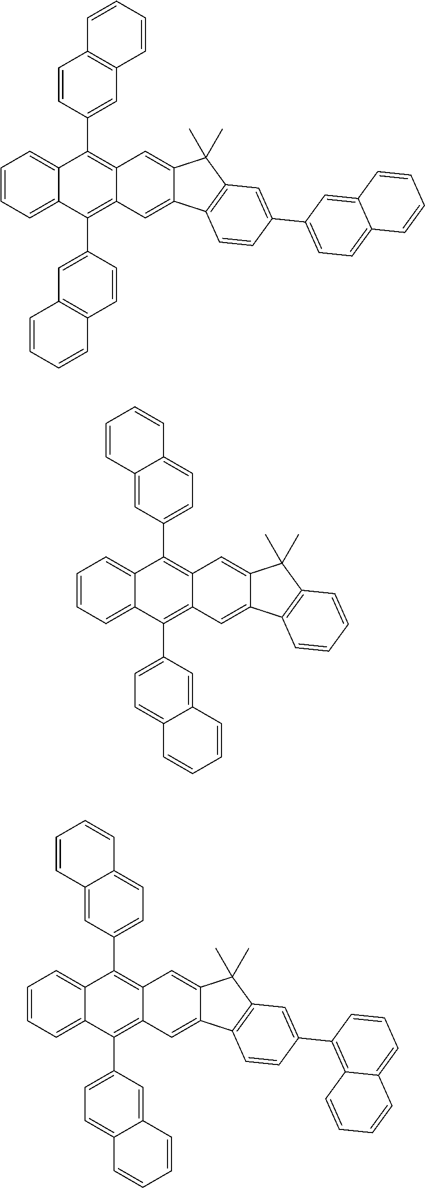

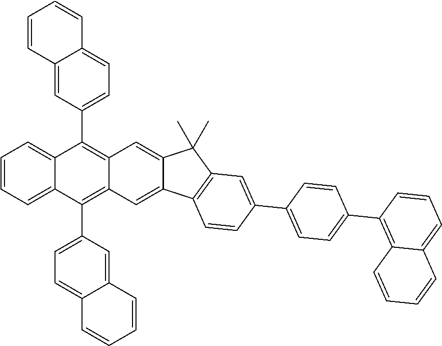 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

The organic light-emitting diode may include a blue subpixel emitting blue light, a green subpixel emitting green light, and a red subpixel emitting red light. The blue subpixel may include a blue EML emitting blue light, wherein the blue EML may include the indole-based compound of Formula 1 above. In some embodiments, the organic light-emitting diode may include a red emission layer, a green emission layer, and/or a blue emission layer that are stacked upon one another to emit white light. The organic light-emitting diode may have any of a variety of structures not limited thereto.

In some embodiments, the blue emission layer may further include a blue dopant, for example, F₂Irpic (bis[3,5-difluoro-2-(2-pyridyl)phenyl](picolinato)iridium(III)), (F₂ppy)₂Ir(tmd), Ir(dfppz)₃, DPVBi (4,4′-bis(2,2′-diphenylethen-1-yl)biphenyl), DPAVBi (4,4′-bis[4-(diphenylamino)styryl]biphenyl), or TBPe (2,5,8,11-tetra-tert-butyl perylene).

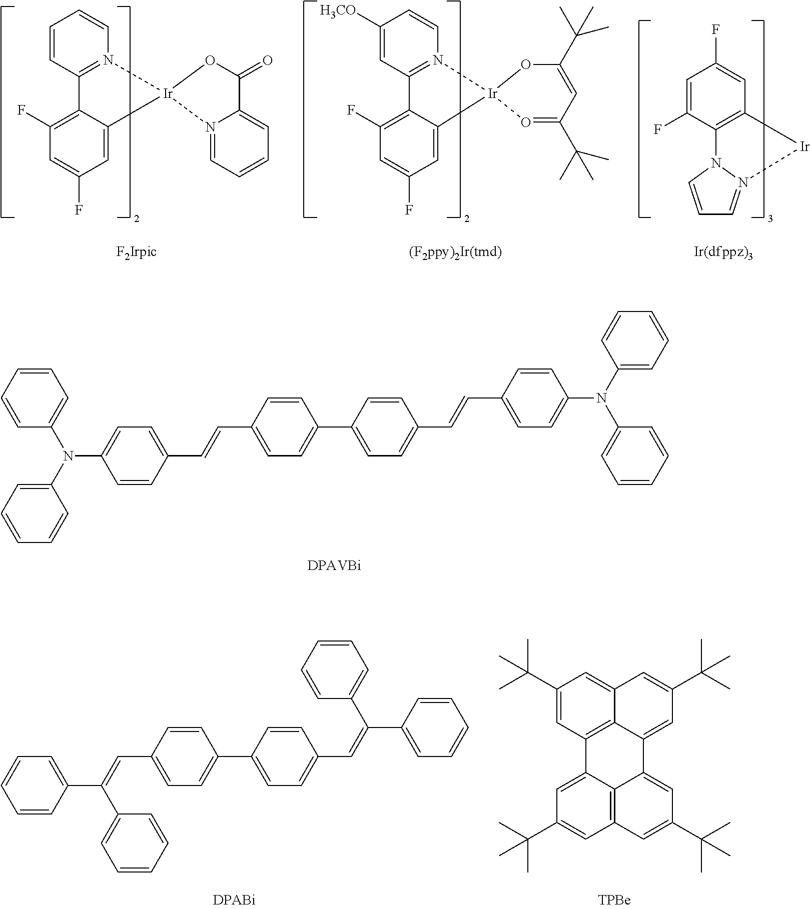

In some other embodiments, the blue emission layer may further include at least one of compounds represented by the following formulae as a blue dopant, but not limited thereto.

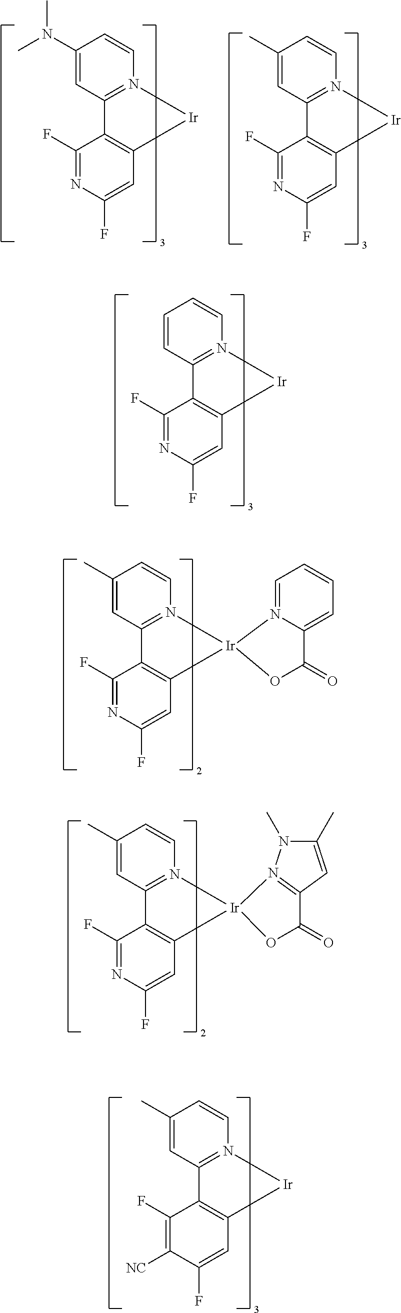

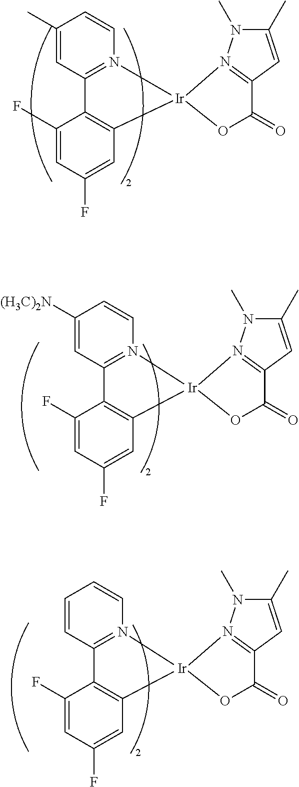

A red emission layer in the red subpixel may include a red dopant. Non-limiting examples of the red dopant are the compounds represented by the following formulae, including PtOEP(Pt(II) octaethylporphine), Ir(piq)₃ (tris(2-phenylisoquinoline)iridium), Btp₂Ir(acac) (bis(2-(2′-benzothienyl)-pyridinato-N,C3′) iridium(acetylacetonate), DCM (4-(dicyanomethylene)-2-methyl-6-[p-(dimethylamino)styryl]-4H-pyran), DCJTB (4-(dicyanomethylene)-2-tert-butyl-6-(1,1,7,7,-tetramethyljulolidyl-9-enyl)-4H-pyran).

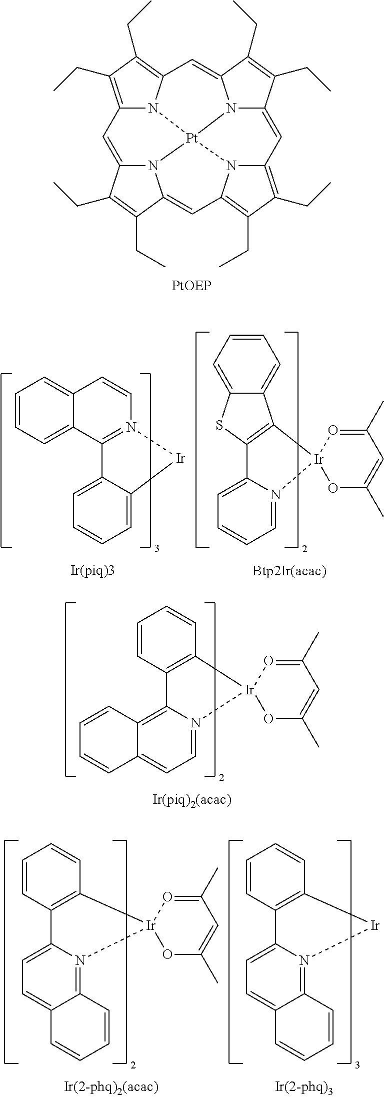

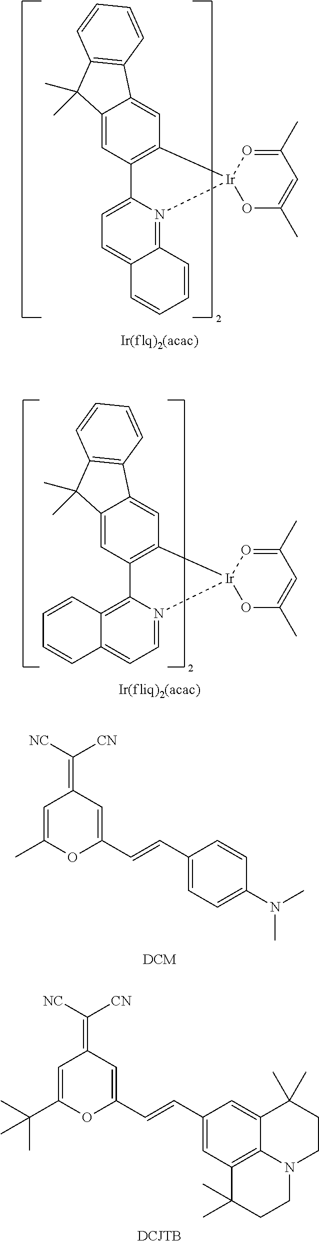

A green emission layer in the green subpixel may include a green dopant. Non-limiting examples of the green dopant are Ir(ppy)₃ (tris(2-phenylpyridine)iridium), Ir(ppy)₂(acac) (bis(2-phenylpyridine)(acetylacetonato)iridium(III)), Ir(mppy)₃ (tris(2-(4-tolyl)phenylpiridine)iridium), C545T (10-(2-benzothiazolyl)-1,1,7,7-tetramethyl-2,3,6,7-tetrahydro-1H,5H,11H-[1]benzopyrano[6,7,8-ij]-quinolizin-11-one).

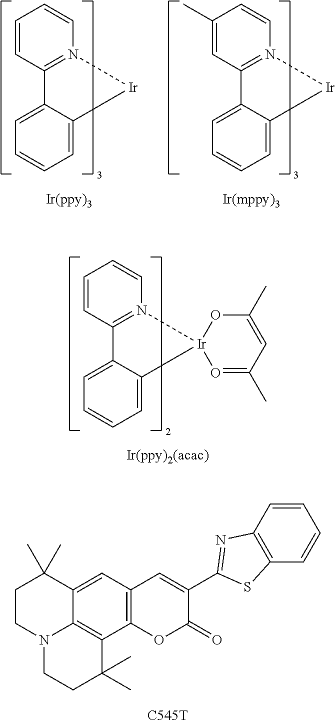

Non-limiting examples of the dopant that may be used in the EML are Pt complexes represented by the following formulae.

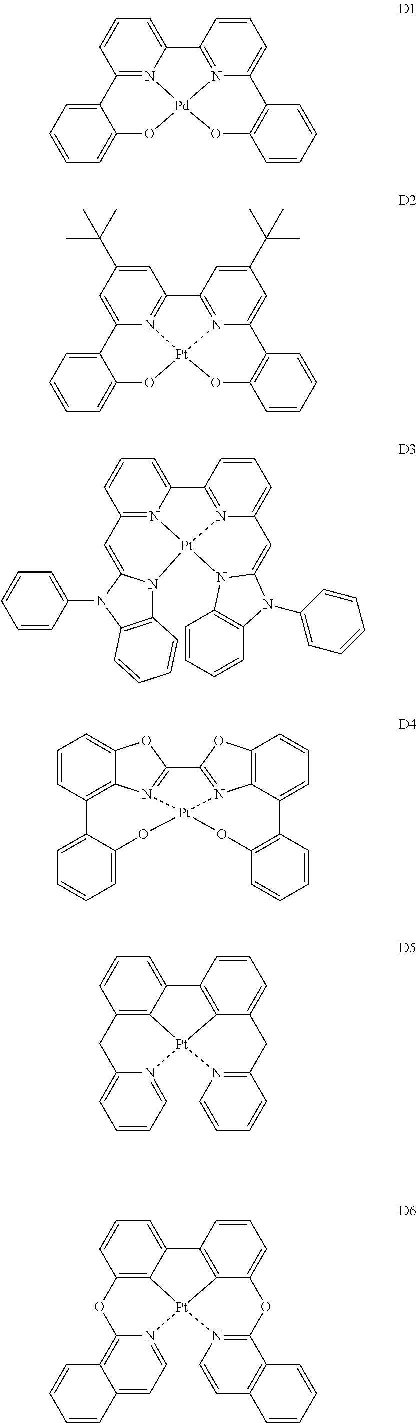

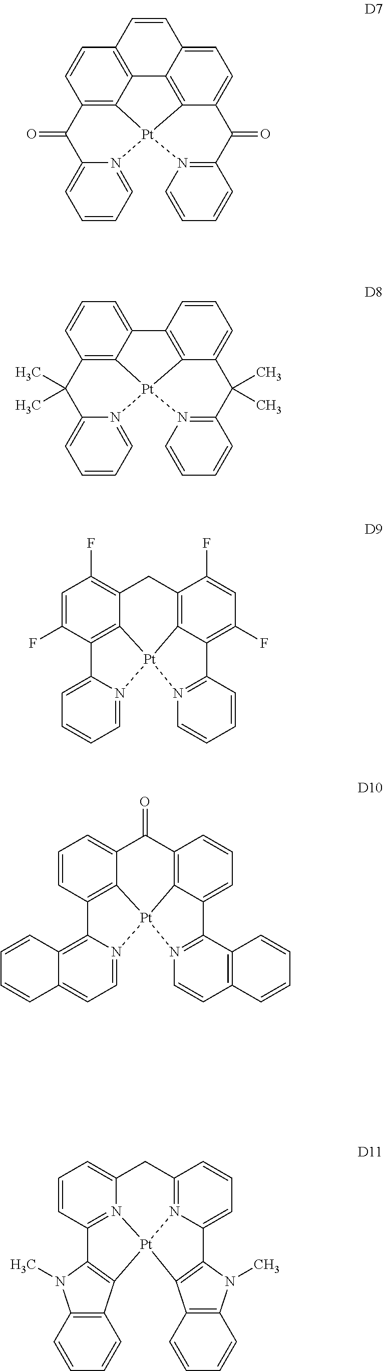

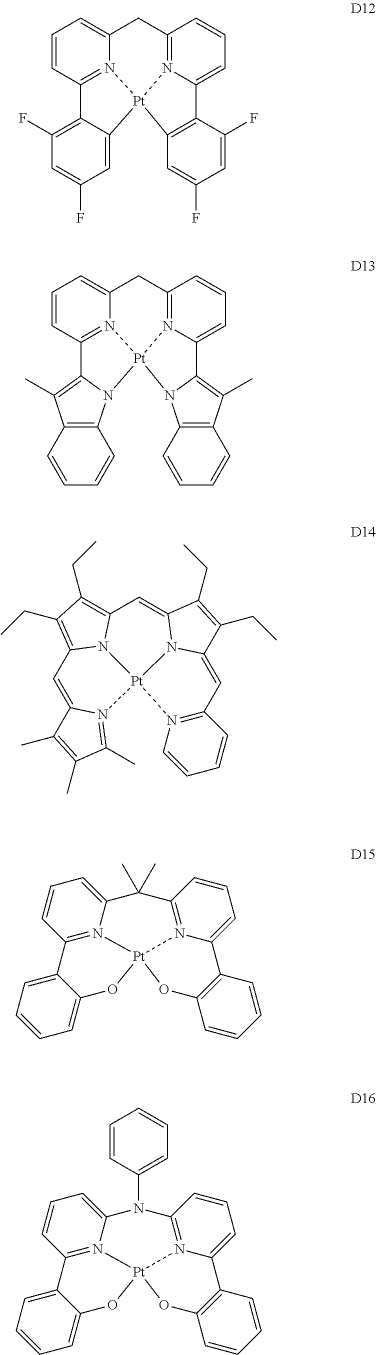

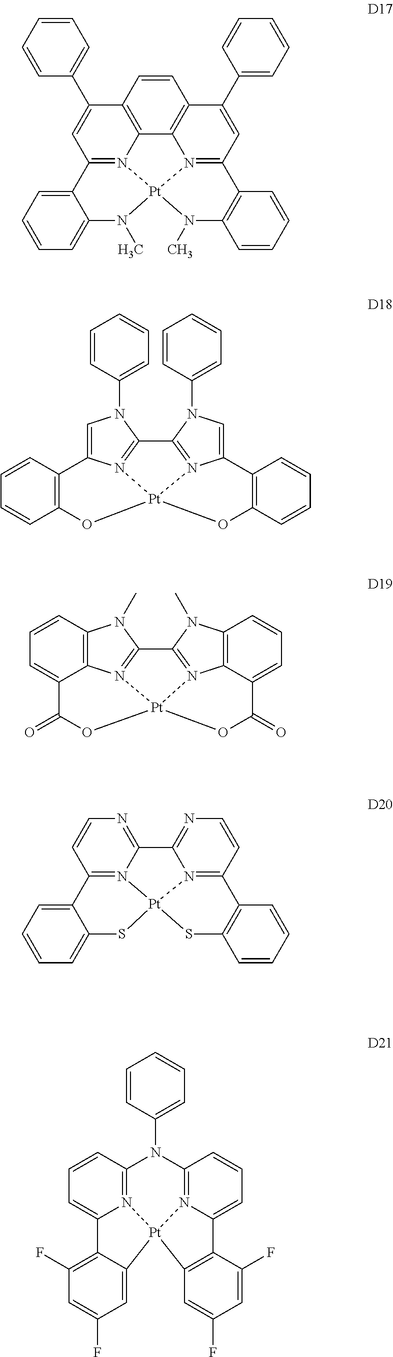

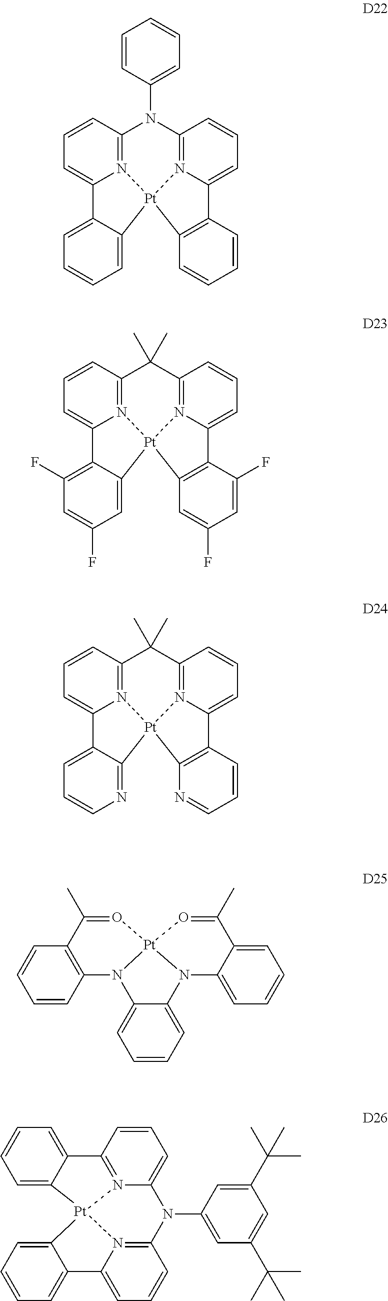

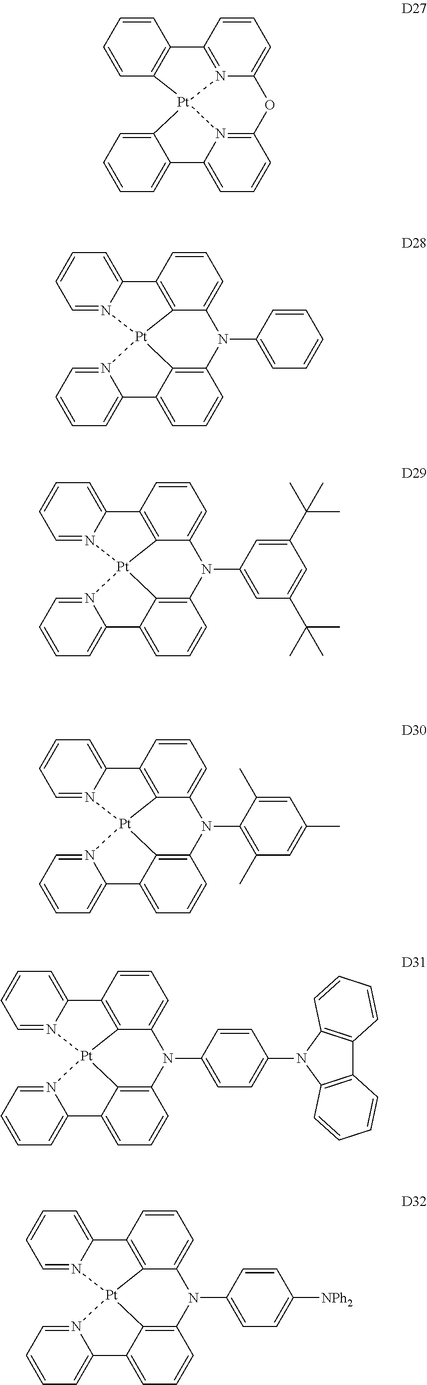

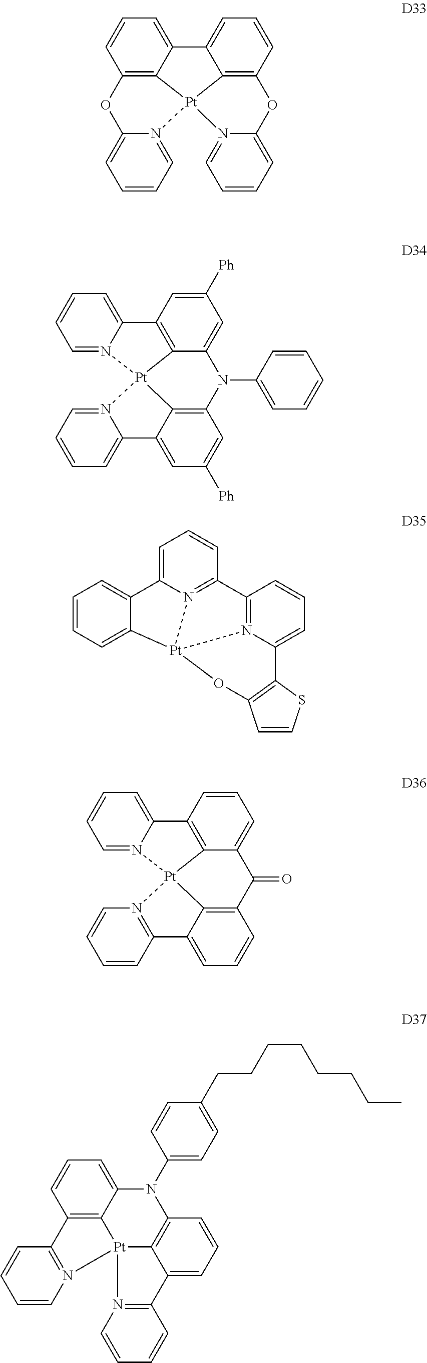

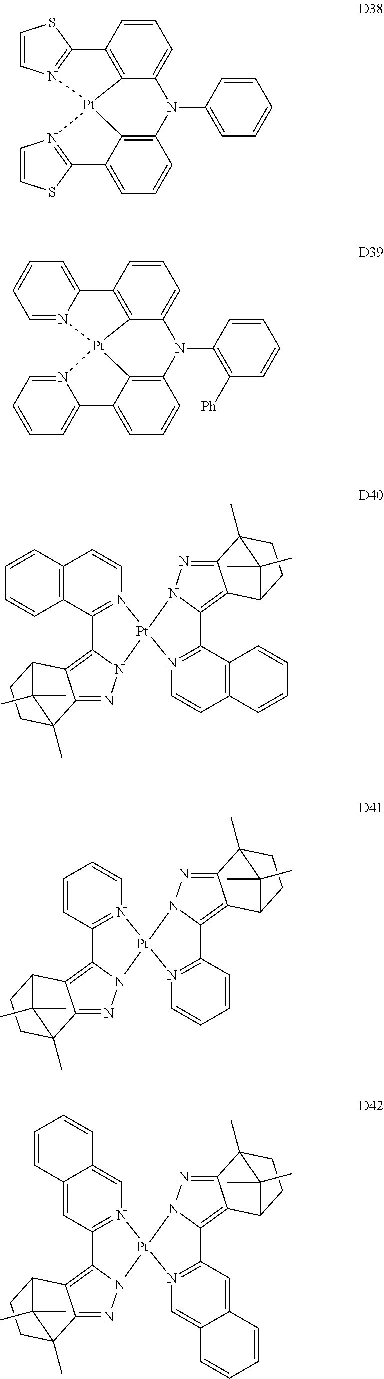

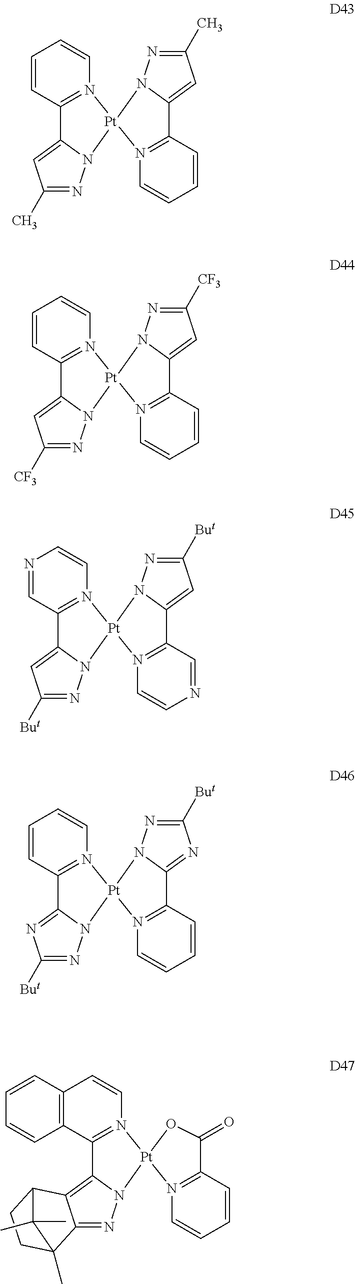

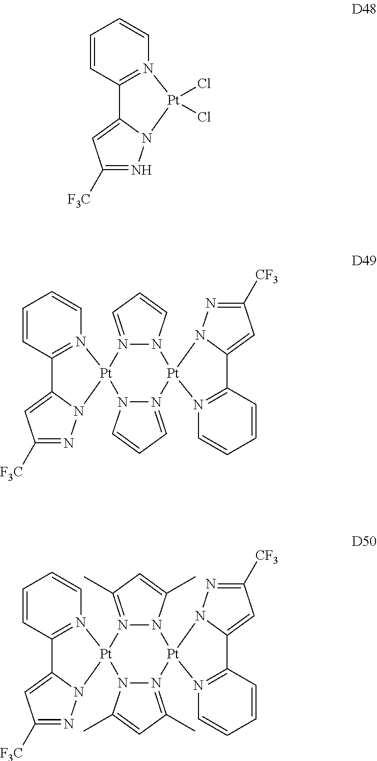

Non-limiting examples of the dopant that may be used in the EML are Os complexes represented by the following formulae.

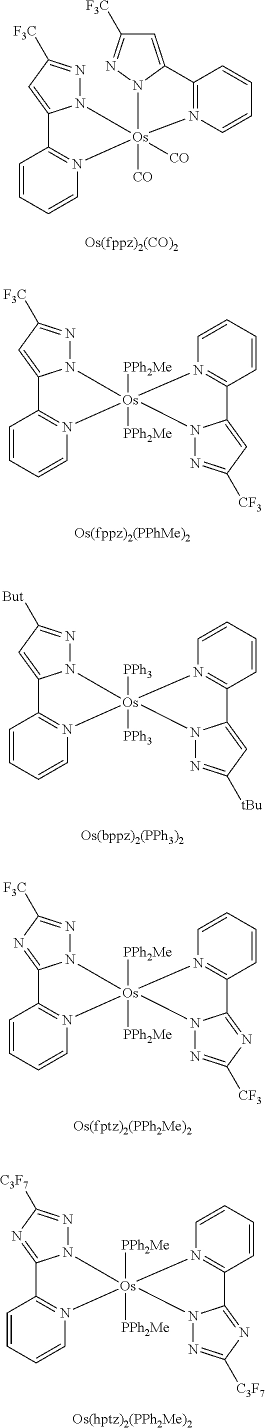

When the EML includes both a host and a dopant, the amount of the dopant may be from about 0.01 to about 15 parts by weight based on 100 parts by weight of the host. However, the amount of the dopant is not limited to this range.

The thickness of the EML may be from about 100 Å to about 1,000 Å, and in some embodiments, may be from about 200 Å to about 600 Å. When the thickness of the EML is within these ranges, the EML may have good light emitting ability without a substantial increase in driving voltage.

Then, an ETL may be formed on the EML by vacuum deposition, spin coating, casting, or the like. When the ETL is formed using vacuum deposition or spin coating, the deposition and coating conditions may be similar to those for the formation of the HIL, though the deposition and coating conditions may vary depending on the material that is used to form the ETL. A material for forming the ETL may be any known material that can stably transport electrons injected from an electron injecting electrode (cathode).

Non-limiting examples of widely known ETL materials are quinoline derivatives, such as Alq₃ (tris(8-quinolinolate)aluminum), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(Naphthalen-1-yl)-3,5-diphenyl-4H-1,2,4-triazole), tBu-PBD(2-(4-biphenylyl)-5-(4-tert-butylphenyl)-1,3,4-oxadiazole), BAlq (see the following formula), Bebq₂ (beryllium bis(benzoquinolin-10-olate), ADN (9,10-di(naphthalene-2-yl)anthracene), Compound 501, and Compound 502.

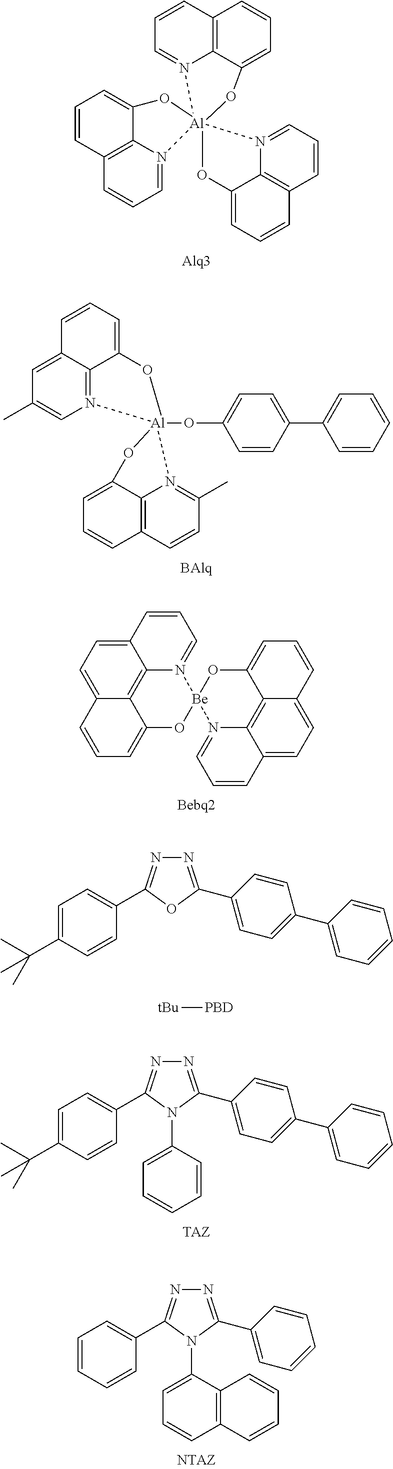

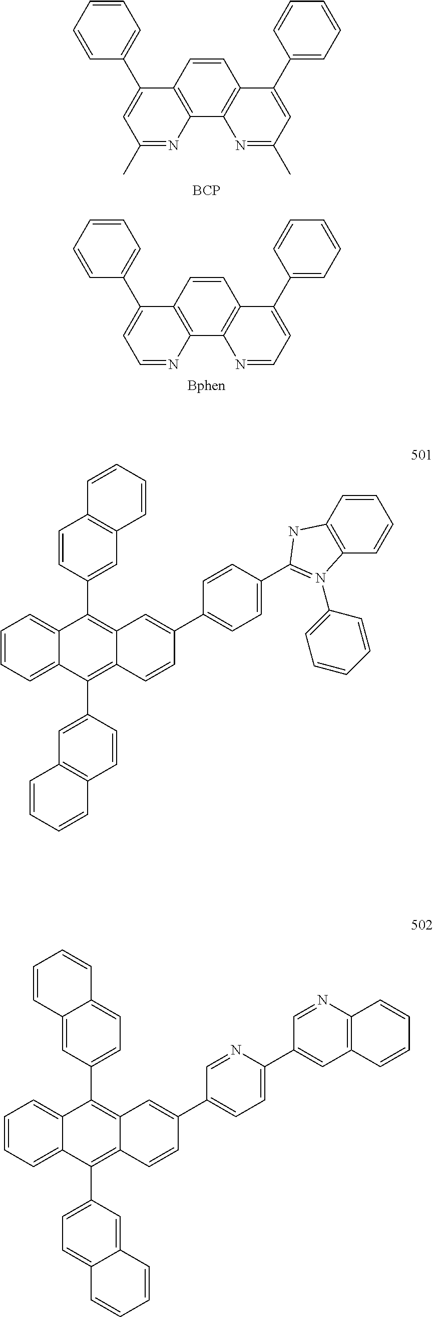

The thickness of the ETL may be from about 100 Å to about 1,000 Å, and in some embodiments, may be from about 150 Å to about 500 Å. When the thickness of the ETL is within these ranges, the ETL may have satisfactory electron transporting ability without a substantial increase in driving voltage.

In some embodiments, the ETL may further include a metal-containing material, in addition to an electron-transporting organic material as described above. The metal-containing material may include a lithium (Li) complex. Non-limiting examples of the Li complex are lithium quinolate (LiQ) and Compound 503 below:

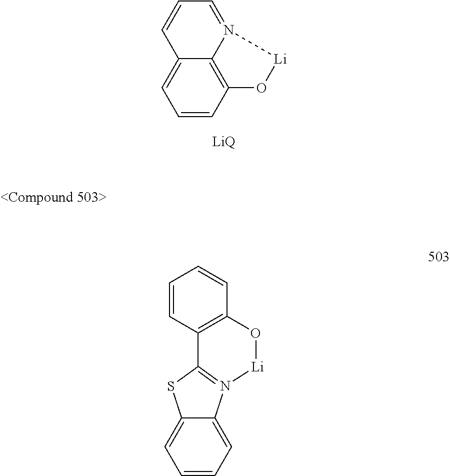

When a phosphorescent dopant is also used in the EML, a hole blocking layer (HBL, not shown) may be formed between the EML and a ETL by using vacuum deposition, spin coating, casting, Langmuir-Blodgett (LB) deposition, or the like, to prevent diffusion of excitons or holes into an ETL. When the HBL is formed using vacuum deposition or spin coating, the conditions for deposition and coating may be similar to those for the formation of the HIL, although the conditions for deposition and coating may vary depending on the material that is used to form the HBL. Any known hole-blocking material may be used. Non-limiting examples of hole-blocking materials are oxadiazole derivatives, triazole derivatives, and phenanthroline derivatives. For example, BCP may be used as a material for forming the HBL.

The thickness of the HBL may be from about 50 Å to about 1000 Å, and in some embodiments, from about 100 Å to about 300 Å. When the thickness of the HBL is within these ranges, the HBL may have improved hole blocking ability without a substantial increase in driving voltage.

Then, an EIL, which facilitates injection of electrons from the cathode, may be formed on the ETL. Any suitable electron-injecting material may be used to form the EIL.

Non-limiting examples of materials for forming the EIL are LiF, NaCl, CsF, Li₂O, and BaO, which are known in the art. The deposition and coating conditions for forming the EIL 18 may be similar to those for the formation of the HIL, though the deposition and coating conditions may vary depending on the material that is used to form the EIL 18.

The thickness of the EIL may be from about 1 Å to about 100 Å, and in some embodiments, may be from about 3 Å to about 90 Å. When the thickness of the EIL is within these ranges, the EIL may have satisfactory electron injection ability without a substantial increase in driving voltage.

The second electrode 17 is disposed on the organic layer 15. The second electrode 17 may be a cathode as an electron injection electrode. A material for forming the second electrode 17 may be a metal, an alloy, an electro-conductive compound, which have a low work function, or a mixture thereof. In this regard, the second electrode 9 may be formed as a thin film type transmission electrode from, for example, lithium (Li), magnesium (Mg), aluminum (Al), aluminum (Al)-lithium (Li), calcium (Ca), magnesium (Mg)-indium (In), or magnesium (Mg)-silver (Ag). In some embodiments, to manufacture a top-emission light-emitting diode, the transmission electrode may be formed of indium tin oxide (ITO) or indium zinc oxide (IZO).

The organic light-emitting diode may be used in a full color display, a lamp, or the like. For example, the organic light-emitting diode may be a full color display.

According to another embodiment of the present invention, an organic light-emitting diode includes: a first substrate including a first subpixel, a second subpixel, and a third subpixel; a plurality of first electrodes corresponding to the first subpixel, the second subpixel, and the third subpixel, respectively; a second electrode as a common electrode for the first subpixel, the second subpixel, and the third subpixel; a first emission layer disposed between the first electrode and the second electrode and emitting first color light; a second emission layer disposed between the first electrode of the second subpixel and the second electrode and emitting second color light; and a third emission layer disposed between the first electrode of the third subpixel and emitting third color light, the first emission layer including at least one of the indole-based compounds of Formula 1. The first electrode may be a transmission electrode or a semi-transmission electrode, and the second electrode may be a reflective electrode. In some embodiments, the first electrode may be a transmission electrode, and the second electrode may be a transmission electrode or a semi-transmission electrode.

Mixed light of the first color light, the second color light, and the third color light emitted in the organic light-emitting diode may be white light. Accordingly, the organic light-emitting diode may be a full color display. For example, the first color light may be blue light. The second color light may be green light, and the third color light may be red light.

The first emission layer of the organic light-emitting diode includes the indole-based compound of Formula 1, and thus may emit first color light (blue light) with high color purity, which nearly complies with the NTSC or sRGB standard (for example, having a y coordinate of 1.0 or less). Thus, the organic light-emitting diode may be used in a high-definition large-screen TV.

The organic light-emitting diode may be a bottom-emission organic light-emitting diode with a transmissive or semi-transmissive electrode as the first electrode and a reflective electrode as the second electrode. In some other embodiments, the organic light-emitting diode may be a top-emission organic light-emitting diode with a reflective electrode as the first electrode and a transmissive or semi-transmissive electrode as the second electrode.

The organic light-emitting diode including the indole-based compound of Formula 1 above may emit blue light having high color purity (for example, having a y coordinate of about 1.0 or less) nearly complying with the sRGB standard, and thus may not use an additional structure, for example, for compensating for color purity of blue light, which consequently may low manufacturing costs.

The full color display of the organic light-emitting diode may be applicable in a TV, a PC monitor, a mobile communication terminal, an MP3 player, a car navigation system, and the like.

Hereinafter, the present invention will be described in detail with reference to the following synthesis examples and other examples. However, these examples are for illustrative purposes only and are not intended to limit the scope of the present invention.

### SYNTHESIS EXAMPLES

2,3-diphenylindole, 2,3-bis(2-fluorophenyl)-1H-indole, and 2,3-di(naphthalene-1-yl)-1H-indole were synthesized as below by a method disclosed in document (Tetrahedron Letters 52 (2011), p. 1916-1918).

### Synthesis Example 1

### Synthesis of Compound 1

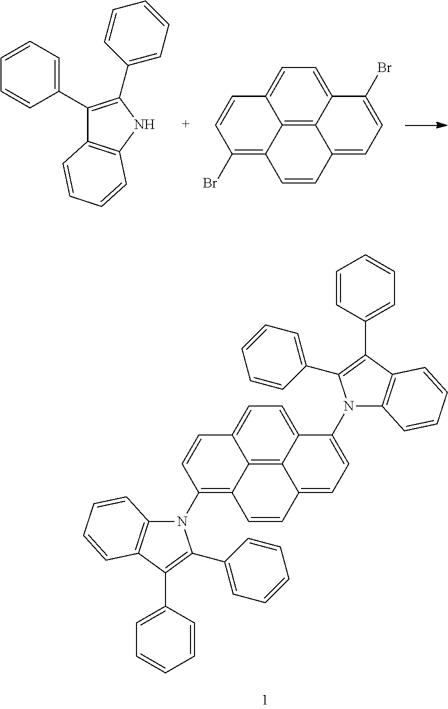

1.9 g (7.2 mmole) of 2,3-diphenylindole, 1.3 g (3.6 mmole) of 1,6-dibromopyrene, 40 mg (0.18 mol) of palladium(II) acetate (Pd(OAc)₂), 108 mg (0.54 mmol) of P(t-Bu)₃, and 1.0 g (10.9 mmol) of sodium t-butoxide were added into 100 mL of toluene under a nitrogen atmosphere, and then refluxed for about 12 hours. After completion of the reaction, the solvent was removed by evaporation. The resultant was washed with 1,000 mL of methylene chloride and 1,000 mL of water. Then an organic layer was collected and dried using anhydrous magnesium sulfate, followed by recrystallization and silicagel chromatography to obtain 0.3 g of Compound 1 (Yield: 10%).

MS (MALDI-TOF) m/z: 736 [M]+.

### Synthesis Example 2

### Synthesis of Compound 21

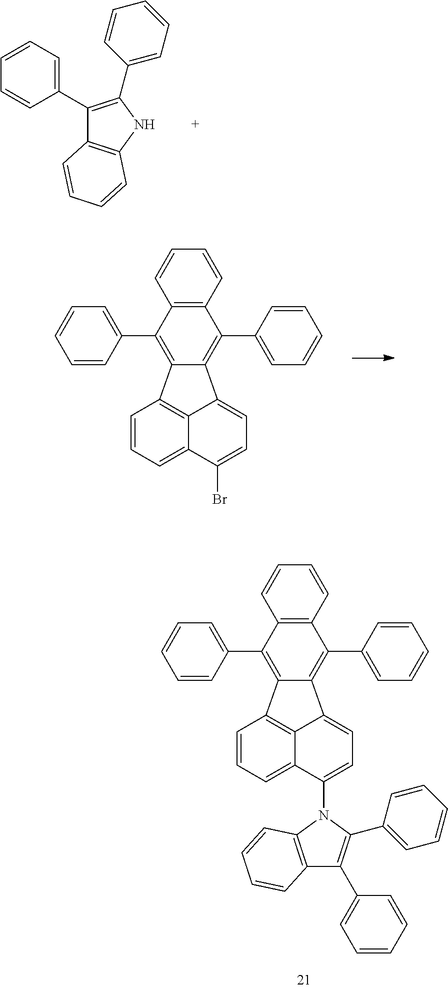 [SMILES: c1ccc(-c2[nH]c3ccccc3c2-c2ccccc2)cc1 ; "+" ; Brc1ccc2c3c(cccc13)-c1c-2c(-c2ccccc2)c2ccccc2c1-c1ccccc1 ; c1ccc(-c2c3c(c(-c4ccccc4)c4ccccc24)-c2ccc(-n4c(-c5ccccc5)c(-c5ccccc5)c5ccccc54)c4cccc-3c24)cc1]

About 0.3 g of Compound 21 (Yield: 9%) was synthesized in the same manner as in Synthesis Example 1, except that 3-bromo-7,12-diphenylbenzo[k]fluoranthene instead of 1,6-dibromopyrene was used.

MS (MALDI-TOF) m/z: 671 [M]+.

### Synthesis Example 3

### Synthesis of Compound 38

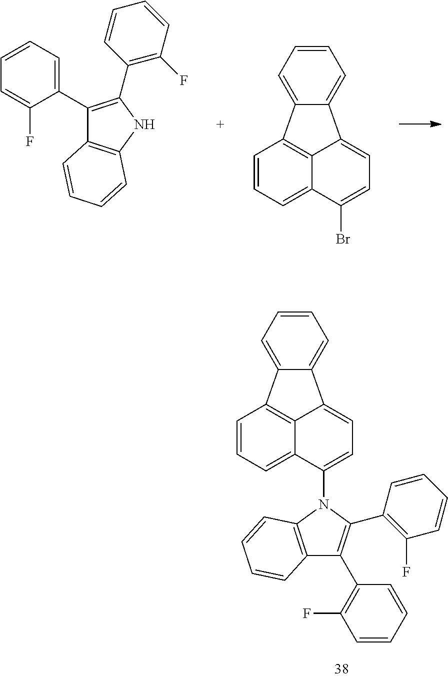

About 0.4 g of Compound 38 (Yield: 7%) was synthesized in the same manner as in Synthesis Example 1, except that 2,3-bis(2-fluorophenyl)-1H-indole and 3-bromofluoranthene, instead of 1,6-dibromopyrene and 3-bromo-7,12-diphenylbenzo[k]fluoranthene, respectively, were used.

MS (MALDI-TOF) m/z: 505 [M]+

### Synthesis Example 4

### Synthesis of Compound 41

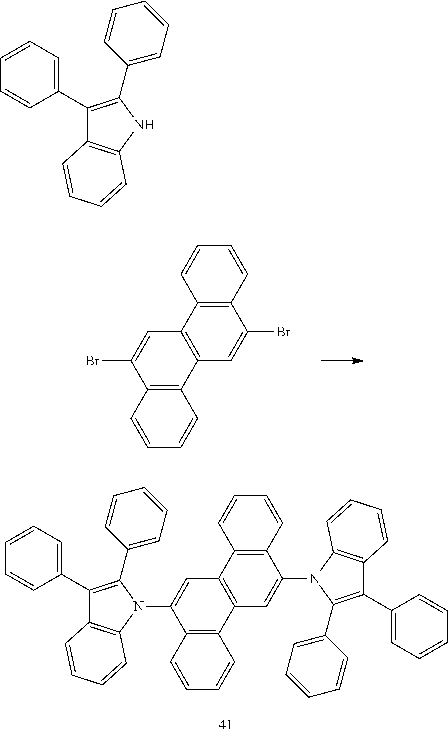

About 0.2 g of Compound 41 (Yield: 5%) was synthesized in the same manner as in Synthesis Example 1, except that 6,12-dibromochrysene instead of 1,6-dibromopyrene was used.

MS (MALDI-TOF) m/z: 762 [M]+.

### Synthesis Example 5

### Synthesis of Compound 52

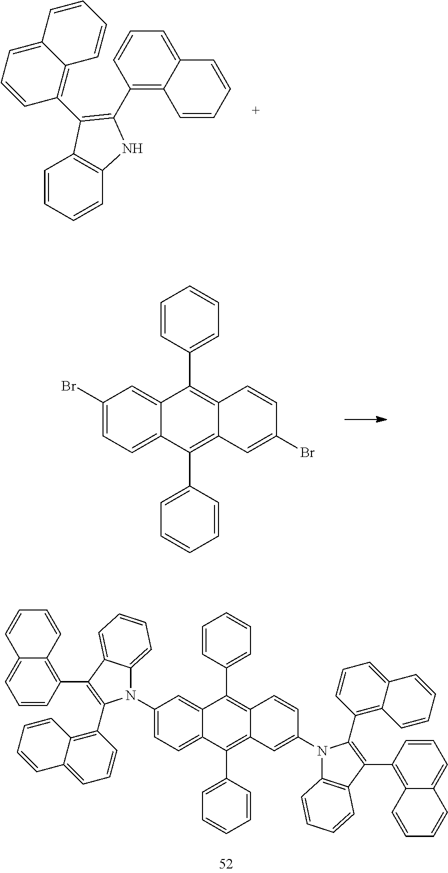 [SMILES: c1ccc2c(-c3[nH]c4ccccc4c3-c3cccc4ccccc34)cccc2c1 ; Brc1ccc2c(-c3ccccc3)c3cc(Br)ccc3c(-c3ccccc3)c2c1 ; c1ccc(-c2c3ccc(-n4c(-c5cccc6ccccc56)c(-c5cccc6ccccc56)c5ccccc54)cc3c(-c3ccccc3)c3ccc(-n4c(-c5cccc6ccccc56)c(-c5cccc6ccccc56)c5ccccc54)cc23)cc1]

About 1.2 g of Compound 52 (Yield: 30%) was synthesized in the same manner as in Synthesis Example 1, except that 2,3-di(naphthalene-1-yl)-1H-indole and 2,6-dibromo-9,10-diphenylanthracene, instead of 1,6-dibromopyrene and 3-bromo-7,12-diphenylbenzo[k]fluoranthene, respectively, were used.

### Example 1

A 15 Ω/cm² (1200 Å) ITO glass substrate (available from Corning Co.) was cut to a size of 50 mm×50 mm×0.5 mm, ultrasonically washed with isopropyl alcohol and pure water, each for 5 minutes, and washed again with UV ozone for 30 minutes. m-MTDATA was vacuum-deposited on the ITO glass substrate to form an HIL having a thickness of about 600 Å on the anode, and then α-NPD was vacuum-deposited on the HIL to form a HTL having a thickness of about 300 Å.

Compound 1 (dopant) and 2-tert-butyl-9,10-di(naphth-2-yl)anthracene (TBADN, host) were co-deposited on the HTL at a deposition rate of about 0.05 Å/sec and about 1 Å/sec, respectively, to form an EML having a thickness of about 200 Å.

Then, Alq₃ was deposited on the EML to form an ETL having a thickness of about 300 Å, and then LiF was deposited on the ETL to form an EIL having a thickness of about 10 Å. Then, Al was deposited on the EIL to form cathode having a thickness of about 2000 Å, thereby completing the manufacture of an organic light-emitting diode.

### Example 2

An organic light-emitting diode was manufactured in the same manner as in Example 1, except that Compound 21 instead of Compound 1 was used as a dopant of the EML.

### Example 3

An organic light-emitting diode was manufactured in the same manner as in Example 1, except that Compound 38 instead of Compound 1 was used as a dopant of the EML.

### Example 4

An organic light-emitting diode was manufactured in the same manner as in Example 1, except that Compound 41 instead of Compound 1 was used as a dopant of the EML.

### Example 5

An organic light-emitting diode was manufactured in the same manner as in Example 1, except that Compound 52 instead of Compound 1 was used as a dopant of the EML.

### Comparative Example 1

An organic light-emitting diode was manufactured in the same manner as in Example 1, except that Compound A-1 represented by the formula below instead of Compound 1 was used as a dopant of the EML.

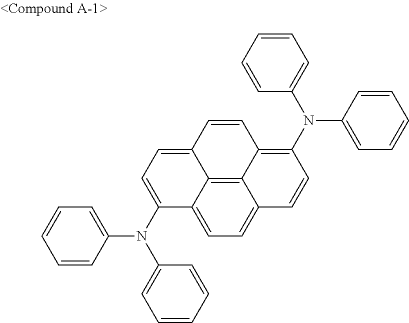 [SMILES: c1ccc(N(c2ccccc2)c2ccc3ccc4c(N(c5ccccc5)c5ccccc5)ccc5ccc2c3c54)cc1]

### Comparative Example 2

An organic light-emitting diode was manufactured in the same manner as in Example 1, except that Compound A-2 represented by the formula below instead of Compound 1 was used as a dopant of the EML.

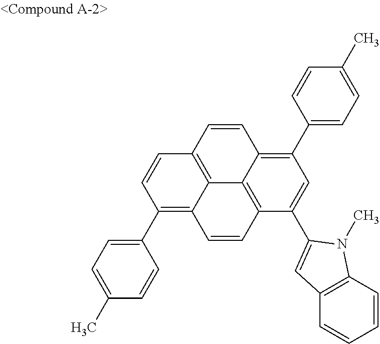 [SMILES: Cc1ccc(-c2ccc3ccc4c(-c5ccc(C)cc5)cc(-c5cc6ccccc6n5C)c5ccc2c3c45)cc1]

### Comparative Example 3

An organic light-emitting diode was manufactured in the same manner as in Example 1, except that Compound A-3 represented by the formula below instead of Compound 1 was used as a material of the ETL.

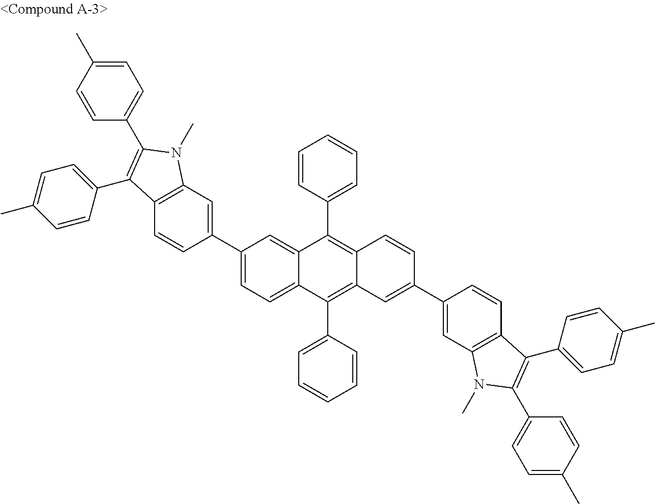

### Evaluation Example

Luminances, current densities, and color coordinates of the organic light-emitting diodes of Examples 1 to 5 and Comparative Examples 1 to 3 were measured using a PR650 (Spectroscan) Source Measurement Unit. (available from Photo Research, Inc.). The results are shown in Table 1 below.

TABLE 1

| | | Luminance | Current density | |
|---|---|---|---|---|
| Example | EML | (cd/m²) | (mA/cm²) | Color coordinates |
| Example 1 | Compound1/TBADN | 700 | 15 | (0.14, 0.088) |
| Example 2 | Compound21/TBADN | 700 | 16 | (0.14, 0.093) |
| Example 3 | Compound38/TBADN | 700 | 19 | (0.14, 0.094) |
| Example 4 | Compound41/TBADN | 700 | 17 | (0.14, 0.092) |
| Example 5 | Compound52/TBADN | 700 | 16 | (0.14, 0.099) |
| Comparative | Compound A-1/TBADN | 700 | 21 | (0.14, 0.19) |
| Example 1 | | | | |
| Comparative | Compound A-2/TBADN | 700 | 48 | (0.15, 0.10) |
| Example 2 | | | | |
| Comparative | Compound A-3/TBADN | 700 | 22 | (0.15, 0.19) |
| Example 3 | | | | |

Referring to Table 1, the organic light-emitting diodes of Examples 1 to 10 were found to have better performance in terms of luminance and electrical characteristics, as compared with the organic light-emitting diodes of Comparative Examples 1 to 3.

As described above, according to the one or more of the above embodiments of the present invention, an organic light-emitting diode including an indole-based compound of Formula 1 above may have high performance, for example, a low driving voltage, a high luminance, a high efficiency, and a long lifetime.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. An indole-based compound represented by Formula 1 below: 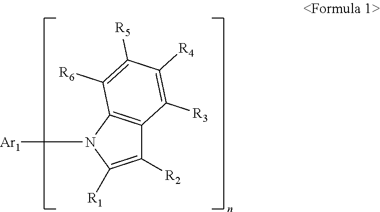
wherein, in Formula 1,
Ar₁ is one of a substituted or unsubstituted pyrene, a substituted or unsubstituted chrysene, a substituted or unsubstituted fluoranthene, a substituted or unsubstituted benzo[k]fluoranthene, or a substituted or unsubstituted anthracene;
n is 1 or 2, wherein, when n is 2, the two Ar₁'s are identical to or different from each other; and
R₁ to R₆ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, —Si(Q₁)(Q₂)(Q₃), or —N(Q₄)(Q₅) (where Q₁ to Q₅ are each independently a substituted or unsubstituted C₁-C₆₀ alkyl group, a substituted or unsubstituted C₆-C₆₀ aryl group, or a substituted or unsubstituted C₂-C₆₀ heteroaryl group).

2. An indole-based compound of claim 1, wherein Ar₁ is a group represented by one of Formulae 2A to 2P below: 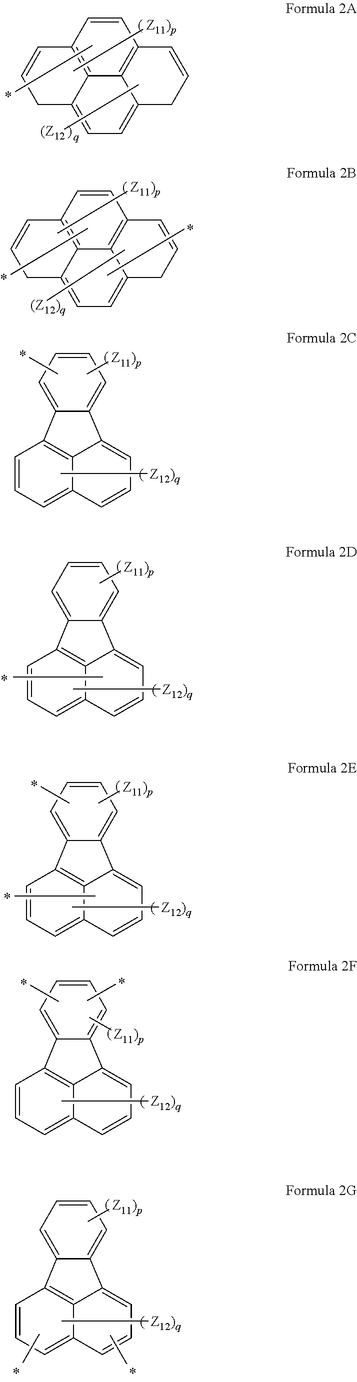 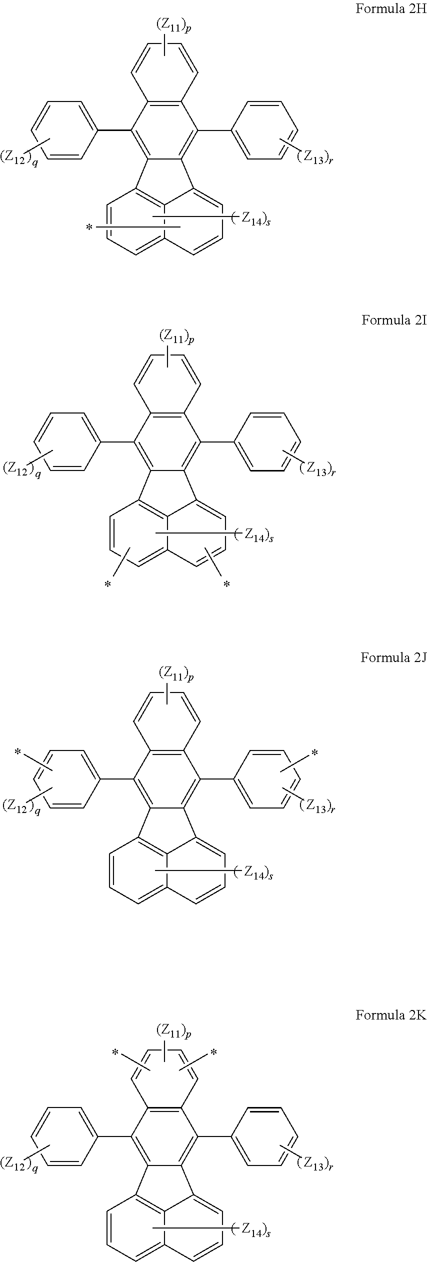 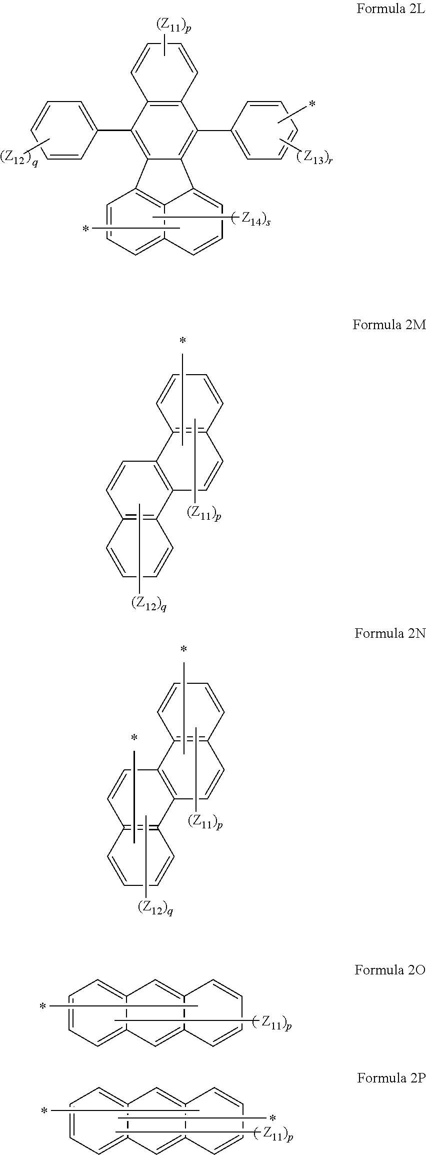
wherein, in Formulae 2A to 2P,
Z₁₁ to Z₁₄ are substituents, each independently being one selected from
a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, or a C₂-C₂₀ heteroaryl group,
a C₁-C₂₀ alkyl group, a C₁-C₂₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof, or
a C₆-C₂₀ aryl group or a C₂-C₂₀ heteroaryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, or a C₂-C₂₀ heteroaryl group, wherein, when the total number of Z₁₁ to Z₁₄ substituents is more than one, the Z₁₁, the Z₁₂, the Z₁₃, and Z₁₄ substituents are identical to or different from each other,
p is an integer of 0 to 9;
q and s are each independently an integer of 0 to 6;
r is an integer of 0 to 5; and
* is a binding site.

3. An indole-based compound of claim 2, wherein Z₁₁ to Z₁₄ are each independently selected from
a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a propyl group, a methoxy group, an ethoxy group, a propoxy group, a phenyl group, a naphthyl group, a pyrrole group, a pyridyl group, and a pyrimidyl group,
a methyl group, an ethyl group, a propyl group, a methoxy group, an ethoxy group, a propoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof, or
a phenyl group, a naphthyl group, a pyrrole group, a pyridyl group, and a pyrimidyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, or a C₂-C₂₀ heteroaryl group; and
the Z₁₁, the Z₁₂, the Z₁₃, and Z₁₄ substituents are identical to or different from each other.

4. An indole-based compound of claim 1, wherein Ar₁ is a group represented by one of Formulae 3A to 3H: 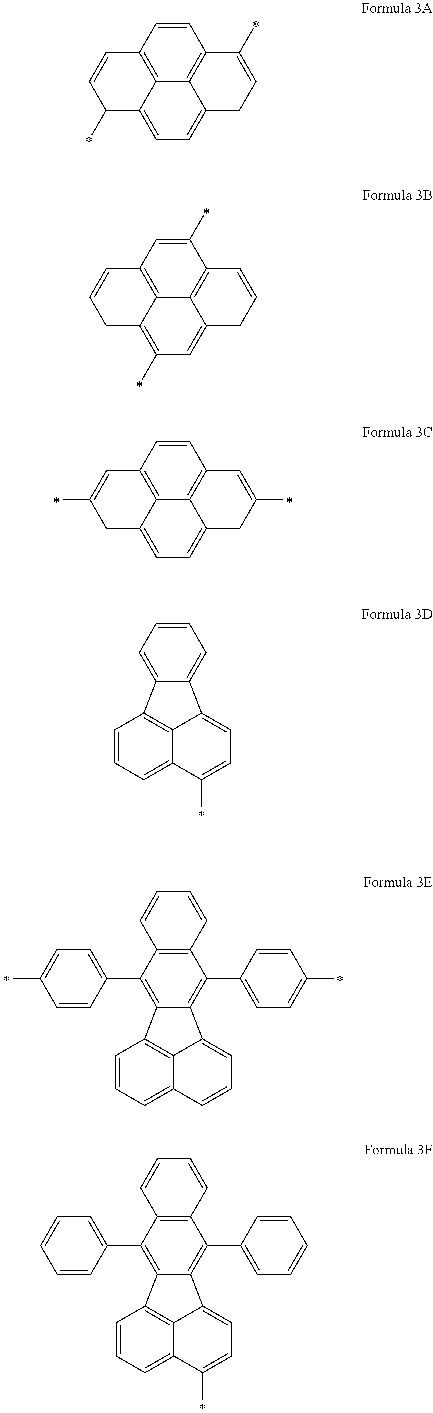 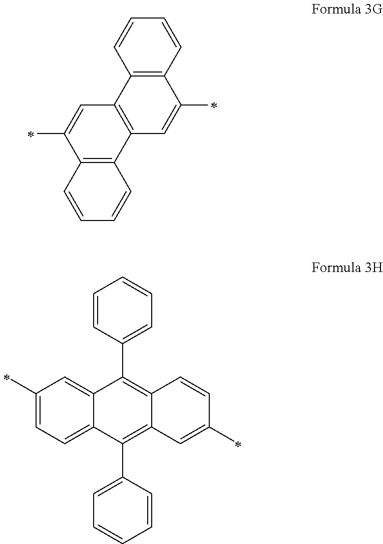
wherein, in Formulae 3A to 3H, * indicates a binding site.

5. An indole-based compound of claim 1, wherein R₁ to R₆ are each independently selected from
a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, a C₁-C₁₀ alkoxy group, a phenyl group, a naphthyl group, a phenanthrenyl group, an anthryl group, a pentalenyl group, or an indenyl group, or
a C₁-C₁₀ alkyl group, a C₁-C₁₀ alkoxy group, a phenyl group, a naphthyl group, a phenanthrenyl group, an anthryl group, a pentalenyl group, and an indenyl group, each substituted with at least one of a deuterium atom, a halogen atom, a hydroxyl group, a cyano group, a nitro group, an amino group, an amidino group, a hydrazine, a hydrazone, a silyl group, a carboxyl group or a salt thereof, a sulfonic acid group or a salt thereof, or a phosphoric acid group or a salt thereof.

6. An indole-based compound of claim 1, wherein R₁ to R₆ are each independently selected from a phenyl group, a naphthyl group, a phenanthrenyl group, an anthryl group, a pentalenyl group, or an indenyl group, each substituted with a hydrogen atom, a deuterium atom, a halogen atom, a cyano group, a methyl group, an ethyl group, a propyl group, a phenyl group, or a silyl group.

7. An indole-based compound of claim 1, wherein R₁ and R₂ are each independently a hydrogen atom or a group represented by one of Formulae 4A and 4B; and
R₃ to R₆ are hydrogen atoms: 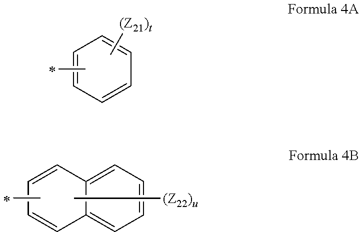
wherein, in Formula 4A and 4B,
Z₂₁ and Z₂₂ are substituents, being each independently selected from
a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, or a C₂-C₂₀ heteroaryl group,
a C₁-C₂₀ alkyl group or a C₁-C₂₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof, or
a C₆-C₂₀ aryl group or a C₂-C₂₀ heteroaryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, C₁-C₂₀ alkyl group, a C₁-C₂₀ alkoxy group, a C₆-C₂₀ aryl group, or a C₂-C₂₀ heteroaryl group;
t is an integer of 0 to 5, and u is an integer of 0 to 7, wherein, when the total number of Z₂₁ and Z₂₂ substituents is more than one, the Z₂₁ and Z₂₂ substituents are identical to or different from each other; and
* indicates a binding site.

8. An indole-based compound of claim 1, wherein R₁ and R₂ are each independently a hydrogen atom or a group represented by one of Formulae 5A to 5M below; and R₃ to R₆ are each independently hydrogen atoms: 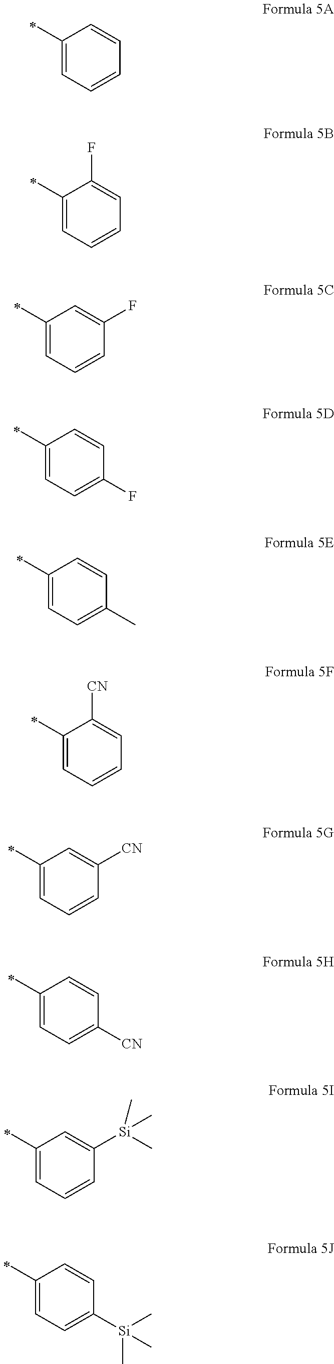 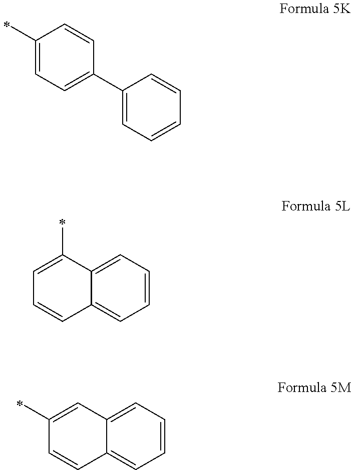
wherein, in Formulae 5A to 5M, * indicates a binding site.

9. An indole-based compound of claim 1, wherein the indole-based compound is one of Compounds 1 to 60 below:

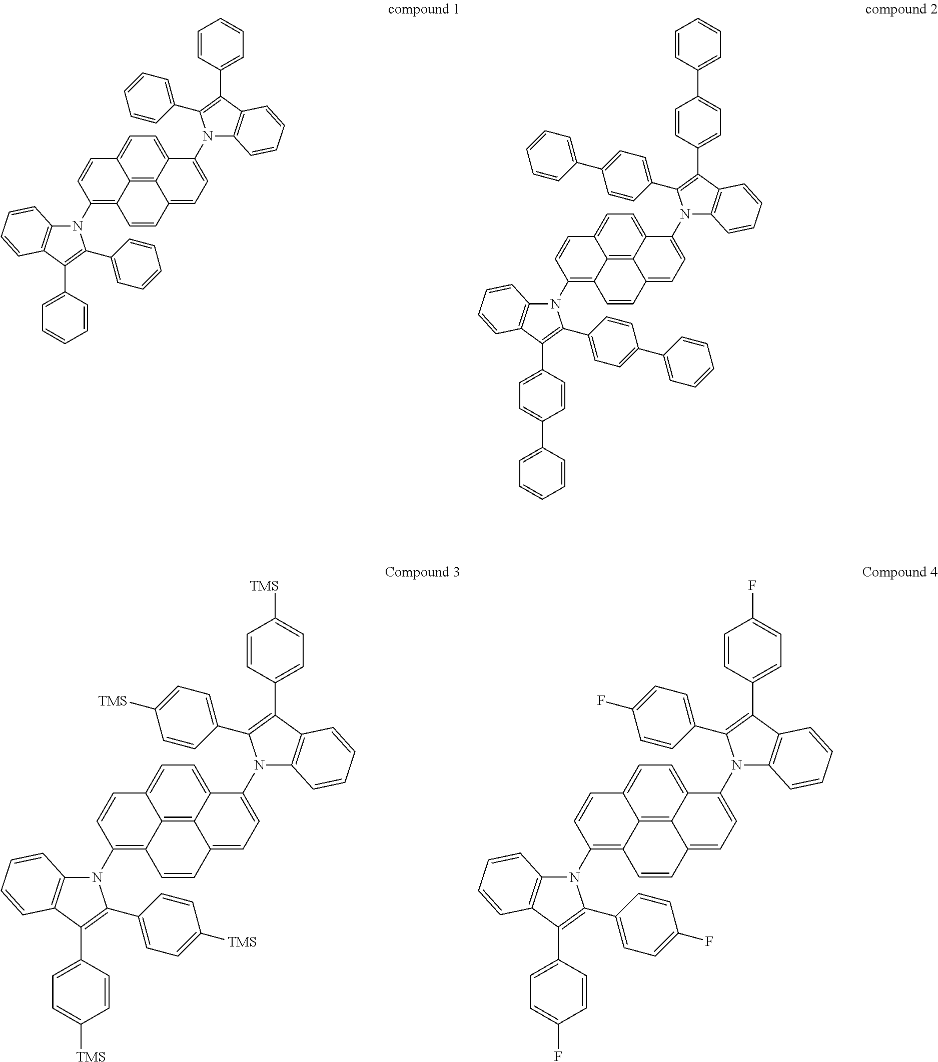

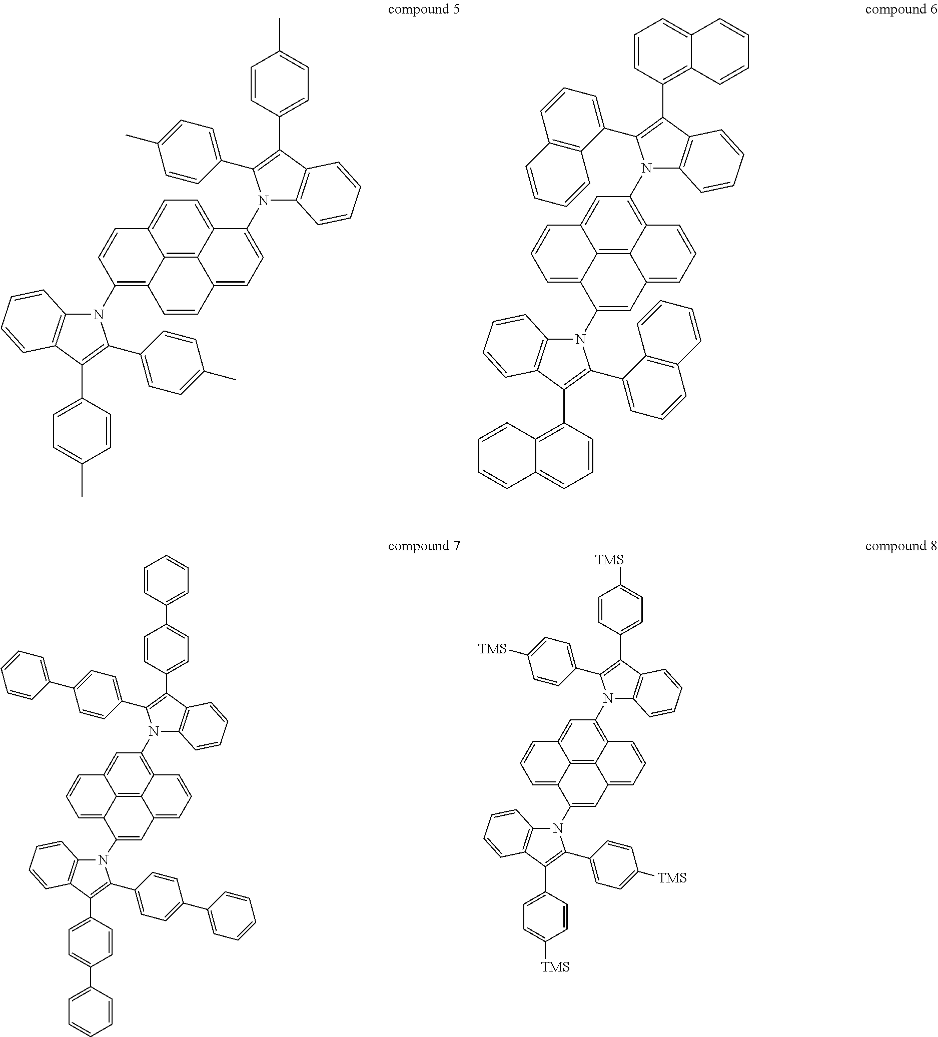

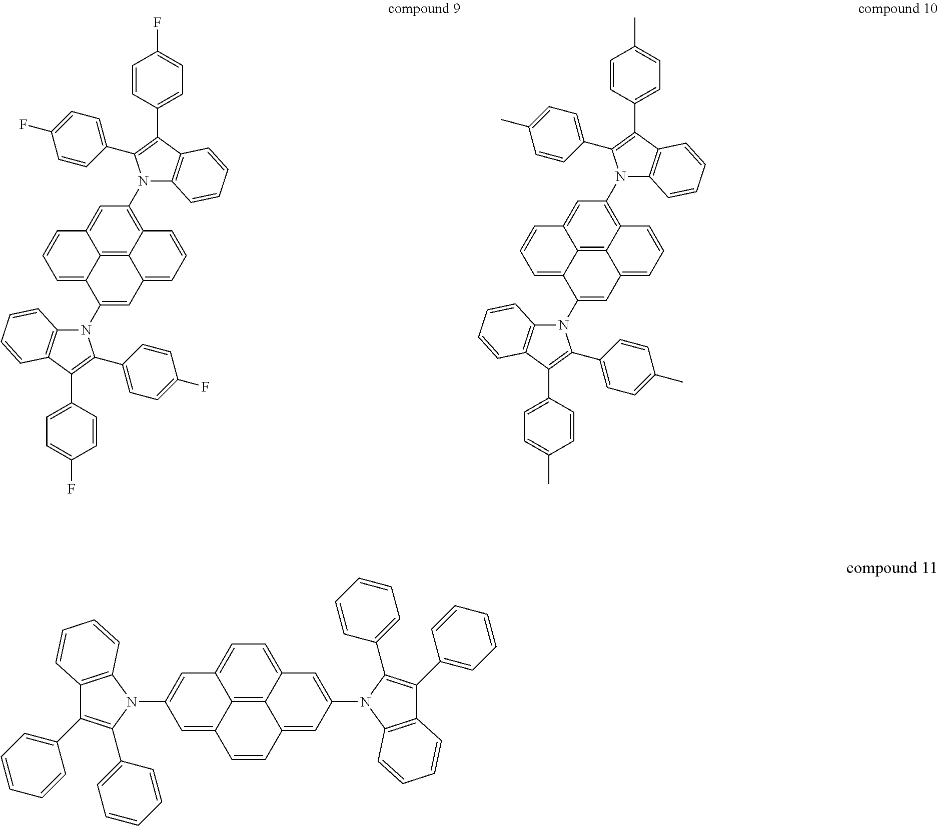 [SMILES: Fc1ccc(-c2c(-c3ccc(F)cc3)n(-c3cc4cccc5c(-n6c(-c7ccc(F)cc7)c(-c7ccc(F)cc7)c7ccccc76)cc6cccc3c6c45)c3ccccc23)cc1 ; Cc1ccc(-c2c(-c3ccc(C)cc3)n(-c3cc4cccc5c(-n6c(-c7ccc(C)cc7)c(-c7ccc(C)cc7)c7ccccc76)cc6cccc3c6c45)c3ccccc23)cc1 ; c1ccc(-c2c(-c3ccccc3)n(-c3cc4ccc5cc(-n6c(-c7ccccc7)c(-c7ccccc7)c7ccccc76)cc6ccc(c3)c4c56)c3ccccc23)cc1]

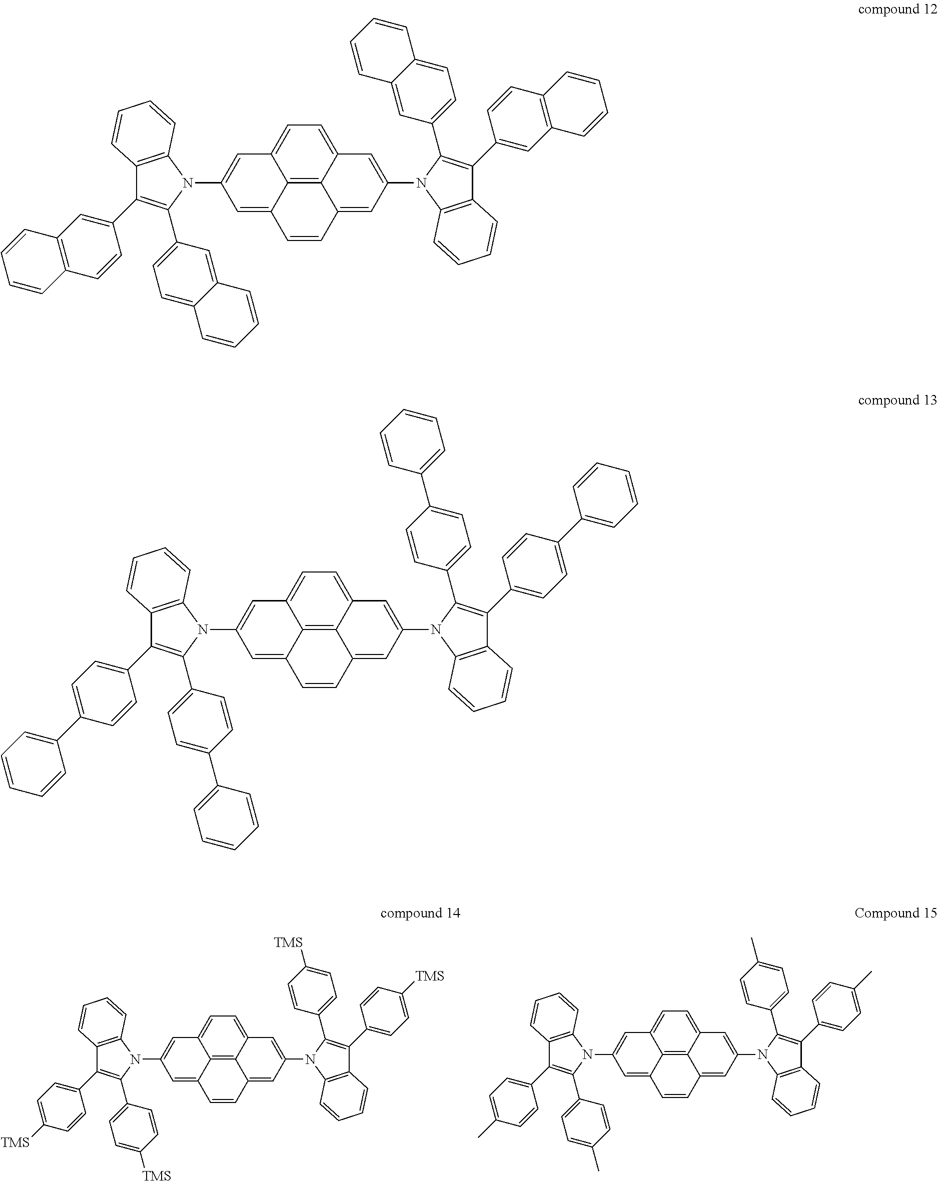

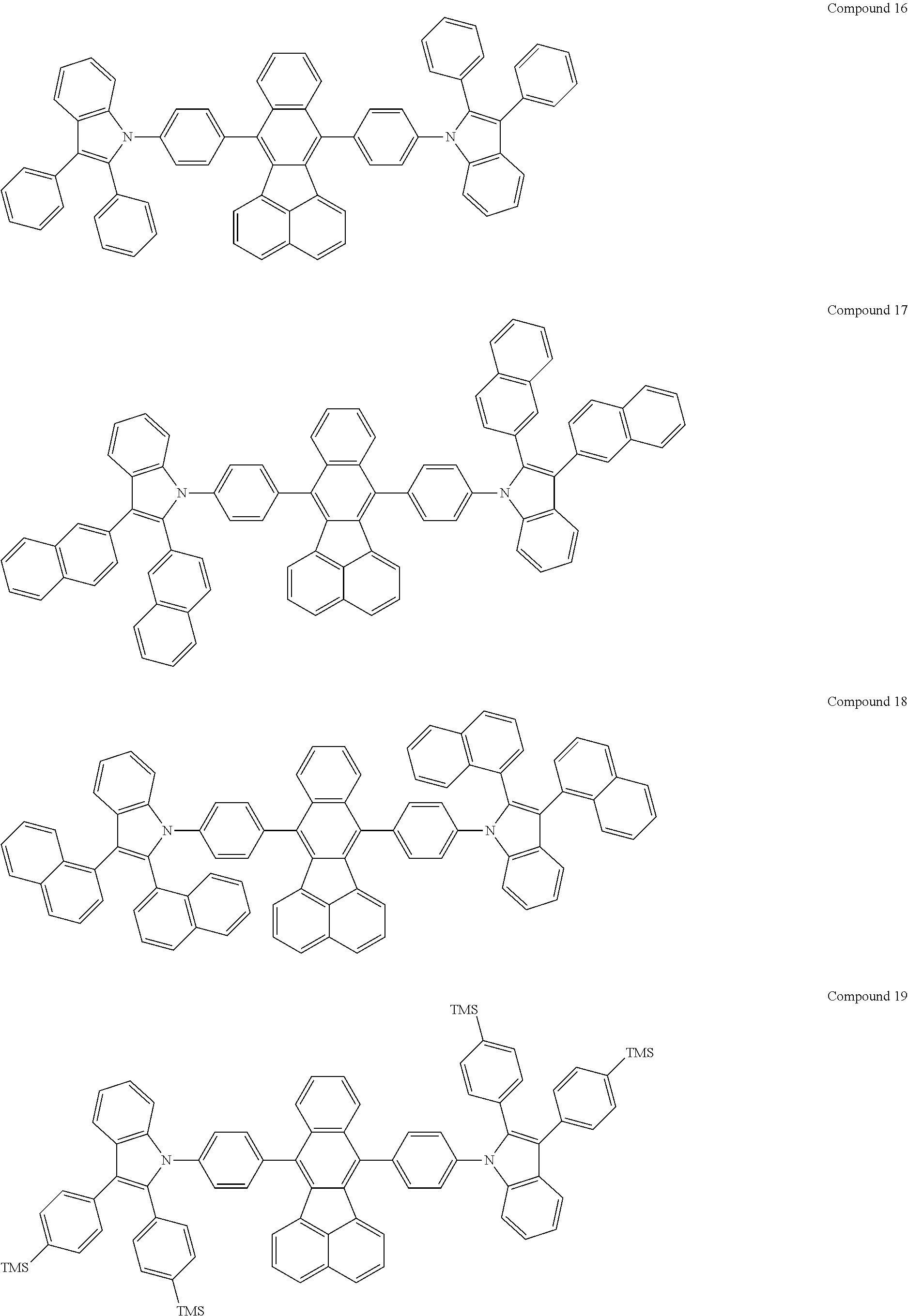

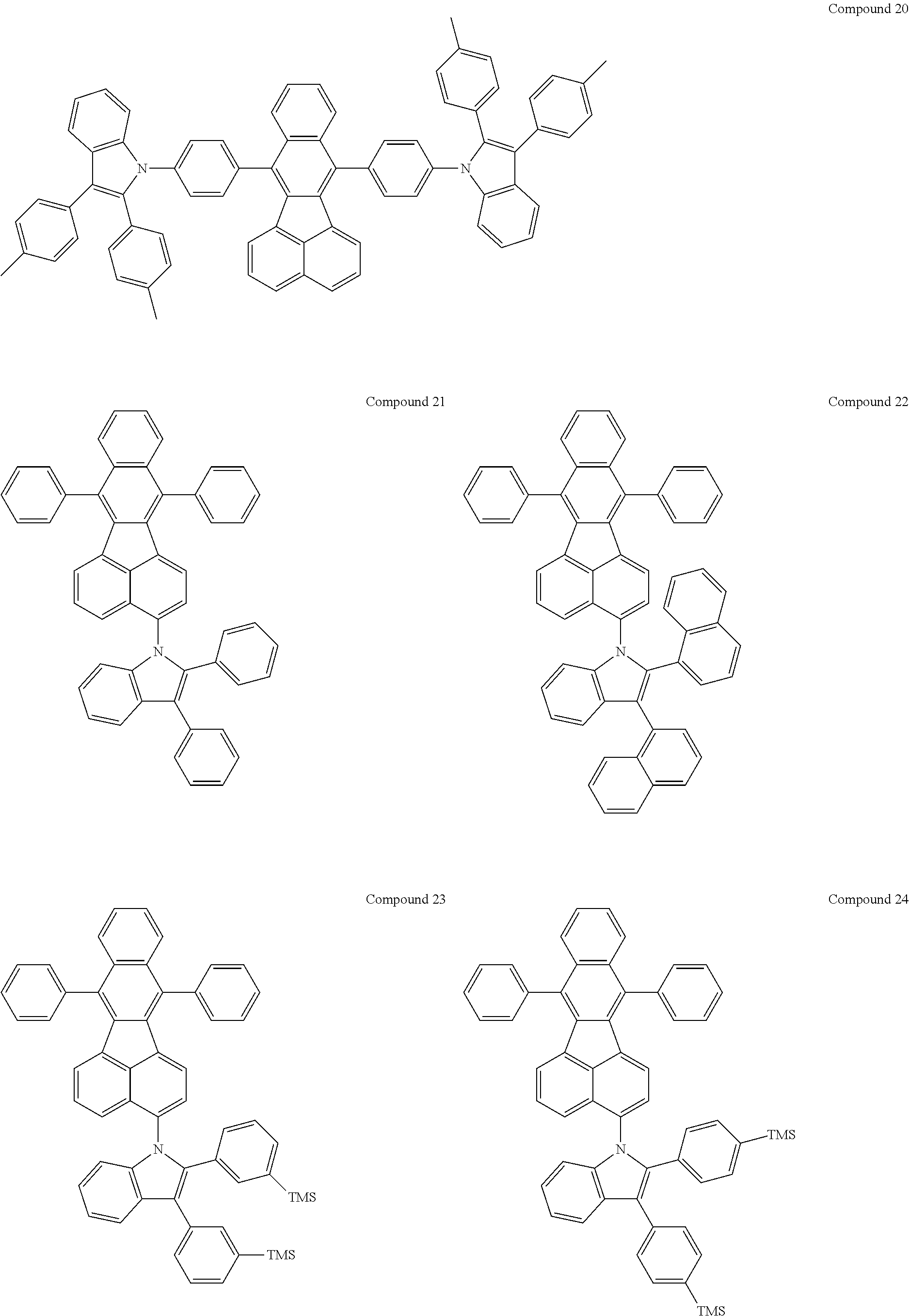

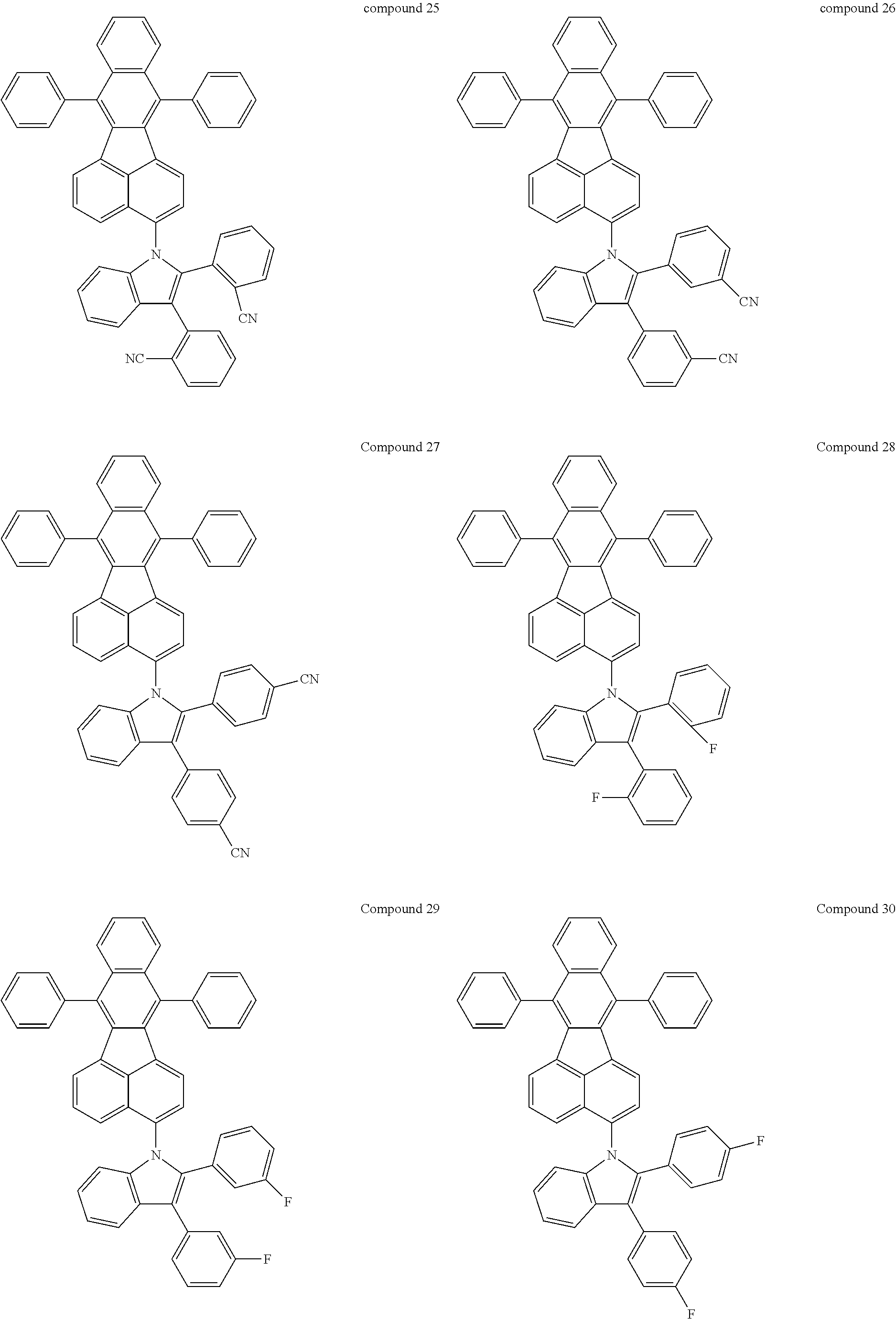

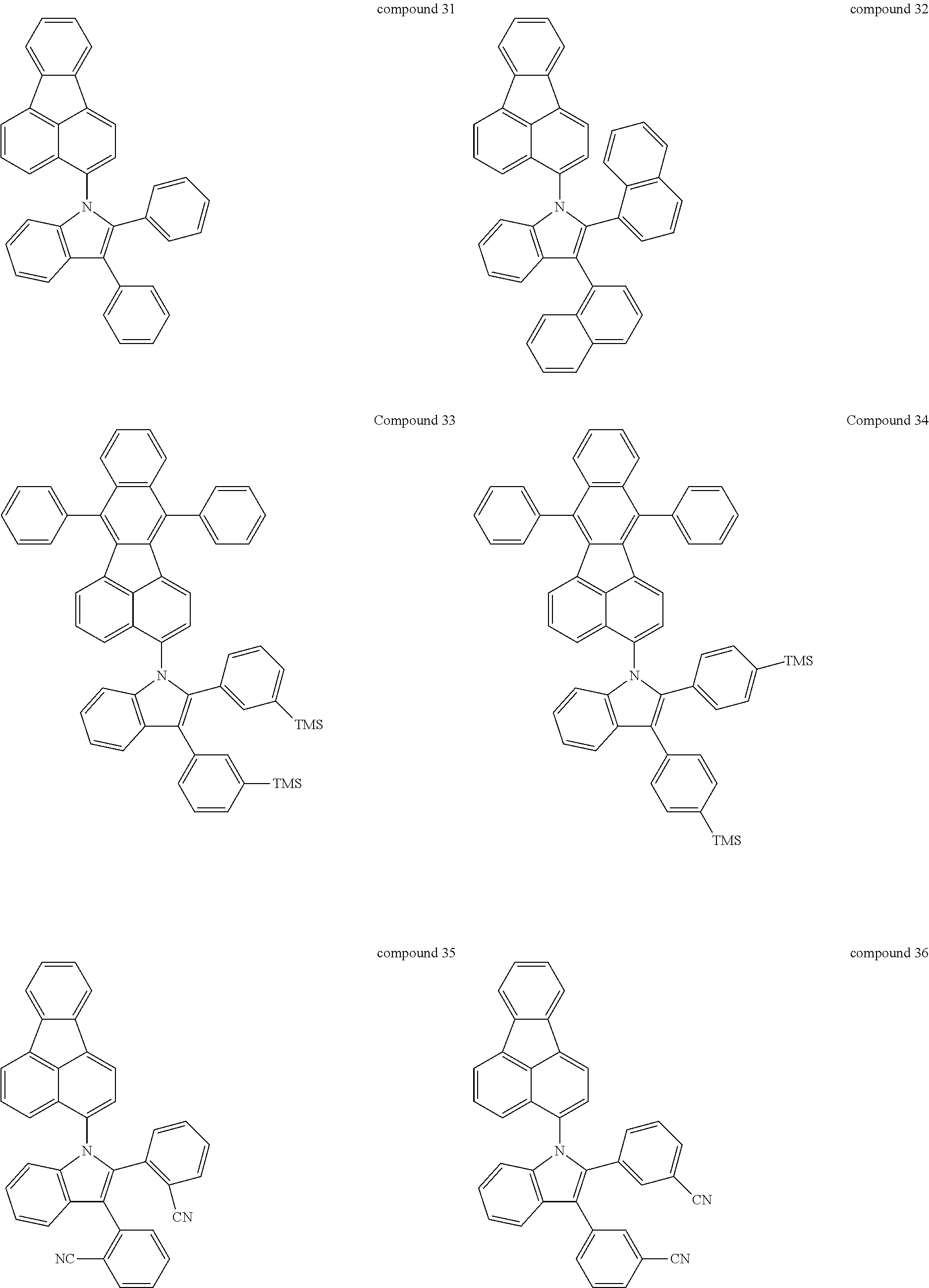

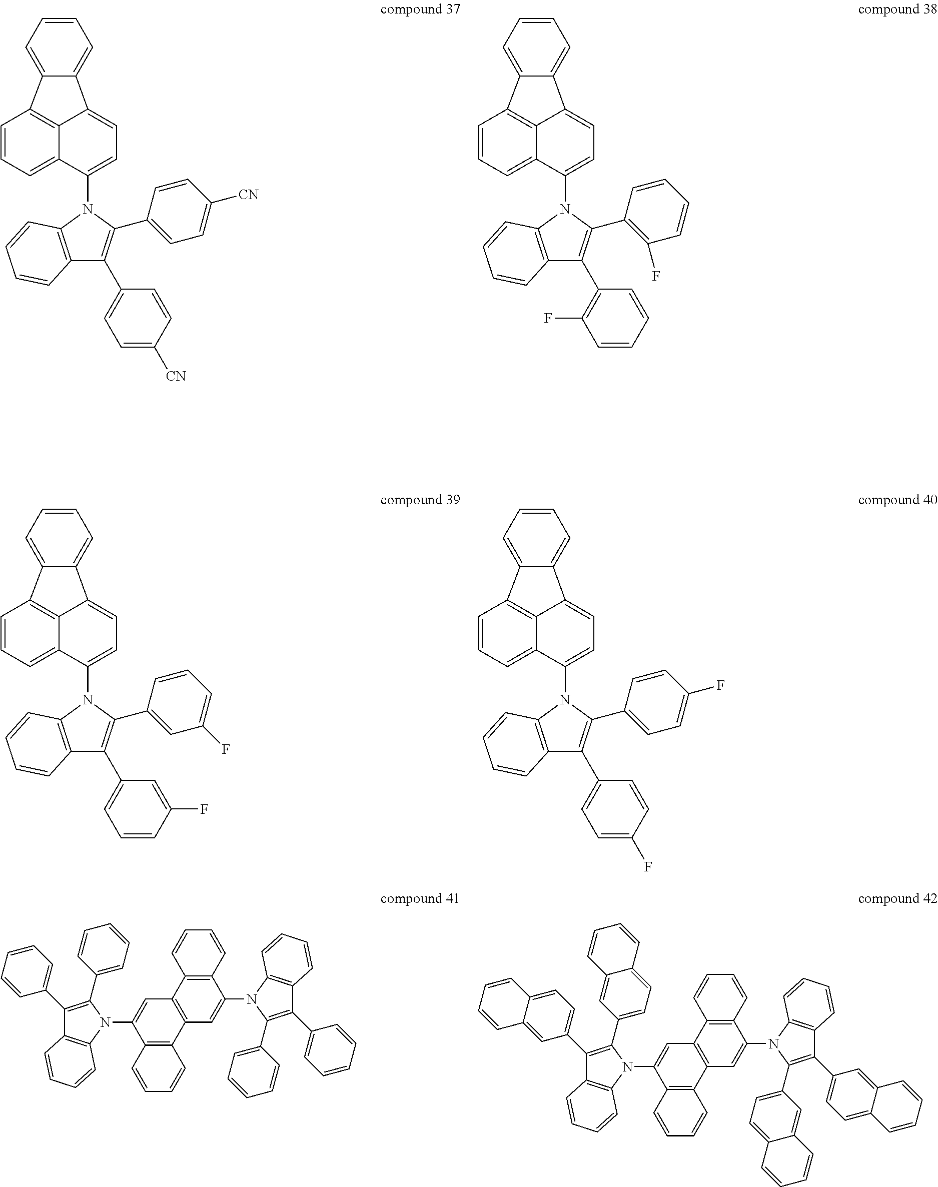

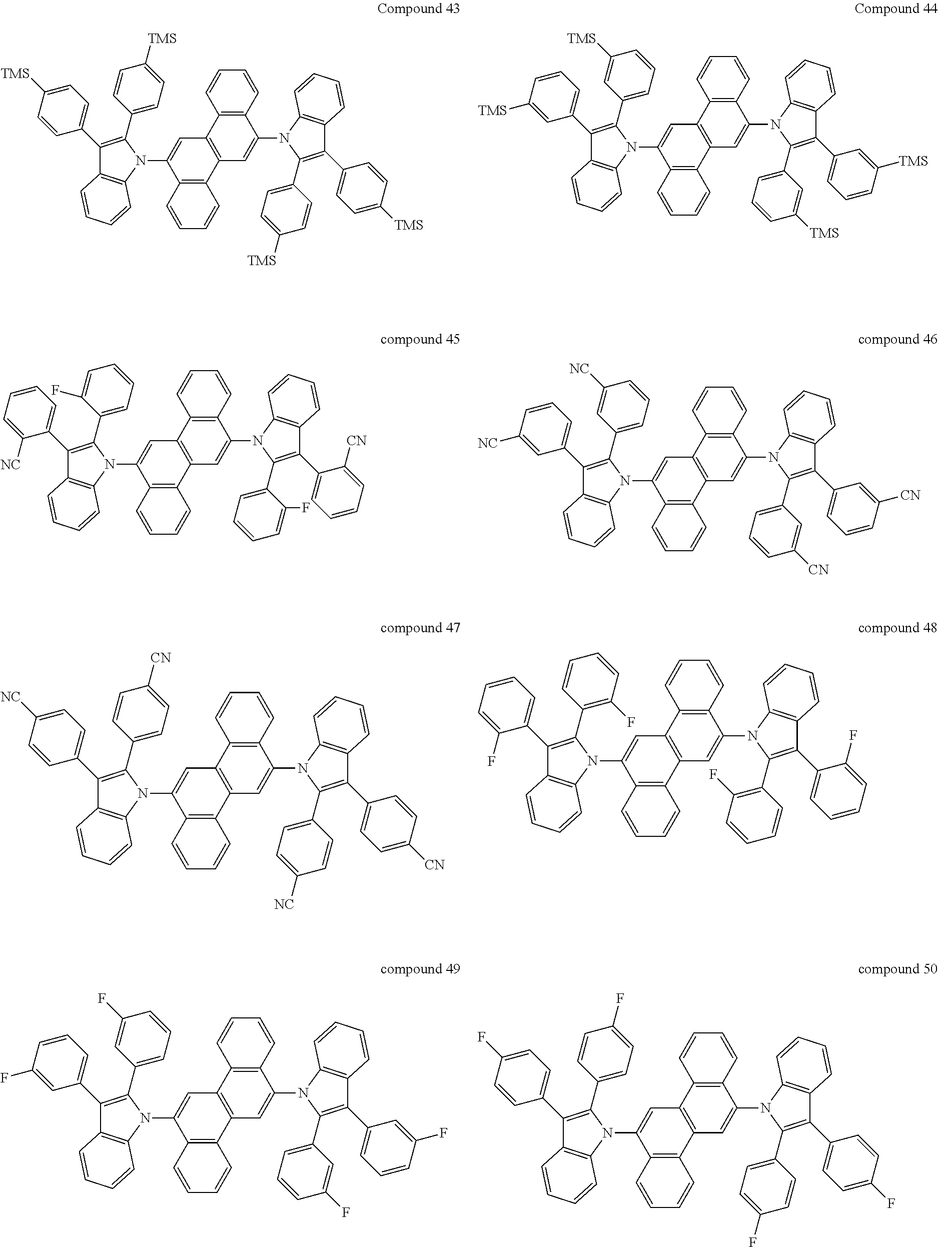

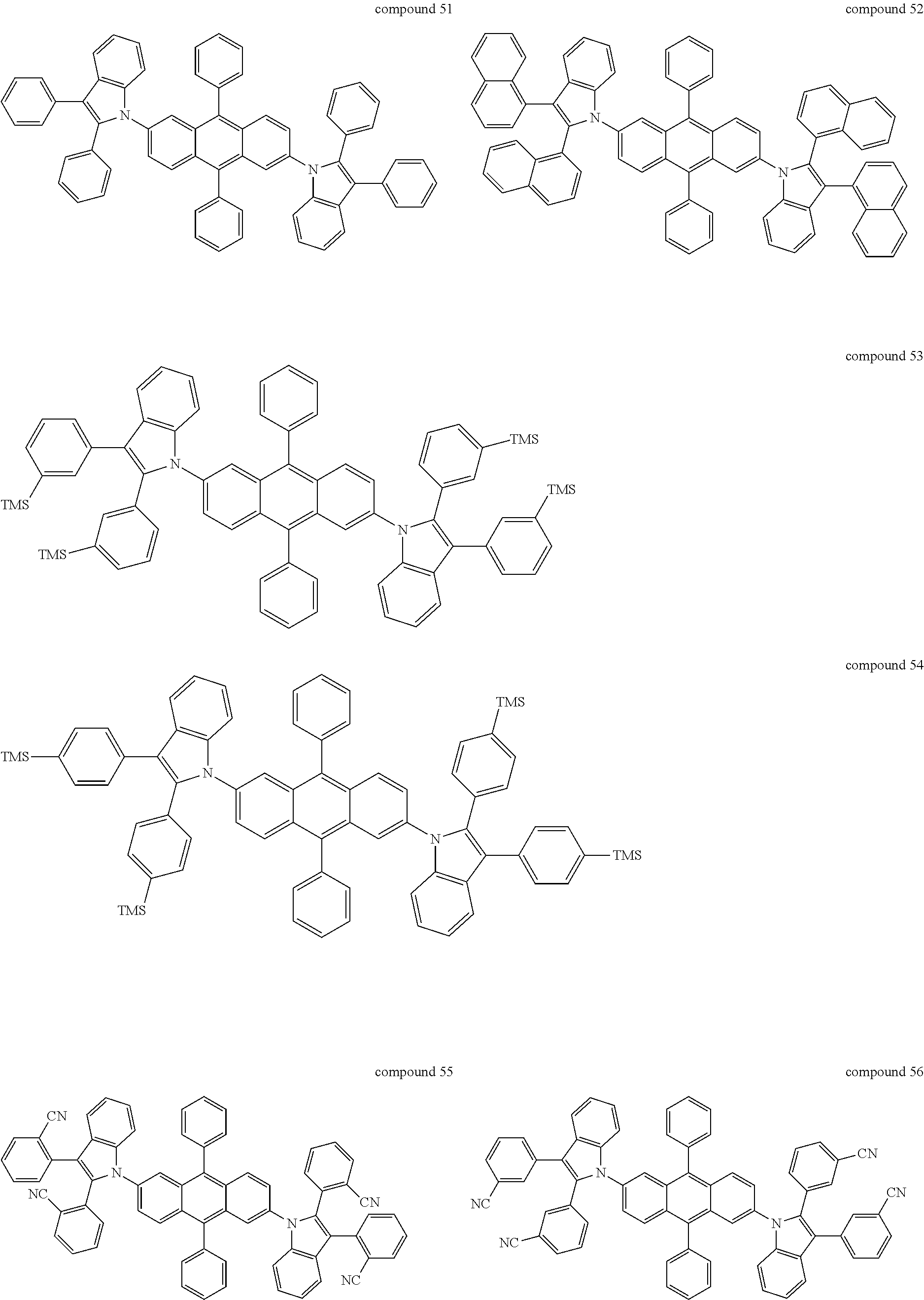

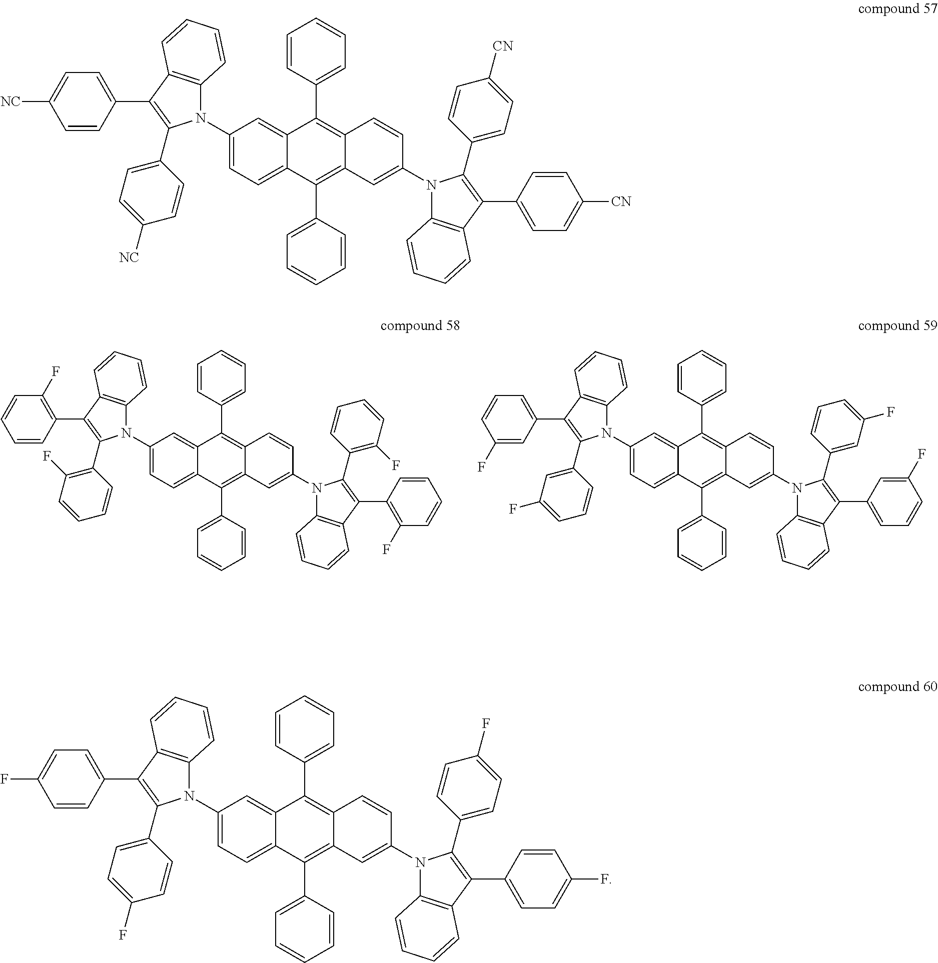

10. An indole-based compound of claim 9, wherein the indole-based compound is one of Compounds 1, 21, 38, 41, and 52 below:

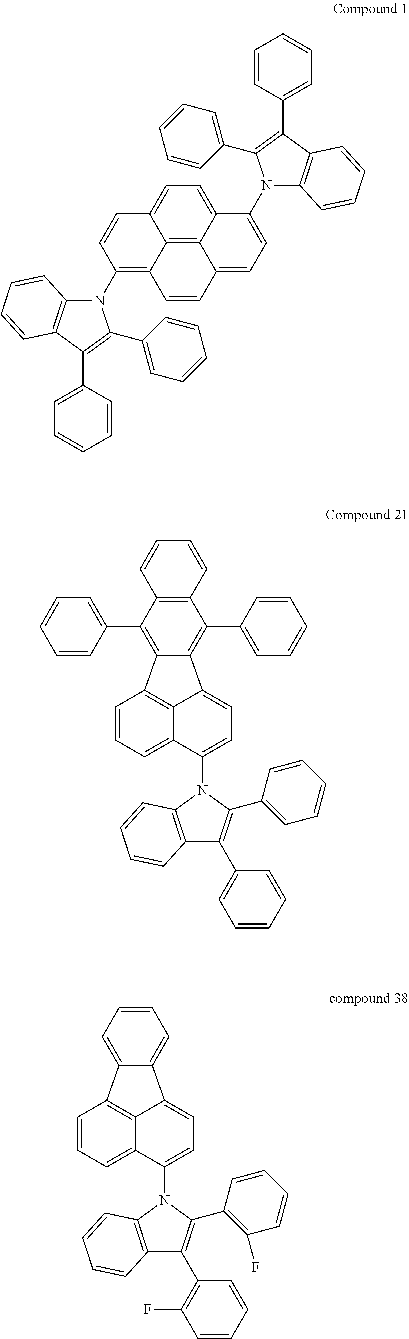 [SMILES: c1ccc(-c2c(-c3ccccc3)n(-c3ccc4ccc5c(-n6c(-c7ccccc7)c(-c7ccccc7)c7ccccc76)ccc6ccc3c4c65)c3ccccc23)cc1 ; c1ccc(-c2c3c(c(-c4ccccc4)c4ccccc24)-c2ccc(-n4c(-c5ccccc5)c(-c5ccccc5)c5ccccc54)c4cccc-3c24)cc1 ; Fc1ccccc1-c1c(-c2ccccc2F)n(-c2ccc3c4c(cccc24)-c2ccccc2-3)c2ccccc12]

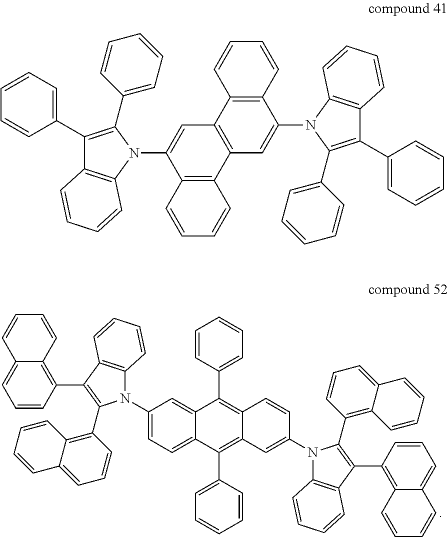 [SMILES: c1ccc(-c2c(-c3ccccc3)n(-c3cc4c5ccccc5c(-n5c(-c6ccccc6)c(-c6ccccc6)c6ccccc65)cc4c4ccccc34)c3ccccc23)cc1 ; c1ccc(-c2c3ccc(-n4c(-c5cccc6ccccc56)c(-c5cccc6ccccc56)c5ccccc54)cc3c(-c3ccccc3)c3ccc(-n4c(-c5cccc6ccccc56)c(-c5cccc6ccccc56)c5ccccc54)cc23)cc1]

11. An organic light-emitting diode comprising:
a substrate;
a first electrode disposed on the substrate;
a second electrode disposed opposite to the first electrode; and
an organic layer disposed between the first electrode and the second electrode,
the organic layer comprises at least one layer comprising at least one indole-based compound of claim 1.

12. The organic light-emitting diode of claim 1, wherein the organic layer comprises at least one of a hole injection layer, a hole transport layer, a hole injection and transport layer having both hole injection and hole transport capabilities, an emission layer, a hole blocking layer, an electron transport layer, an electron injection layer, or an electron injection and transport layer having both electron injection and electron transport capabilities.

13. The organic light-emitting diode of claim 12, wherein the organic layer comprises the emission layer, and the emission layer comprises an indole-based compound of Formula 1.

14. The organic light-emitting diode of claim 13, wherein the emission layer comprises a host and a dopant, and the dopant comprises an indole-based compound of Formula 1.

15. The organic light-emitting diode of claim 14, wherein the host comprises an anthracene-based material.

16. The organic light-emitting diode of claim 12, wherein the organic layer comprises a hole injection layer, a hole transport layer, or a hole injection and transport layer, and at least one of the hole injection layer, the hole transport layer, or the hole injection layer further comprises a charge-generating material.

17. The organic light-emitting diode of claim 16, wherein the charge-generating material is a p-type dopant.

18. The organic light-emitting diode of claim 17, wherein the p-dopant is a quinine derivative, a metal oxide, or a cyano group-containing compound.
